(19) United States
(12) Patent Application Publication
(10) Pub. No.: US 2016/0351815 A1
(43) Pub. Date: Dec. 1, 2016

(54) Phenazine-Based Molecular and Polymeric Semiconductors

(71) Applicants: Universita degli Studi di Milano - Bicocca, Milan (IT); Polyera Corporation, Skokie, IL (US)

(72) Inventors: Antonio Papagni, Milan (IT); Antonio Facchetti, Chicago, IL (US); Zhihua Chen, Skokie, IL (US)

(21) Appl. No.: 15/168,026

(22) Filed: May 28, 2016

Related U.S. Application Data
(60) Provisional application No. 62/168,484, filed on May 29, 2015.

(51) Int. Cl. H01L 51/00; C08G 61/12

(52) U.S. Cl. CPC H01L 51/0036; C08G 61/126; H01L 51/4253

(57) ABSTRACT

The present invention relates to new semiconducting compounds having at least one optionally substituted phenazine moiety. The compounds disclosed herein can exhibit high carrier mobility and/or efficient light absorption/emission characteristics, and can possess certain processing advantages such as solution-processability and/or good stability at ambient conditions.

### CROSS-REFERENCE TO RELATED APPLICATIONS

This application claims priority to and the benefit of U.S. Provisional Patent Application Ser. No. 62/168,484, filed on May 29, 2015, the disclosure of which is incorporated by reference herein in its entirety.

### BACKGROUND

Organic electronics is a new technology for fabricating optoelectronic devices using high-throughput, inexpensive solution processes (e.g., printing methodologies) on flexible plastic foils, which contrasts sharply with the highly specialized and expensive facilities and equipment required for silicon fabrication. By developing new organic electronic materials, these technologies could enable inexpensive, lightweight, flexible, optically transparent, and unbreakable components for displays, cell phones, medical diagnostics, RFID tags, and solar modules which can then be integrated with textiles, printed batteries, solar cells, and aircraft/satellite structures. The enabling material component of all these technologies (among other essential materials) is the semiconductor where charge transport, light absorption, and/or light generation occurs. To broaden device functionalities and applications, two types of semiconductors are required: p-type (hole-transporting) and n-type (electron-transporting). The use/combination of these two types of semiconductors enables the fabrication of elementary electronic building blocks for driving displays, harvesting light, generating light, carrying out logic operations, and sensor functions. To achieve high device efficiencies such as large charge carrier mobilities (μ) needed for transistor/circuit operations, or efficient exciton formation/splitting necessary for photonic devices, organic semiconductors should have specific and appropriate optical and electronic features.

Several p- and n-channel molecular semiconductors have reached acceptable device performance and stability. For example, OTFTs based on acenes and oligothiophenes (p-channel) and perylenes (n-channel) exhibit carrier mobilities (μ's)>1 cm²/Vs in ambient conditions. However, molecular semiconductors typically are less easily processable via printing methodologies than polymeric semiconductors due to solution viscosity requirements.

Accordingly, the art desires new semiconducting compounds, particularly those having good stability, processing properties, and/or charge transport characteristics in ambient conditions.

### SUMMARY

In light of the foregoing, the present teachings provide organic semiconducting compounds that can address various deficiencies and shortcomings of the prior art, including those outlined above. Compounds according to the present teachings can exhibit properties such as optimized optical absorption, good charge transport characteristics and chemical stability in ambient conditions, low-temperature processability, large solubility in common solvents, and processing versatility (e.g., via various solution processes). As a result, optoelectronic devices such as OPV cells that incorporate one or more of the present compounds as a photoactive layer can exhibit high performance in ambient conditions, for example, demonstrating one or more of low band-gap, high fill factor, high open circuit voltage, and high power conversion efficiency, and preferably all of these criteria. Similarly, other organic semiconductor-based devices such as OTFTs can be fabricated efficiently using the organic semiconductor materials described herein.

Generally, the present teachings provide semiconducting compounds that include one or more divalent phenazine moieties. Such divalent phenazine moieties can be represented by formula (I):

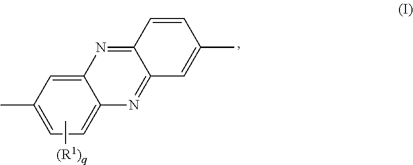

wherein R¹ is an optional substituent (i.e., q can be 0 or an integer selected from 1, 2, 3, 4, 5 and 6, preferably 2 or 6). In some embodiments, the present compound is a polymer having one or more repeating units M₁ each of which includes at least one phenazine moiety (and optionally, one or more linear and/or cyclic conjugated moieties) and where the polymer has a degree of polymerization (n) ranging from at least 3. In preferred embodiments, the divalent phenazine moieties can be represented by formula (II):

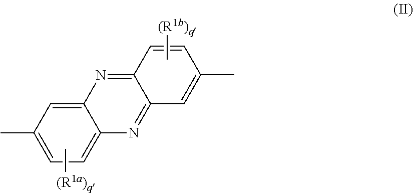

wherein R^{1a} and R^{1b} can be identical or different substituents, and q′, at each occurrence, independently, can be 0 or an integer selected from 1, 2, and 3. Preferably, at least one of q′ is not 0.

In certain embodiments, the polymer is a homopolymer including only repeating units M₁. In other embodiments, the polymer also includes at least one other repeating unit M₂ that does not include any phenazine moiety. Such M₂ unit can be selected from:

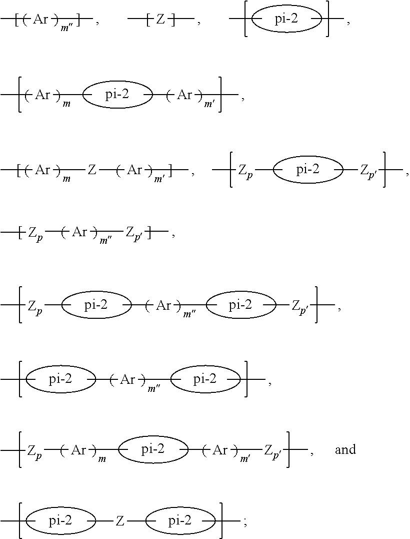

wherein pi-2, Ar, Z, m, m′, m″, p, and p′ are as defined herein. In some embodiments, the present compound is a molecular compound including at least one phenazine moiety and a plurality of linear and/or cyclic conjugated moieties, such that the compound as a whole provides a pi-extended conjugated system.

The present teachings also provide methods of preparing such compounds and semiconductor materials based on such compounds, as well as various compositions, composites, and devices that incorporate the compounds and semiconductor materials disclosed herein.

The foregoing as well as other features and advantages of the present teachings will be more fully understood from the following figures, description, examples, and claims.

### BRIEF DESCRIPTION OF DRAWINGS

It should be understood that the drawings described below are for illustration purpose only. The drawings are not necessarily to scale, with emphasis generally being placed upon illustrating the principles of the present teachings. The drawings are not intended to limit the scope of the present teachings in any way.

FIG. 1 illustrates different configurations for opto-electronic devices: a) bottom-gate top contact thin-film transistor, b) top-gate bottom-contact thin-film transistor, c) conventional organic solar cell, d) inverted solar cell; each of which can be used to incorporate one or more compounds of the present teachings, particularly as the semiconductor materials.

FIG. 2 provides the optical absorption spectrum (A) and ¹⁹F NMR spectrum (B) of 2,7-dibromo-1,3,4,6,8,9-hexafluorophenazine.

FIG. 3 provides the optical absorption spectrum of 3,8-dibromo-1,6-difluorophenazine.

FIG. 4 provides the cyclic voltammogram (A) and optical absorption spectrum (B) of polymer P2.

FIG. 5 provides the cyclic voltammogram (A) and optical absorption spectrum (B) of polymer P4.

FIG. 6 provides the cyclic voltammogram (A) and optical absorption spectrum (B) of polymer P5.

FIG. 7 reports representative output plots for electron (A) and hole (B) accumulation for a TGBC OTFT based on polymer P2.

FIG. 8 reports representative output (A) and transfer (B) plots for hole accumulation for a TGBC OTFT based on polymer P4.

FIG. 9 reports representative output (A) and transfer (B) plots for hole accumulation for a TGBC OTFT based on polymer P5.

FIG. 10 reports representative output plots for a BGTC OTFT based on vapor-deposited small molecule SM1 (T_{deposition}=70° C.) having different surface functionalization of the Si/SiO₂ substrates.

FIG. 11 reports the external quantum efficiency of a donor polymer:P3 (as acceptor) blend OPV device.

FIG. 12 reports the current-voltage scan of a P4 (as donor):C₇₀PCBM blend OPV device.

### DETAILED DESCRIPTION

Throughout the application, where compositions are described as having, including, or comprising specific components, or where processes are described as having, including, or comprising specific process steps, it is contemplated that compositions of the present teachings also consist essentially of, or consist of, the recited components, and that the processes of the present teachings also consist essentially of, or consist of, the recited process steps.

In the application, where an element or component is said to be included in and/or selected from a list of recited elements or components, it should be understood that the element or component can be any one of the recited elements or components and can be selected from a group consisting of two or more of the recited elements or components. Further, it should be understood that elements and/or features of a composition, an apparatus, or a method described herein can be combined in a variety of ways without departing from the spirit and scope of the present teachings, whether explicit or implicit herein.

The use of the terms “include,” “includes”, “including,” “have,” “has,” or “having” should be generally understood as open-ended and non-limiting unless specifically stated otherwise.

The use of the singular herein includes the plural (and vice versa) unless specifically stated otherwise. In addition, where the use of the term “about” is before a quantitative value, the present teachings also include the specific quantitative value itself, unless specifically stated otherwise. As used herein, the term “about” refers to a ±10% variation from the nominal value unless otherwise indicated or inferred.

It should be understood that the order of steps or order for performing certain actions is immaterial so long as the present teachings remain operable. Moreover, two or more steps or actions may be conducted simultaneously.

As used herein, a “p-type semiconductor material” or a “donor” material refers to a semiconductor material, for example, an organic semiconductor material, having holes as the majority current or charge carriers. In some embodiments, when a p-type semiconductor material is deposited on a substrate, it can provide a hole mobility in excess of about 10⁻⁵ cm²/Vs. In the case of field-effect devices, a p-type semiconductor also can exhibit a current on/off ratio of greater than about 10.

As used herein, an “n-type semiconductor material” or an “acceptor” material refers to a semiconductor material, for example, an organic semiconductor material, having electrons as the majority current or charge carriers. In some embodiments, when an n-type semiconductor material is deposited on a substrate, it can provide an electron mobility in excess of about 10⁻⁵ cm²/Vs. In the case of field-effect devices, an n-type semiconductor also can exhibit a current on/off ratio of greater than about 10.

As used herein, “mobility” refers to a measure of the velocity with which charge carriers, for example, holes (or units of positive charge) in the case of a p-type semiconductor material and electrons (or units of negative charge) in the case of an n-type semiconductor material, move through the material under the influence of an electric field. This parameter, which depends on the device architecture, can be measured using a field-effect device or space-charge limited current measurements.

As used herein, a compound can be considered “ambient stable” or “stable at ambient conditions” when a transistor incorporating the compound as its semiconducting material exhibits a carrier mobility that is maintained at about its initial measurement when the compound is exposed to ambient conditions, for example, air, ambient temperature, and humidity, over a period of time. For example, a compound can be described as ambient stable if a transistor incorporating the compound shows a carrier mobility that does not vary more than 20% or more than 10% from its initial value after exposure to ambient conditions, including, air, humidity and temperature, over a 3 day, 5 day, or 10 day period.

As used herein, fill factor (FF) is the ratio (given as a percentage) of the actual maximum obtainable power, (Pₘ or Vₘₚ*Jₘₚ), to the theoretical (not actually obtainable) power, (J_{sc}*V_{oc}). Accordingly, FF can be determined using the equation:

FF=(Vₘₚ*Jₘₚ)/(J_{sc}*V_{oc})

where Jₘₚ and Vₘₚ represent the current density and voltage at the maximum power point (Pₘ), respectively, this point being obtained by varying the resistance in the circuit until J*V is at its greatest value; and J_{sc} and V_{oc} represent the short circuit current and the open circuit voltage, respectively. Fill factor is a key parameter in evaluating the performance of solar cells. Commercial solar cells typically have a fill factor of about 60% or greater.

As used herein, the open-circuit voltage (V_{oc}) is the difference in the electrical potentials between the anode and the cathode of a device when there is no external load connected.

As used herein, the power conversion efficiency (PCE) of a solar cell is the percentage of power converted from incident light to electrical power. The PCE of a solar cell can be calculated by dividing the maximum power point (Pₘ) by the input light irradiance (E, in W/m²) under standard test conditions (STC) and the surface area of the solar cell (A_{c} in m²). STC typically refers to a temperature of 25° C. and an irradiance of 1000 W/m² with an air mass 1.5 (AM 1.5) spectrum.

As used herein, a component (such as a thin film layer) can be considered “photoactive” if it contains one or more compounds that can absorb photons to produce excitons for the generation of a photocurrent.

As used herein, “solution-processable” refers to compounds (e.g., polymers), materials, or compositions that can be used in various solution-phase processes including spin-coating, printing (e.g., inkjet printing, gravure printing, offset printing and the like), spray coating, electrospray coating, drop casting, dip coating, and blade coating.

As used herein, a “polymeric compound” (or “polymer”) refers to a molecule including a plurality of one or more repeating units connected by covalent chemical bonds. A polymeric compound can be represented by the general formula:

*M*

wherein M is the repeating unit or monomer. The polymeric compound can have only one type of repeating unit as well as two or more types of different repeating units. When a polymeric compound has only one type of repeating unit, it can be referred to as a homopolymer. When a polymeric compound has two or more types of different repeating units, the term “copolymer” or “copolymeric compound” can be used instead. For example, a copolymeric compound can include repeating units

*M^{a}* and *M^{b}*,

where M^{a} and M^{b} represent two different repeating units. Unless specified otherwise, the assembly of the repeating units in the copolymer can be head-to-tail, head-to-head, or tail-to-tail. In addition, unless specified otherwise, the copolymer can be a random copolymer, an alternating copolymer, or a block copolymer. For example, the general formula:

*M^{a}ₓ-M^{b}_{y}*

can be used to represent a copolymer of M^{a} and M^{b} having x mole fraction of M^{a} and y mole fraction of M^{b} in the copolymer, where the manner in which comonomers M^{a} and M^{b} is repeated can be alternating, random, regiorandom, regioregular, or in blocks. In addition to its composition, a polymeric compound can be further characterized by its degree of polymerization (n) and molar mass (e.g., number average molecular weight (Mₙ) and/or weight average molecular weight (M_{w}) depending on the measuring technique(s)).

As used herein, “heteroatom” refers to an atom of any element other than carbon or hydrogen and includes, for example, nitrogen, oxygen, silicon, sulfur, phosphorus, and selenium.

As used herein, “halo” or “halogen” refers to fluoro, chloro, bromo, and iodo.

As used herein, “oxo” refers to a double-bonded oxygen (i.e., ═O).

As used herein, “alkyl” refers to a straight-chain or branched saturated hydrocarbon group. Examples of alkyl groups include methyl (Me), ethyl (Et), propyl (e.g., n-propyl and iso-propyl), butyl (e.g., n-butyl, iso-butyl, sec-butyl, tert-butyl), pentyl groups (e.g., n-pentyl, iso-pentyl, neopentyl), hexyl groups, and the like. In various embodiments, an alkyl group can have 1 to 40 carbon atoms (i.e., C₁₋₄₀ alkyl group), for example, 1-20 carbon atoms (i.e., C₁₋₂₀ alkyl group). In some embodiments, an alkyl group can have 1 to 6 carbon atoms, and can be referred to as a “lower alkyl group.” Examples of lower alkyl groups include methyl, ethyl, propyl (e.g., n-propyl and iso-propyl), and butyl groups (e.g., n-butyl, iso-butyl, sec-butyl, tert-butyl). In some embodiments, alkyl groups can be substituted as described herein. An alkyl group is generally not substituted with another alkyl group, an alkenyl group, or an alkynyl group.

As used herein, “haloalkyl” refers to an alkyl group having one or more halogen substituents. At various embodiments, a haloalkyl group can have 1 to 40 carbon atoms (i.e., C₁₋₄₀ haloalkyl group), for example, 1 to 20 carbon atoms (i.e., C₁₋₂₀ haloalkyl group). Examples of haloalkyl groups include CF₃, C₂F₅, CHF₂, CH₂F, CCl₃, CHCl₂, CH₂Cl, C₂Cl₅, and the like. Perhaloalkyl groups, i.e., alkyl groups where all of the hydrogen atoms are replaced with halogen atoms (e.g., CF₃ and C₂F₅), are included within the definition of “haloalkyl.” For example, a C₁₋₄₀ haloalkyl group can have the formula —C_{z}H_{2z+1-t}X⁰ₜ, where X⁰, at each occurrence, is F, Cl, Br or I, z is an integer in the range of 1 to 40, and t is an integer in the range of 1 to 81, provided that t is less than or equal to 2z+1. Haloalkyl groups that are not perhaloalkyl groups can be substituted as described herein.

As used herein, “alkoxy” refers to —O-alkyl group. Examples of alkoxy groups include, but are not limited to, methoxy, ethoxy, propoxy (e.g., n-propoxy and isopropoxy), t-butoxy, pentoxyl, hexoxyl groups, and the like. The alkyl group in the —O-alkyl group can be substituted as described herein.

As used herein, “alkylthio” refers to an —S-alkyl group. Examples of alkylthio groups include, but are not limited to, methylthio, ethylthio, propylthio (e.g., n-propylthio and isopropylthio), t-butylthio, pentylthio, hexylthio groups, and the like. The alkyl group in the —S-alkyl group can be substituted as described herein.

As used herein, “alkenyl” refers to a straight-chain or branched alkyl group having one or more carbon-carbon double bonds. Examples of alkenyl groups include ethenyl, propenyl, butenyl, pentenyl, hexenyl, butadienyl, pentadienyl, hexadienyl groups, and the like. The one or more carbon-carbon double bonds can be internal (such as in 2-butene) or terminal (such as in 1-butene). In various embodiments, an alkenyl group can have 2 to 40 carbon atoms (i.e., C₂₋₄₀ alkenyl group), for example, 2 to 20 carbon atoms (i.e., C₂₋₂₀ alkenyl group). In some embodiments, alkenyl groups can be substituted as described herein. An alkenyl group is generally not substituted with another alkenyl group, an alkyl group, or an alkynyl group.

As used herein, “alkynyl” refers to a straight-chain or branched alkyl group having one or more triple carbon-carbon bonds. Examples of alkynyl groups include ethynyl, propynyl, butynyl, pentynyl, hexynyl, and the like. The one or more triple carbon-carbon bonds can be internal (such as in 2-butyne) or terminal (such as in 1-butyne). In various embodiments, an alkynyl group can have 2 to 40 carbon atoms (i.e., C₂₋₄₀ alkynyl group), for example, 2 to 20 carbon atoms (i.e., C₂₋₂₀ alkynyl group). In some embodiments, alkynyl groups can be substituted as described herein. An alkynyl group is generally not substituted with another alkynyl group, an alkyl group, or an alkenyl group.

As used herein, a “cyclic moiety” can include one or more (e.g., 1-6) carbocyclic or heterocyclic rings. In embodiments where the cyclic moiety is a “polycyclic moiety,” the “polycyclic moiety” can include two or more rings fused to each other (i.e., sharing a common bond) and/or connected to each other via a spiro atom. The cyclic moiety can be a cycloalkyl group, a heterocycloalkyl group, an aryl group, or a heteroaryl group (i.e., can include only saturated bonds, or can include one or more unsaturated bonds regardless of aromaticity), and can be optionally substituted as described herein. In embodiments where the cyclic moiety is a “monocyclic moiety,” the “monocyclic moiety” can include a 3-20 membered carbocyclic or heterocyclic ring. A monocyclic moiety can include a C₆₋₂₀ aryl group (e.g., C₆₋₁₄ aryl group) or a 5-20 membered heteroaryl group (e.g., 5-14 membered heteroaryl group), each of which can be optionally substituted as described herein.

As used herein, “cycloalkyl” refers to a non-aromatic carbocyclic group including cyclized alkyl, alkenyl, and alkynyl groups. In various embodiments, a cycloalkyl group can have 3 to 20 carbon atoms, for example, 3 to 14 carbon atoms (i.e., C₃₋₁₄ cycloalkyl group). A cycloalkyl group can be monocyclic (e.g., cyclohexyl) or polycyclic (e.g., containing fused, bridged, and/or spiro ring systems), where the carbon atoms are located inside or outside of the ring system. Any suitable ring position of the cycloalkyl group can be covalently linked to the defined chemical structure. Examples of cycloalkyl groups include cyclopropyl, cyclobutyl, cyclopentyl, cyclohexyl, cycloheptyl, cyclopentenyl, cyclohexenyl, cyclohexadienyl, cycloheptatrienyl, norbornyl, norpinyl, norcaryl, adamantyl, and spiro[4.5]decanyl groups, as well as their homologs, isomers, and the like. In some embodiments, cycloalkyl groups can be substituted as described herein.

As used herein, “cycloheteroalkyl” refers to a non-aromatic cycloalkyl group that contains at least one ring heteroatom selected from O, S, Se, N, P, and Si (e.g., O, S, and N), and optionally contains one or more double or triple bonds. A cycloheteroalkyl group can have 3 to 20 ring atoms, for example, 3 to 14 ring atoms (i.e., 3-14 membered cycloheteroalkyl group). One or more N, P, S, or Se atoms (e.g., N or S) in a cycloheteroalkyl ring may be oxidized (e.g., morpholine N-oxide, thiomorpholine S-oxide, thiomorpholine S,S-dioxide). In some embodiments, nitrogen or phosphorus atoms of cycloheteroalkyl groups can bear a substituent, for example, a hydrogen atom, an alkyl group, or other substituents as described herein. Cycloheteroalkyl groups can also contain one or more oxo groups, such as oxopiperidyl, oxooxazolidyl, dioxo-(1H,3H)-pyrimidyl, oxo-2(1H)-pyridyl, and the like. Examples of cycloheteroalkyl groups include, among others, morpholinyl, thiomorpholinyl, pyranyl, imidazolidinyl, imidazolinyl, oxazolidinyl, pyrazolidinyl, pyrazolinyl, pyrrolidinyl, pyrrolinyl, tetrahydrofuranyl, tetrahydrothiophenyl, piperidinyl, piperazinyl, and the like. In some embodiments, cycloheteroalkyl groups can be substituted as described herein.

As used herein, “aryl” refers to an aromatic monocyclic hydrocarbon ring system or a polycyclic ring system in which two or more aromatic hydrocarbon rings are fused (i.e., having a bond in common with) together or at least one aromatic monocyclic hydrocarbon ring is fused to one or more cycloalkyl and/or cycloheteroalkyl rings. An aryl group can have 6 to 22 carbon atoms in its ring system (e.g., C₆₋₁₄ aryl group), which can include multiple fused rings. In some embodiments, a polycyclic aryl group can have from 8 to 22 carbon atoms. Any suitable ring position of the aryl group can be covalently linked to the defined chemical structure. Examples of aryl groups having only aromatic carbocyclic ring(s) include phenyl, 1-naphthyl (bicyclic), 2-naphthyl (bicyclic), anthracenyl (tricyclic), phenanthrenyl (tricyclic), pentacenyl (pentacyclic) and like groups. Examples of polycyclic ring systems in which at least one aromatic carbocyclic ring is fused to one or more cycloalkyl and/or cycloheteroalkyl rings include, among others, benzo derivatives of cyclopentane (i.e., an indanyl group, which is a 5,6-bicyclic cycloalkyl/aromatic ring system), cyclohexane (i.e., a tetrahydronaphthyl group, which is a 6,6-bicyclic cycloalkyl/aromatic ring system), imidazoline (i.e., a benzimidazolinyl group, which is a 5,6-bicyclic cycloheteroalkyl/aromatic ring system), and pyran (i.e., a chromenyl group, which is a 6,6-bicyclic cycloheteroalkyl/aromatic ring system). Other examples of aryl groups include benzodioxanyl, benzodioxolyl, chromanyl, indolinyl groups, and the like. In some embodiments, aryl groups can be substituted as described herein. In some embodiments, an aryl group can have one or more halogen substituents, and can be referred to as a “haloaryl” group. Perhaloaryl groups, i.e., aryl groups where all of the hydrogen atoms are replaced with halogen atoms (e.g., —C₆F₅), are included within the definition of “haloaryl.” In certain embodiments, an aryl group is substituted with another aryl group and can be referred to as a biaryl group. Each of the aryl groups in the biaryl group can be substituted as disclosed herein.

As used herein, “arylalkyl” refers to an -alkyl-aryl group, where the arylalkyl group is covalently linked to the defined chemical structure via the alkyl group. An arylalkyl group is within the definition of a —Y—C₆₋₁₄ aryl group, where Y is as defined herein. An example of an arylalkyl group is a benzyl group (—CH₂—C₆H₅). An arylalkyl group can be optionally substituted, i.e., the aryl group and/or the alkyl group, can be substituted as disclosed herein.

As used herein, “heteroaryl” refers to an aromatic monocyclic ring system containing at least one ring heteroatom selected from oxygen (O), nitrogen (N), sulfur (S), silicon (Si), and selenium (Se) or a polycyclic ring system where at least one of the rings present in the ring system is aromatic and contains at least one ring heteroatom. Polycyclic heteroaryl groups include two or more heteroaryl rings fused together and monocyclic heteroaryl rings fused to one or more aromatic carbocyclic rings, non-aromatic carbocyclic rings, and/or non-aromatic cycloheteroalkyl rings. A heteroaryl group, as a whole, can have, for example, 5 to 22 ring atoms and contain 1-5 ring heteroatoms (i.e., 5-20 membered heteroaryl group). The heteroaryl group can be attached to the defined chemical structure at any heteroatom or carbon atom that results in a stable structure. Generally, heteroaryl rings do not contain O—O, S—S, or S—O bonds. However, one or more N or S atoms in a heteroaryl group can be oxidized (e.g., pyridine N-oxide, thiophene S-oxide, thiophene S,S-dioxide). Examples of heteroaryl groups include, for example, the 5- or 6-membered monocyclic and 5-6 bicyclic ring systems shown below:

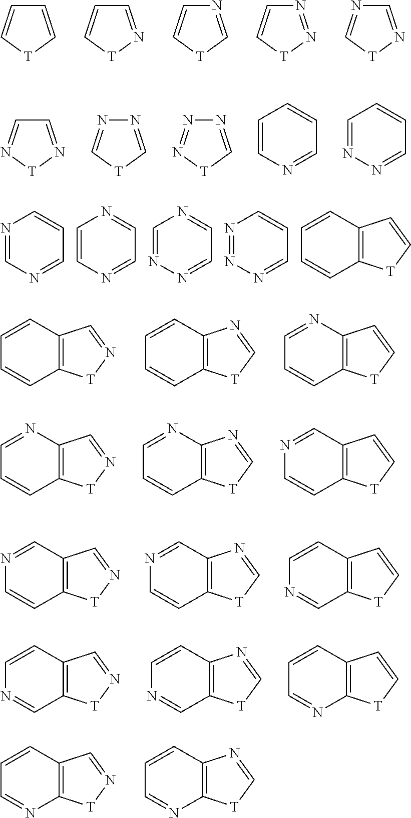

where T is O, S, NH, N-alkyl, N-aryl, N-(arylalkyl) (e.g., N-benzyl), SiH₂, SiH(alkyl), Si(alkyl)₂, SiH(arylalkyl), Si(arylalkyl)₂, or Si(alkyl)(arylalkyl). Examples of such heteroaryl rings include pyrrolyl, furyl, thienyl, pyridyl, pyrimidyl, pyridazinyl, pyrazinyl, triazolyl, tetrazolyl, pyrazolyl, imidazolyl, isothiazolyl, thiazolyl, thiadiazolyl, isoxazolyl, oxazolyl, oxadiazolyl, indolyl, isoindolyl, benzofuryl, benzothienyl, quinolyl, 2-methylquinolyl, isoquinolyl, quinoxalyl, quinazolyl, benzotriazolyl, benzimidazolyl, benzothiazolyl, benzisothiazolyl, benzisoxazolyl, benzoxadiazolyl, benzoxazolyl, cinnolinyl, 1H-indazolyl, 2H-indazolyl, indolizinyl, isobenzofuyl, naphthyridinyl, phthalazinyl, pteridinyl, purinyl, oxazolopyridinyl, thiazolopyridinyl, imidazopyridinyl, furopyridinyl, thienopyridinyl, pyridopyrimidinyl, pyridopyrazinyl, pyridopyridazinyl, thienothiazolyl, thienoxazolyl, thienoimidazolyl groups, and the like. Further examples of heteroaryl groups include 4,5,6,7-tetrahydroindolyl, tetrahydroquinolinyl, benzothienopyridinyl, benzofuropyridinyl groups, and the like. In some embodiments, heteroaryl groups can be substituted as described herein.

Compounds of the present teachings can include a “divalent group” defined herein as a linking group capable of forming a covalent bond with two other moieties. For example, compounds of the present teachings can include a divalent C₁₋₂₀ alkyl group (e.g., a methylene group), a divalent C₂₋₂₀ alkenyl group (e.g., a vinylyl group), a divalent C₂₋₂₀ alkynyl group (e.g., an ethynylyl group). a divalent C₆₋₁₄ aryl group (e.g., a phenylyl group); a divalent 3-14 membered cycloheteroalkyl group (e.g., a pyrrolidylyl), and/or a divalent 5-14 membered heteroaryl group (e.g., a thienylyl group).

The electron-donating or electron-withdrawing properties of several hundred of the most common substituents, reflecting all common classes of substituents have been determined, quantified, and published. The most common quantification of electron-donating and electron-withdrawing properties is in terms of Hammett σ values. Hydrogen has a Hammett σ value of zero, while other substituents have Hammett σ values that increase positively or negatively in direct relation to their electron-withdrawing or electron-donating characteristics. Substituents with negative Hammett σ values are considered electron-donating, while those with positive Hammett σ values are considered electron-withdrawing. See Lange's Handbook of Chemistry, 12th ed., McGraw Hill, 1979, Table 3-12, pp. 3-134 to 3-138, which lists Hammett σ values for a large number of commonly encountered substituents and is incorporated by reference herein.

It should be understood that the term “electron-accepting group” can be used synonymously herein with “electron acceptor” and “electron-withdrawing group”. In particular, an “electron-withdrawing group” (“EWG”) or an “electron-accepting group” or an “electron-acceptor” refers to a functional group that draws electrons to itself more than a hydrogen atom would if it occupied the same position in a molecule. Examples of electron-withdrawing groups include, but are not limited to, halogen or halo (e.g., F, Cl, Br, I), —NO₂, —CN, —NC, —S(R⁰)₂⁺, —N(R⁰)₃⁺, —SO₃H, —SO₂R⁰, —SO₃R⁰, —SO₂NHR⁰, —SO₂N(R⁰)₂, —COOH, —COR⁰, —COOR⁰, —CONHR⁰, —CON(R⁰)₂, C₁₋₄₀ haloalkyl groups, C₆₋₁₄ aryl groups, and 5-14 membered electron-poor heteroaryl groups; where R⁰ is a C₁₋₂₀ alkyl group, a C₂₋₂₀ alkenyl group, a C₂₋₂₀ alkynyl group, a C₁₋₂₀ haloalkyl group, a C₁₋₂₀ alkoxy group, a C₆₋₁₄ aryl group, a C₃₋₁₄ cycloalkyl group, a 3-14 membered cycloheteroalkyl group, and a 5-14 membered heteroaryl group, each of which can be optionally substituted as described herein. For example, each of the C₁₋₂₀ alkyl group, the C₂₋₂₀ alkenyl group, the C₂₋₂₀ alkynyl group, the C₁₋₂₀ haloalkyl group, the C₁₋₂₀ alkoxy group, the C₆₋₁₄ aryl group, the C₃₋₁₄ cycloalkyl group, the 3-14 membered cycloheteroalkyl group, and the 5-14 membered heteroaryl group can be optionally substituted with 1-5 small electron-withdrawing groups such as F, Cl, Br, —NO₂, —CN, —NC, —S(R⁰)₂⁺, —N(R⁰)₃⁺, —SO₃H, —SO₂R⁰, —SO₃R⁰, —SO₂NHR⁰, —SO₂N(R⁰)₂, —COOH, —COR⁰, —COOR⁰, —CONHR⁰, and —CON(R⁰)₂.

It should be understood that the term “electron-donating group” can be used synonymously herein with “electron donor”. In particular, an “electron-donating group” or an “electron-donor” refers to a functional group that donates electrons to a neighboring atom more than a hydrogen atom would if it occupied the same position in a molecule. Examples of electron-donating groups include —OH, —OR⁰, —NH₂, —NHR⁰, —N(R⁰)₂, and 5-14 membered electron-rich heteroaryl groups, where R⁰ is a C₁₋₂₀ alkyl group, a C₂₋₂₀ alkenyl group, a C₂₋₂₀ alkynyl group, a C₆₋₁₄ aryl group, or a C₃₋₁₄ cycloalkyl group.

Various unsubstituted heteroaryl groups can be described as electron-rich (or π-excessive) or electron-poor (or π-deficient). Such classification is based on the average electron density on each ring atom as compared to that of a carbon atom in benzene. Examples of electron-rich systems include 5-membered heteroaryl groups having one heteroatom such as furan, pyrrole, and thiophene; and their benzofused counterparts such as benzofuran, benzopyrrole, and benzothiophene. Examples of electron-poor systems include 6-membered heteroaryl groups having one or more heteroatoms such as pyridine, pyrazine, pyridazine, and pyrimidine; as well as their benzofused counterparts such as quinoline, isoquinoline, quinoxaline, cinnoline, phthalazine, naphthyridine, quinazoline, phenanthridine, acridine, and purine. Mixed heteroaromatic rings can belong to either class depending on the type, number, and position of the one or more heteroatom(s) in the ring. See Katritzky, A. R and Lagowski, J. M., Heterocyclic Chemistry (John Wiley & Sons, New York, 1960).

At various places in the present specification, substituents of monomers A and B are disclosed in groups or in ranges. It is specifically intended that the description include each and every individual subcombination of the members of such groups and ranges. For example, the term “C₁₋₆ alkyl” is specifically intended to individually disclose C₁, C₂, C₃, C₄, C₅, C₆, C₁-C₆, C₁-C₅, C₁-C₄, C₁-C₃, C₁-C₂, C₂-C₆, C₂-C₅, C₂-C₄, C₂-C₃, C₃-C₆, C₃-C₅, C₃-C₄, C₄-C₆, C₄-C₅, and C₅-C₆ alkyl. By way of other examples, an integer in the range of 0 to 40 is specifically intended to individually disclose 0, 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, and 40, and an integer in the range of 1 to 20 is specifically intended to individually disclose 1, 2, 3, 4, 5, 6, 7, 8, 9, 10, 11, 12, 13, 14, 15, 16, 17, 18, 19, and 20. Additional examples include that the phrase “optionally substituted with 1-5 substituents” is specifically intended to individually disclose a chemical group that can include 0, 1, 2, 3, 4, 5, 0-5, 0-4, 0-3, 0-2, 0-1, 1-5, 1-4, 1-3, 1-2, 2-5, 2-4, 2-3, 3-5, 3-4, and 4-5 substituents.

Compounds described herein can contain an stereogenic atom (also referred as a stereocenter) and some of the compounds can contain one or more stereogenic atoms or stereocenters, which can thus give rise to stereoisomers and optical isomers: enantiomers, (stereoisomers which are not superimposable to their mirror images) and diastereomers (stereoisomers which are not mirror images, including geometric isomers due to hindered rotation along multiple bonds). The present teachings include such optical isomers and diastereomers, including their respective resolved enantiomerically or diastereomerically pure isomers (e.g., (+) or (−) stereoisomer) and their racemic mixtures, as well as other mixtures of the enantiomers and diastereomers. In some embodiments, optical isomers can be obtained in enantiomerically enriched or pure form by standard procedures known to those skilled in the art, which include, for example, chiral separation, diastereomeric salt formation, kinetic resolution, and asymmetric synthesis. The present teachings also encompass cis- and trans-isomers of compounds containing alkenyl moieties (e.g., alkenes, azo, and imines). It also should be understood that compounds of the present teachings encompass all possible regioisomers in pure form and mixtures thereof. It may be possible to separate such isomers, for example, using standard separation procedures known to those skilled in the art, for example, column chromatography, thin-layer chromatography, simulated moving-bed chromatography, and high-performance liquid chromatography. However, mixtures of regioisomers can be used similarly to the uses of each individual regioisomer of the present teachings.

It is specifically contemplated that the depiction of one regioisomer includes any other regioisomers and any regioisomeric mixtures unless specifically stated otherwise.

As used herein, a “leaving group” (“LG”) refers to a charged or uncharged atom (or group of atoms) that can be displaced as a stable species as a result of, for example, a substitution or elimination reaction. Examples of leaving groups include, but are not limited to, halogen (e.g., Cl, Br, I), azide (N₃), thiocyanate (SCN), nitro (NO₂), cyanate (CN), water (H₂O), ammonia (NH₃), and sulfonate groups (e.g., OSO₂—R, wherein R can be a C₁₋₁₀ alkyl group or a C₆₋₁₄ aryl group each optionally substituted with 1-4 groups independently selected from a C₁₋₁₀ alkyl group and an electron-withdrawing group) such as tosylate (toluenesulfonate, OTs), mesylate (methanesulfonate, OMs), brosylate (p-bromobenzenesulfonate, OBs), nosylate (4-nitrobenzenesulfonate, ONs), and triflate (trifluoromethanesulfonate, OTf).

Throughout the specification, structures may or may not be presented with chemical names. Where any question arises as to nomenclature, the structure prevails.

The present teachings relate to molecular and polymeric compounds that can be used as organic semiconductor materials. The present compounds can have good solubility in various common organic solvents and good stability in air. When incorporated into optical, electronic or optoelectronic devices including, but not limited to, organic photovoltaic or solar cells, organic light emitting diodes, and organic field effect transistors, the present compounds can confer various desirable performance properties.

More specifically, the present teachings provide semiconducting compounds that include one or more optionally substituted phenazine moieties. The optionally substituted phenazine moieties can be represented by formula (I):

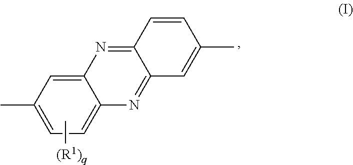

wherein:
R¹, at each occurrence, independently can be selected from halogen, —CN, NO₂, R², -L-R³, OH, OR², OR³, NH₂, NHR², N(R²)₂, NHR³, NR²R³, N(R³)₂, SH, SR², SR³, S(O)₂OH, —S(O)₂OR², —S(O)₂OR³, C(O)H, C(O)R², C(O)R³, C(O)OH, C(O)OR², C(O)OR³, C(O)NH₂, C(O)NHR², C(O)N(R²)₂, C(O)NHR³, C(O)NR²R³, C(O)N(R³)₂, SiH₃, SiH(R²)₂, SiH₂(R²), and Si(R²)₃, wherein L is selected from a divalent C₁₋₄₀ alkyl group, a divalent C₂₋₄₀ alkenyl group, a divalent C₁₋₄₀ haloalkyl group, and a covalent bond; R² is selected from a C₁₋₄₀ alkyl group, a C₂₋₄₀ alkenyl group, a C₂₋₄₀ alkynyl group, and a C₁₋₄₀ haloalkyl group; and R³ is selected from a C₃₋₁₀ cycloalkyl group, a C₆₋₁₄ aryl group, a C₆₋₁₄ haloaryl group, a 3-12 membered cycloheteroalkyl group, and a 5-14 membered heteroaryl group, each of which optionally is substituted with 1-5 substituents selected from halogen, —CN, NO₂, R², OR², and SR²; and q is 0 or an integer selected from 1, 2, 3, 4, 5 or 6.

In some embodiments, q is 0; that is, the phenazine moiety is not substituted. In other embodiments, q is an integer selected from 1, 2, 3, 4, 5 and 6, and each R¹ independently can be selected from F, Cl, Br, I, —CN, —NO₂, R², OR², and SR², where R² can be selected from a linear or branched C₁₋₁₀ alkyl group, a linear or branched C₂₋₁₀ alkenyl group, and a linear or branched C₁₋₁₀ haloalkyl group. In preferred embodiments, q is 2, 4, or 6. In particular embodiments, le can be selected from F, Cl, Br, I, —CN, —NO₂, CH₃, OCH₃, CF₃, and a phenyl group.

In some embodiments, the present compound is a polymer having one or more repeating units M₁, where each M₁ includes at least one optionally substituted phenazine moiety represented by formula (I), and where the polymer has a degree of polymerization (n) ranging from at least 3.

Other than phenazine moieties, repeating units M₁ optionally can include one or more spacers (Sp) which can be either non-cyclic (Z) or cyclic, particularly monocyclic (Ar) or polycyclic (pi-2), which together with the phenazine moieties provide a pi-extended conjugated group. For example, M₁ can be selected from:

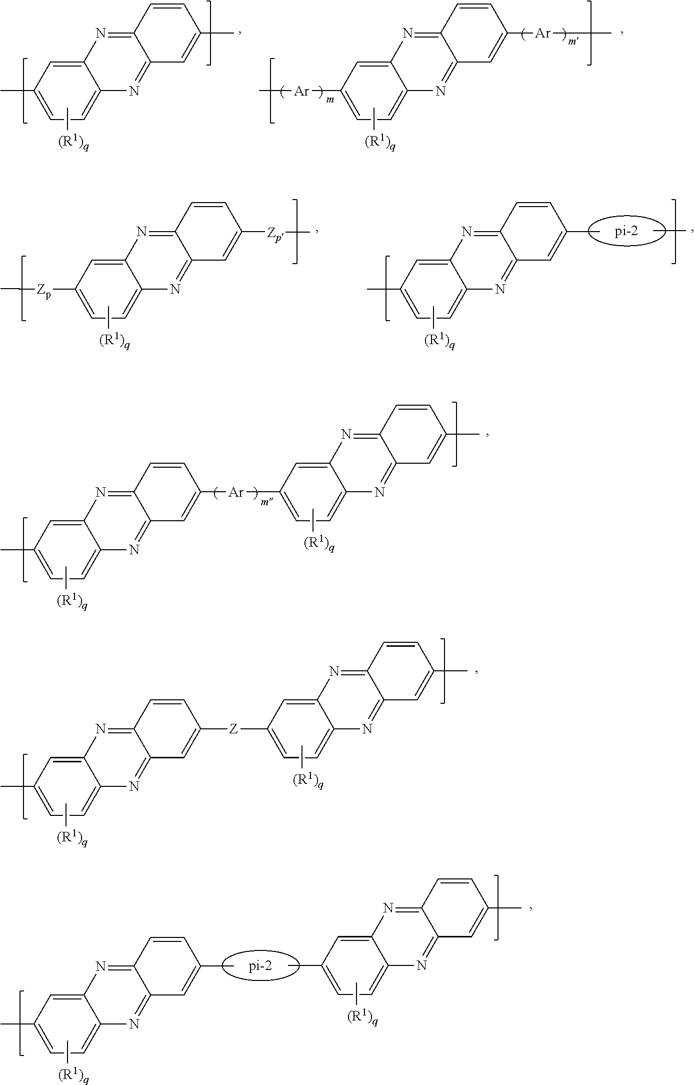

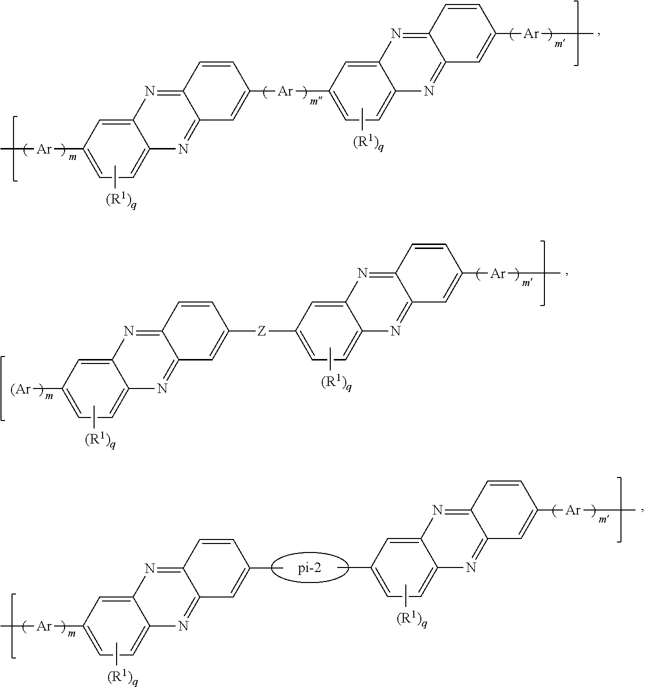

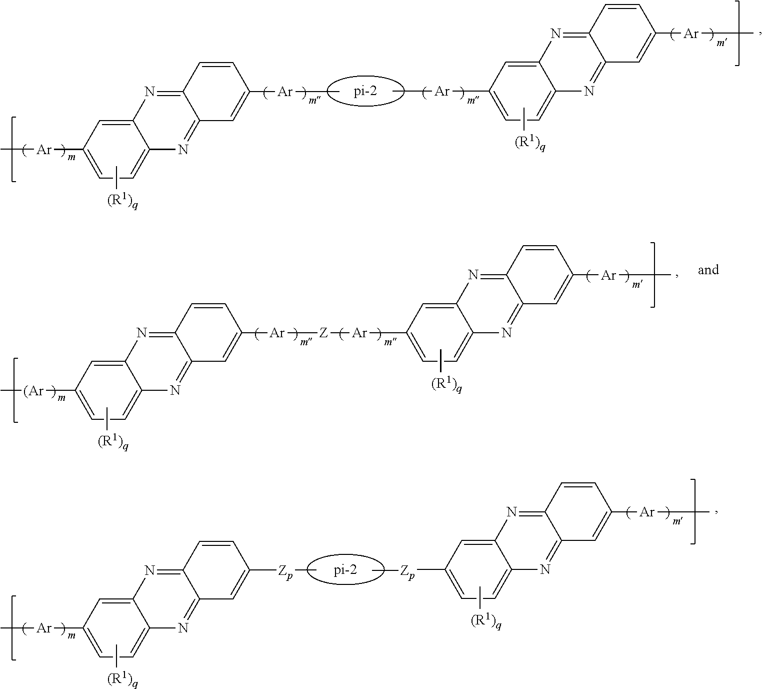

wherein:
R¹ is as defined herein;
pi-2 is an optionally substituted conjugated polycyclic moiety;
Ar, at each occurrence, is independently an optionally substituted 5- or 6-membered aryl or heteroaryl group;
Z is a conjugated noncyclic linker;
m and m′ independently are 0, 1, 2, 3, 4, 5 or 6, provided that at least one of m and m′ is not 0;
m″ is 1, 2, 3, 4, 5 or 6;
p and p′ independently are 0 and 1, provided that at least one of p and p′ is 1; and
q is 0, 1, 2, 3, 4, 5 or 6.

To illustrate, the polycyclic conjugated moiety, pi-2, can be an optionally substituted C₈₋₂₆ aryl group or 8-26 membered heteroaryl group. For example, pi-2 can have a planar and pi-extended conjugated cyclic core which can be optionally substituted as disclosed herein. Examples of suitable cyclic cores include naphthalene, anthracene, tetracene, pentacene, perylene, pyrene, coronene, fluorene, indacene, indenofluorene, and tetraphenylene, as well as their analogs in which one or more carbon atoms can be replaced with a heteroatom such as O, S, Si, Se, N, or P.

In certain embodiments, pi-2 can be selected from:

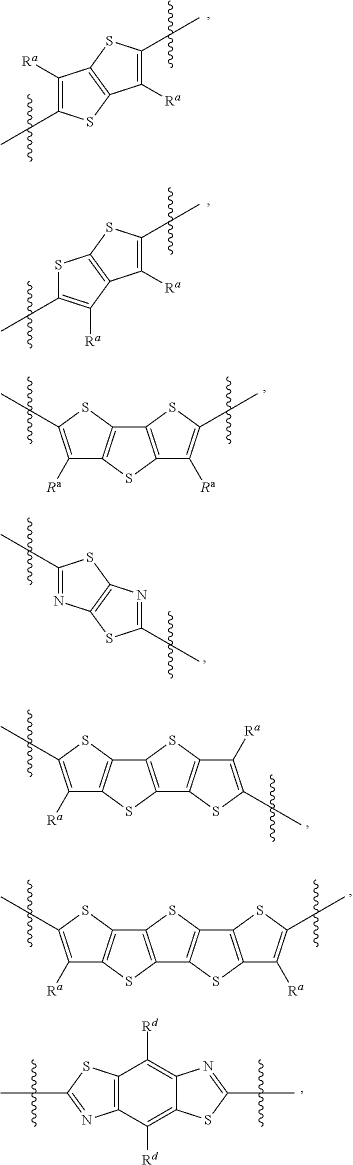

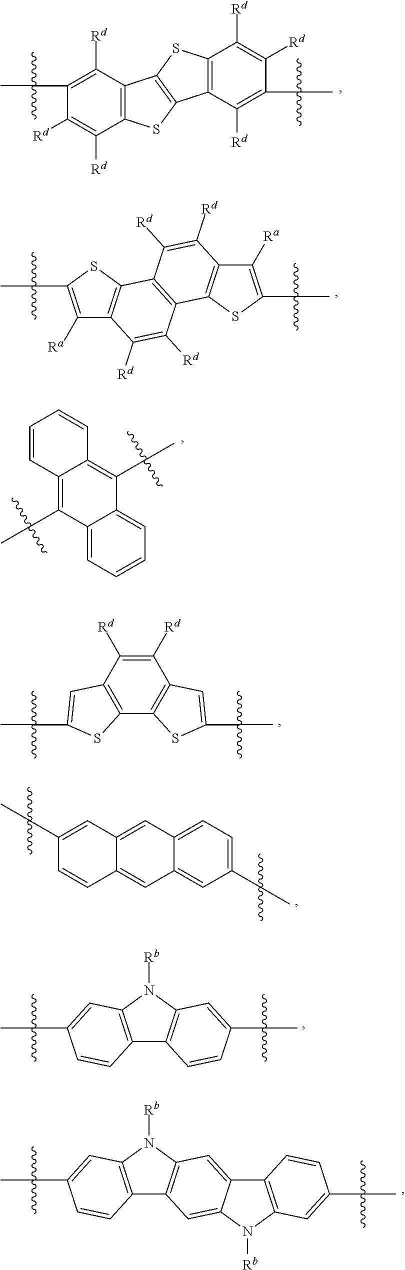

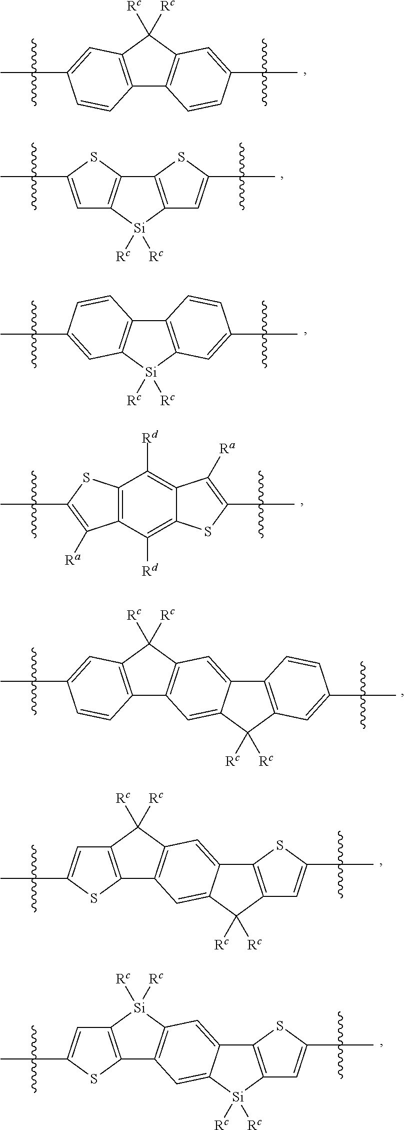

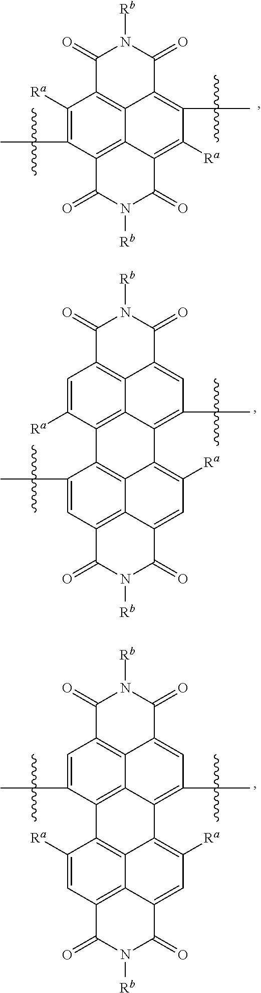

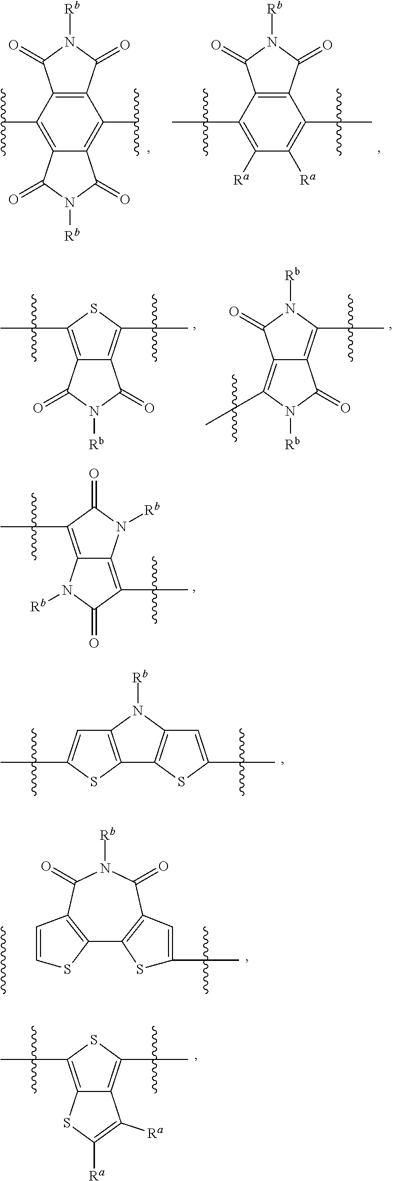

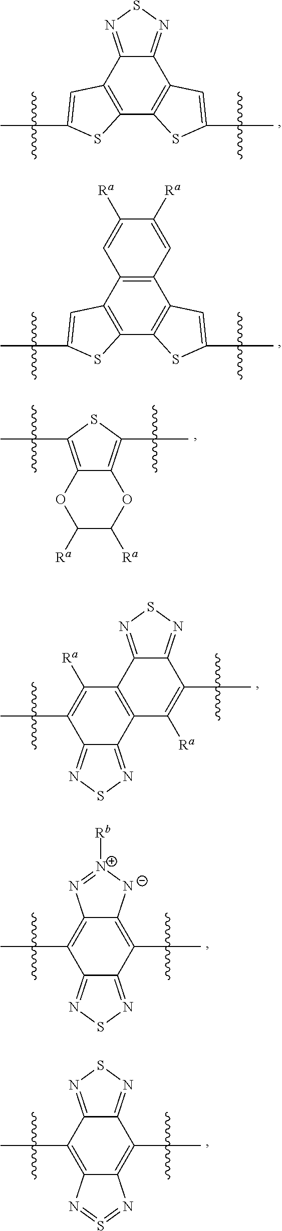

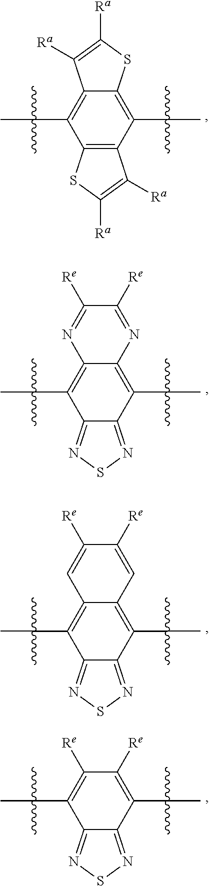

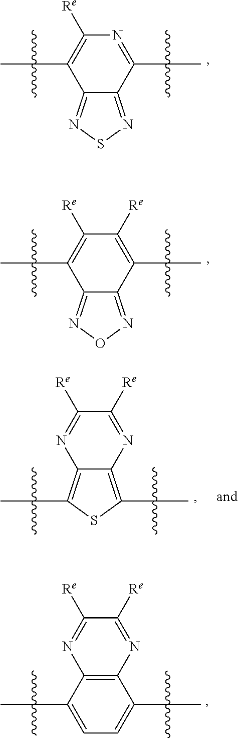

wherein:
R^{a} is selected from the group consisting of H, F, Cl, —CN, R, —OR, —SR, —C(O)R, —OC(O)R, and —C(O)OR;
R^{b} is selected from the group consisting of H, R, and -L′-R^{f};

### R^{c} is H or R;

R^{d} is selected from the group consisting of H, F, Cl, —CN, R, —OR, —SR, —C(O)R, —OC(O)R, —C(O)OR, and -L′-R^{f};
R^{e} is selected from the group consisting of H, F, Cl, —CN, R, —OR, —SR, —C(O)R, —OC(O)R, —C(O)OR, and R^{f};
R^{f} is a C₆₋₂₀ aryl group or a 5-20-membered heteroaryl group, each optionally substituted with 1-8 groups independently selected from the group consisting of F, Cl, —CN, R, —OR, and SR;
L′ is selected from the group consisting of —O—, —S—, —C(O)—, —OC(O)—, —C(O)O—, and a covalent bond; and
R is selected from the group consisting of a C₁₋₄₀ alkyl group, a C₁₋₄₀ haloalkyl group, a C₂₋₄₀ alkenyl group, and a C₂₋₄₀ alkynyl group.

The monocyclic conjugated moiety, Ar, at each occurrence, independently can be an optionally substituted 5- or 6-membered (hetero)aryl group. For example, Ar can be selected from the group consisting of a phenyl group, a thienyl group, a thiazolyl group, an isothiazolyl group, a thiadiazolyl group, a furyl group, an oxazolyl group, an isoxazolyl group, an oxadiazolyl group, a pyrrolyl group, a triazolyl group, a tetrazolyl group, a pyrazolyl group, an imidazolyl group, a pyridyl group, a pyrimidyl group, a pyridazinyl group, and a pyrazinyl group, each of which optionally can be substituted with 1-4 R⁵ groups independently selected from a halogen, CN, a C₁₋₄₀ alkyl group, a C₁₋₄₀ haloalkyl group, a C₁₋₄₀ alkoxy group, and a C₁₋₄₀ alkylthio group.

By way of example, each Ar in (Ar)ₘ, (Ar)_{m′}, and/or (Ar)_{m″} that is present (i.e., when m, m′, and/or m″ is 1, 2, 3, 4, 5 or 6) can be represented by:

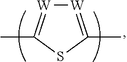

where each W independently can be selected from N, CH, and CR⁴, wherein R⁴ can be selected from F, Cl, —CN, R², OR², SR², C(O)R², OC(O)R², and C(O)OR², where R² is as defined herein. To illustrate further, (Ar)ₘ, (Ar)_{m′}, or (Ar)_{m″} when present can be selected from:

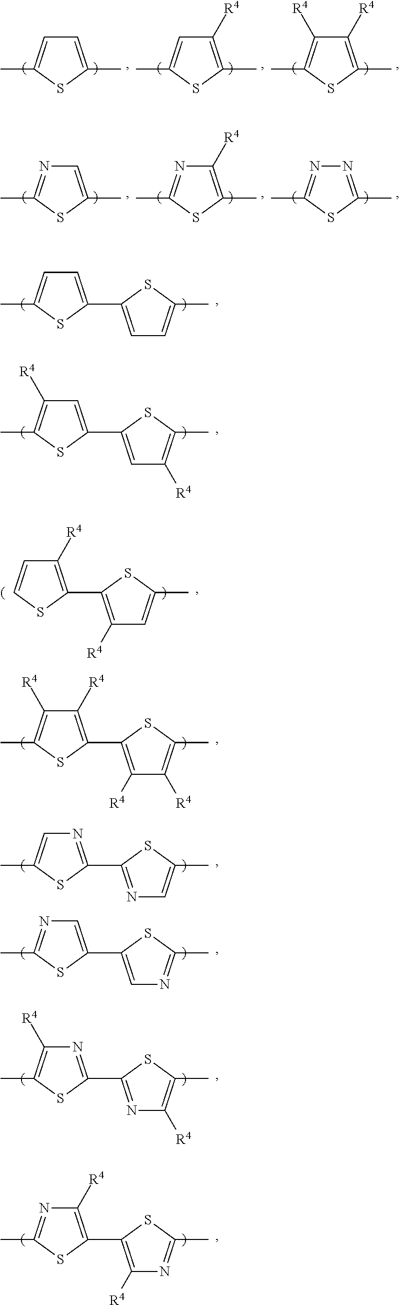

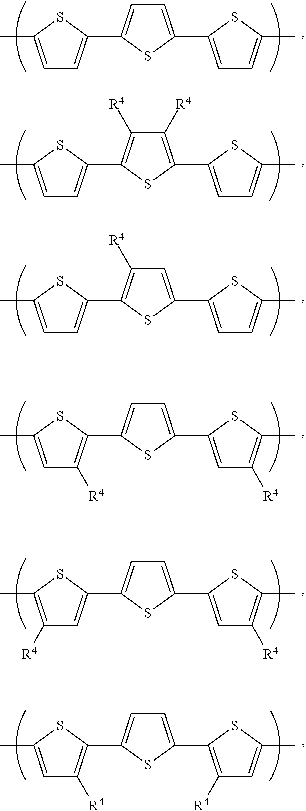

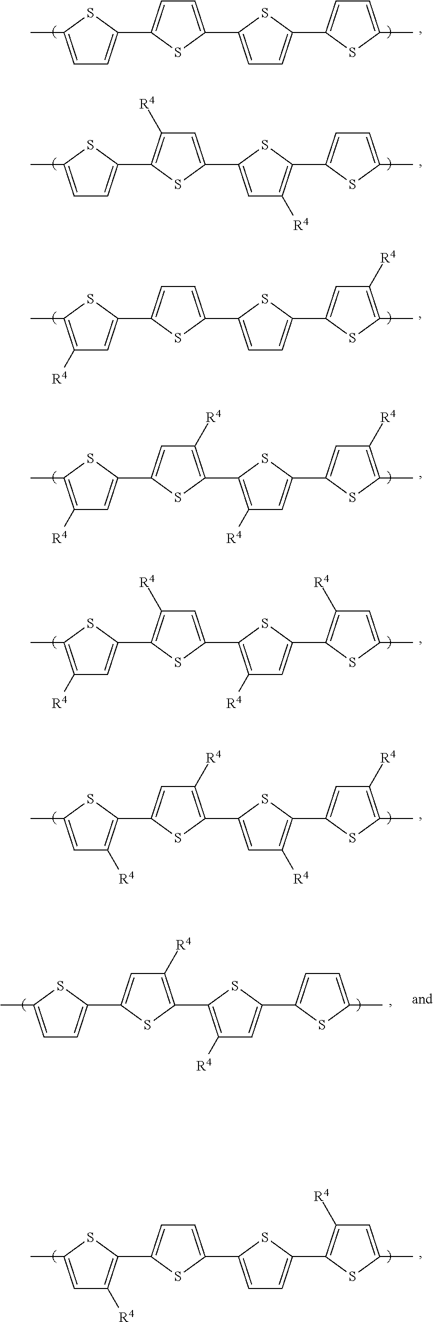

where, for example, each R⁴ independently is selected from F, Cl, CN, R², OR², and SR², where R² is a linear or branched C₁₋₄₀ alkyl or haloalkyl group.

The conjugated noncyclic linker, Z, can include one or more double or triple bonds. For example, Z can be a divalent ethenyl group (i.e., having one double bond), a divalent ethynyl group (i.e., having one tripe bond), a C₄₋₄₀ alkenyl or alkynyl group that includes two or more conjugated double or triple bonds, or some other linear or branched conjugated systems that can include heteroatoms such as Si, N, P, and the like. In certain embodiments, Z can be selected from:

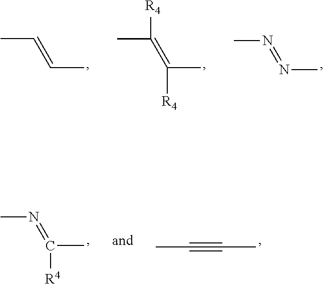

wherein R⁴ is as defined herein. In particular embodiments, Z can be selected from:

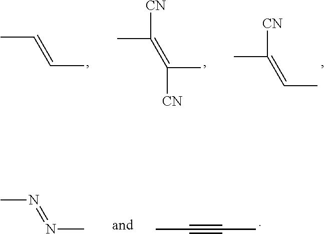

In preferred embodiments, the present polymer includes a repeating unit M₁ selected from the group consisting of:

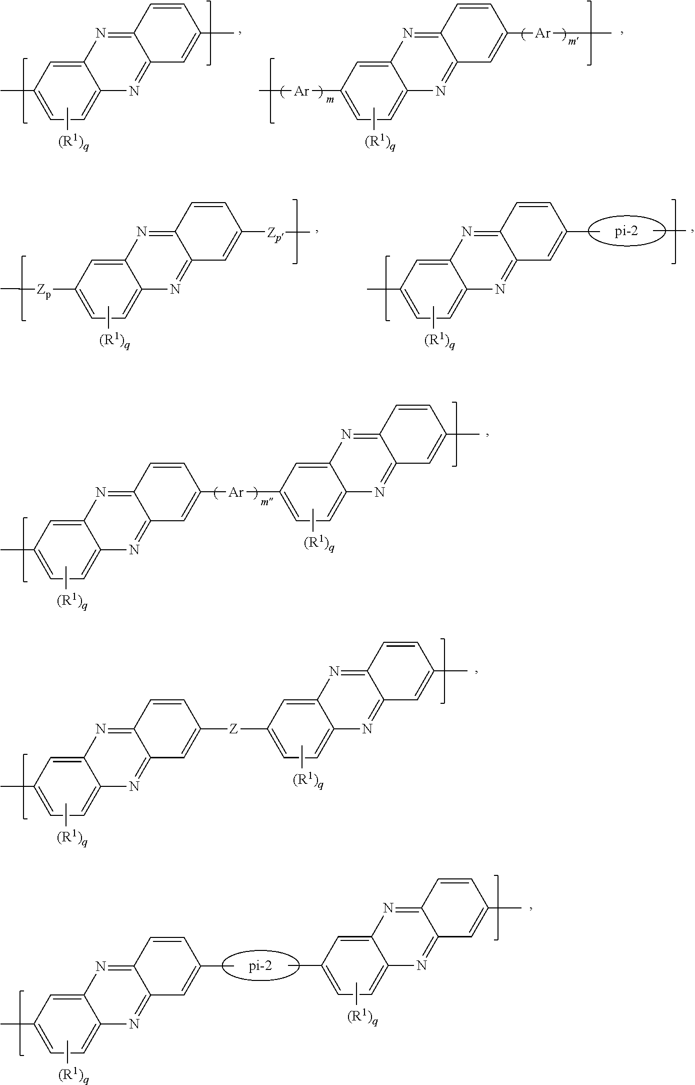

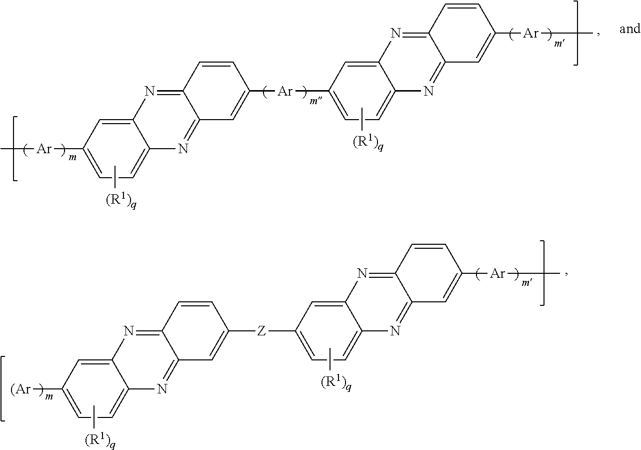

where Ar, R¹, Z, pi-2, m, m′, m″, p, p′, and q are as defined herein.

In the various embodiments described above, each divalent phenazine moiety of formula (I):

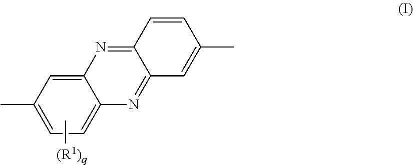

can be represented more specifically by formula (II):

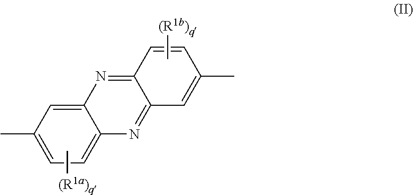

wherein R^{1a} and R^{1b} can be identical or different; and q′, at each occurrence, independently, can be 0 or an integer selected from 1, 2, and 3. In preferred embodiments, at least one of q′ is not 0. To illustrate further, the divalent phenazine moiety in the various embodiments described above can be selected from:

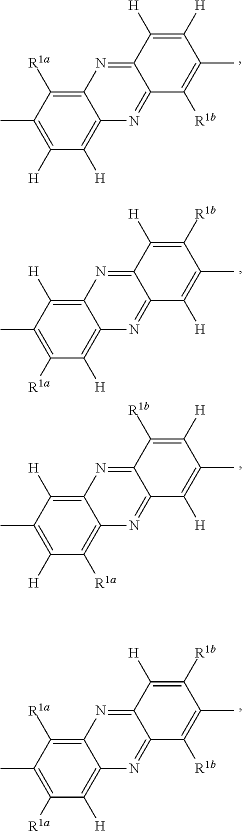

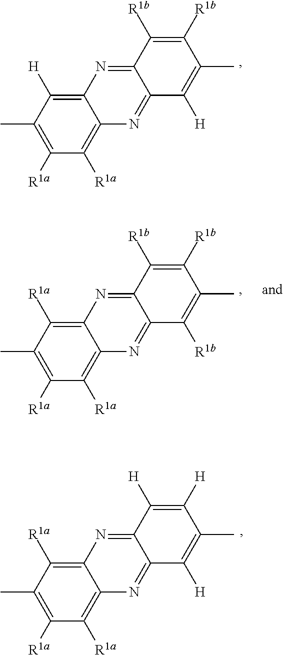

wherein:
R^{1a} and R^{1b} independently can be selected from halogen, —CN, NO₂, R², -L-R³, OH, OR², OR³, NH₂, NHR², N(R²)₂, NHR³, NR²R³, N(R³)₂, SH, SR², SR³, S(O)₂OH, —S(O)₂OR², —S(O)₂OR³, C(O)H, C(O)R², C(O)R³, C(O)OH, C(O)OR², C(O)OR³, C(O)NH₂, C(O)NHR², C(O)N(R²)₂, C(O)NHR³, C(O)NR²R³, C(O)N(R³)₂, SiH₃, SiH(R²)₂, SiH₂(R²), and Si(R²)₃, wherein L is selected from a divalent C₁₋₄₀ alkyl group, a divalent C₂₋₄₀ alkenyl group, a divalent C₁₋₄₀ haloalkyl group, and a covalent bond; R² is selected from a C₁₋₄₀ alkyl group, a C₂₋₄₀ alkenyl group, a C₂₋₄₀ alkynyl group, and a C₁₋₄₀ haloalkyl group; and R³ is selected from a C₃₋₁₀ cycloalkyl group, a C₆₋₁₄ aryl group, a C₆₋₁₄ haloaryl group, a 3-12 membered cycloheteroalkyl group, and a 5-14 membered heteroaryl group, each of which optionally is substituted with 1-5 substituents selected from halogen, —CN, NO₂, R², OR², and SR². In particular embodiments, the divalent phenazine moiety in the various embodiments described above can be selected from:

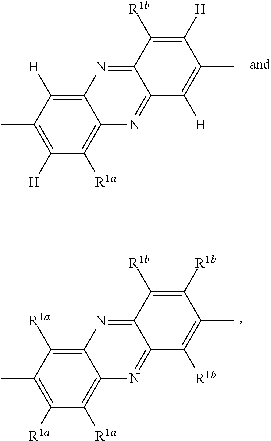

wherein R^{1a} and R^{1b} independently can be selected from F, Cl, Br, I, —CN, —NO₂, R², OR², and SR², where R² can be selected from a linear or branched C₁₋₁₀ alkyl group, a linear or branched C₂₋₁₀ alkenyl group, and a linear or branched C₁₋₁₀ haloalkyl group. In preferred embodiments, R^{1a} and R^{1b} independently can be selected from F, Cl, Br, I, —CN, —NO₂, CH₃, OCH₃, CF₃, and a phenyl group.

More preferably, M₁ is selected from:

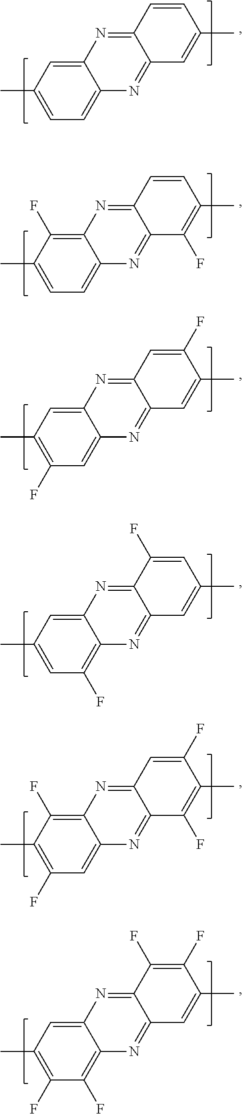

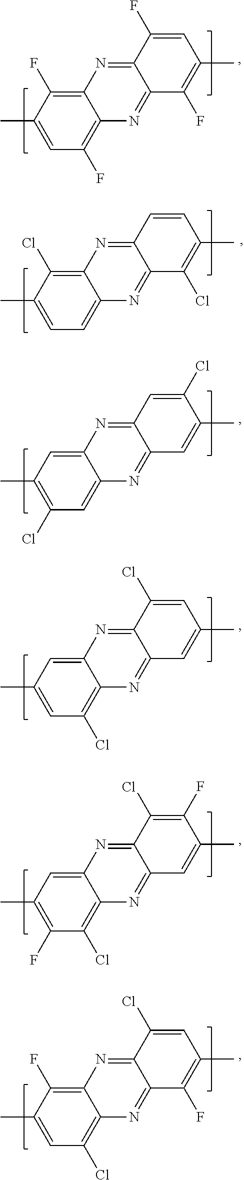

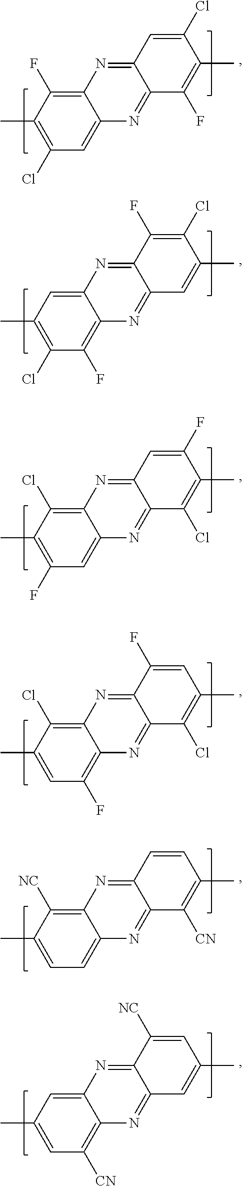

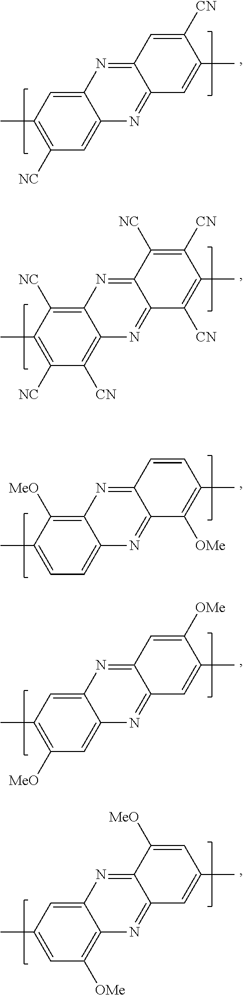

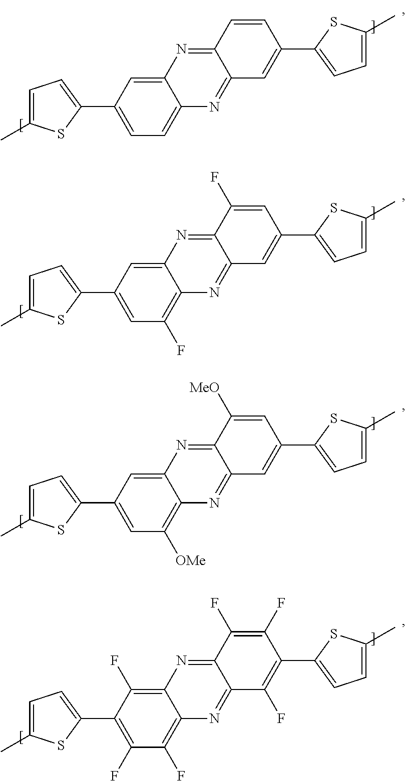

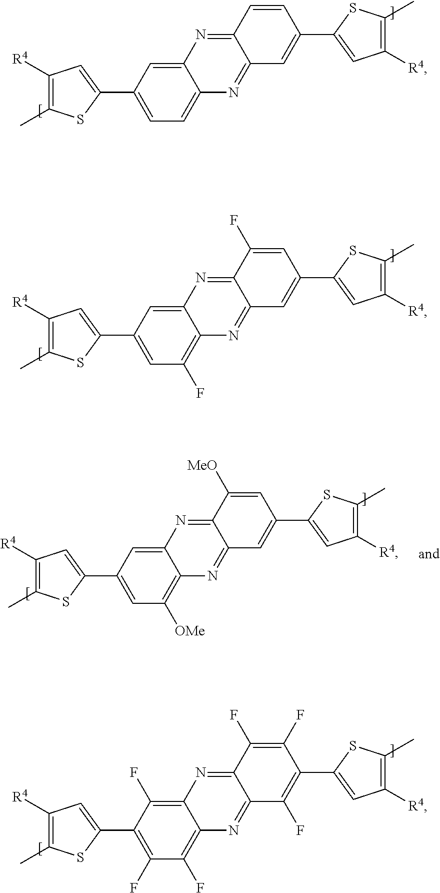

wherein R⁴ can be selected from R², OR², and SR², where R² is a linear or branched C₁₋₄₀ alkyl or haloalkyl group.

In certain embodiments, the present polymer can be a homopolymer including only identical repeating units M₁. In other embodiments, the polymer can be a copolymer including two or more different repeating units M₁. In yet other embodiments, the polymer can be a copolymer including at least one repeating unit M₁ and at least one other repeating unit M₂ that does not include any phenazine moiety. Such M₂ units can include one or more non-cyclic (Z), monocyclic (Ar), and/or polycyclic (pi-2) conjugated linkers, which together provide a pi-extended conjugated group. For example, M₂ can be selected from:

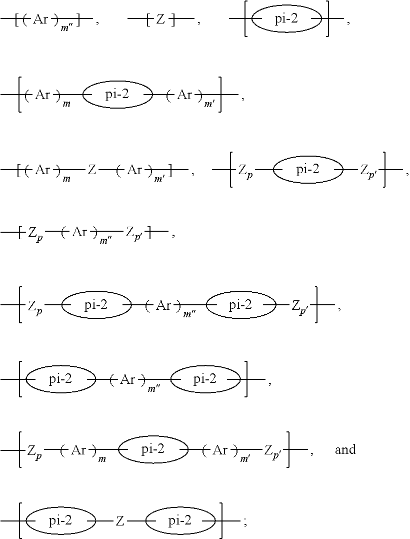

wherein pi-2, Ar, Z, m, m′, m″, p, and p′ are as defined herein.

To illustrate, in certain embodiments, M₂ can have the formula:

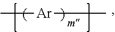

wherein m″ is selected from 1, 2, 3, or 4; and Ar is as defined herein. For example, M₂ can be selected from the group consisting of:

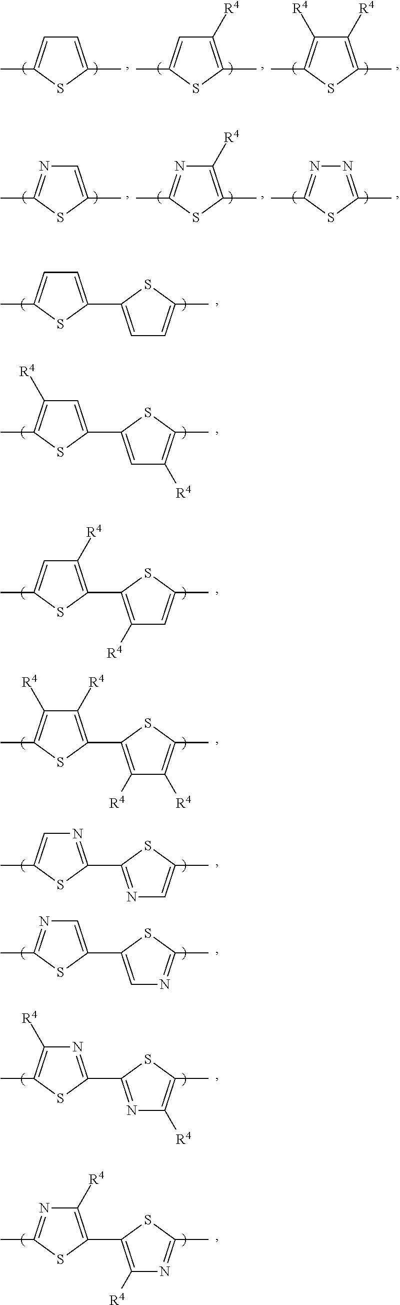

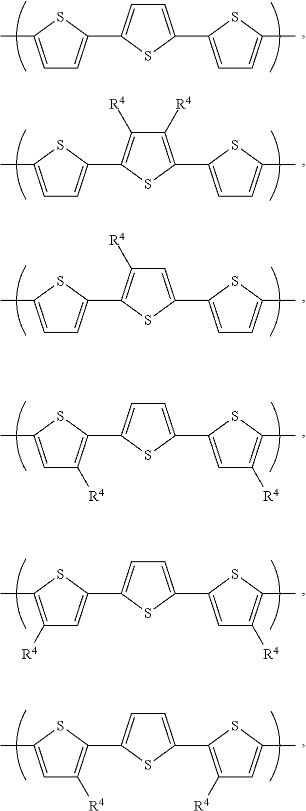

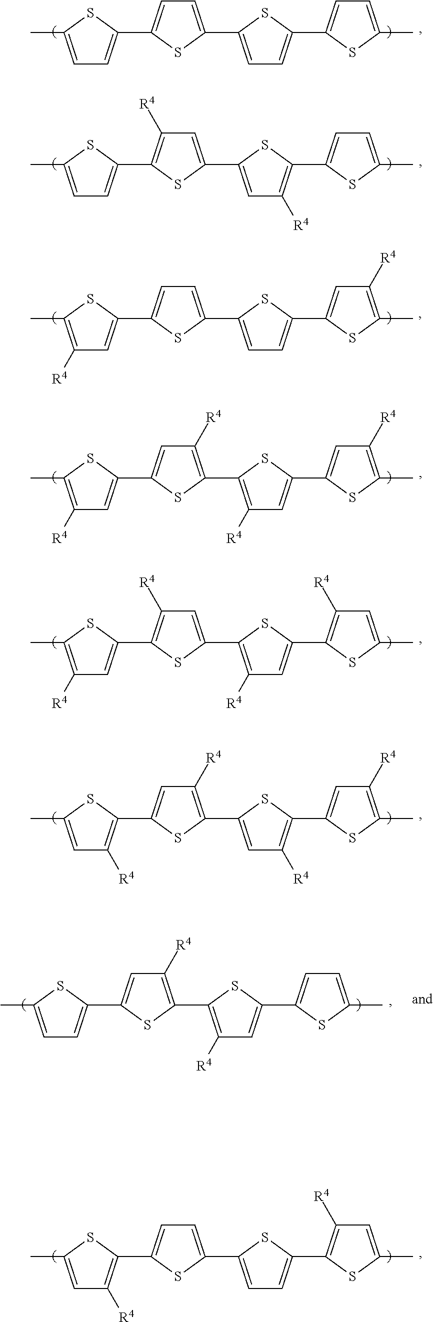

where, for example, each R⁴ independently is selected from F, Cl, CN, R², OR², and SR², where R² is a linear or branched C₁₋₄₀ alkyl or haloalkyl group.

In other embodiments, M₂ can have the formula:

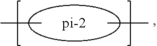

wherein pi-2 can be selected from:

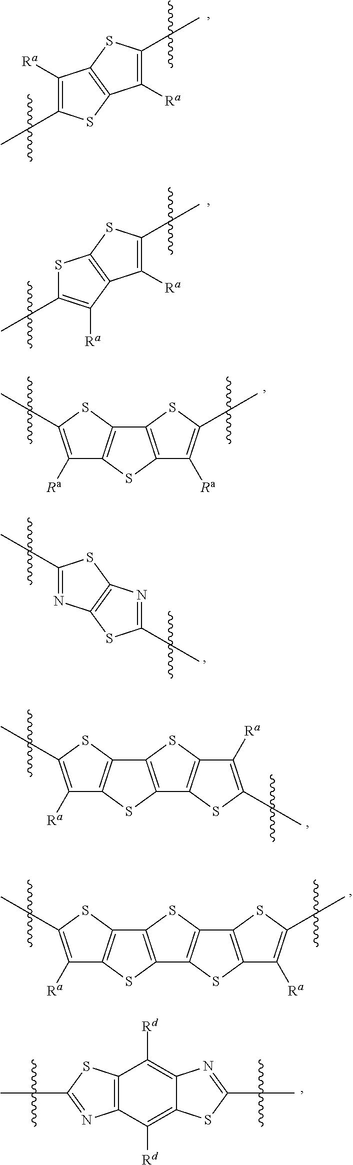

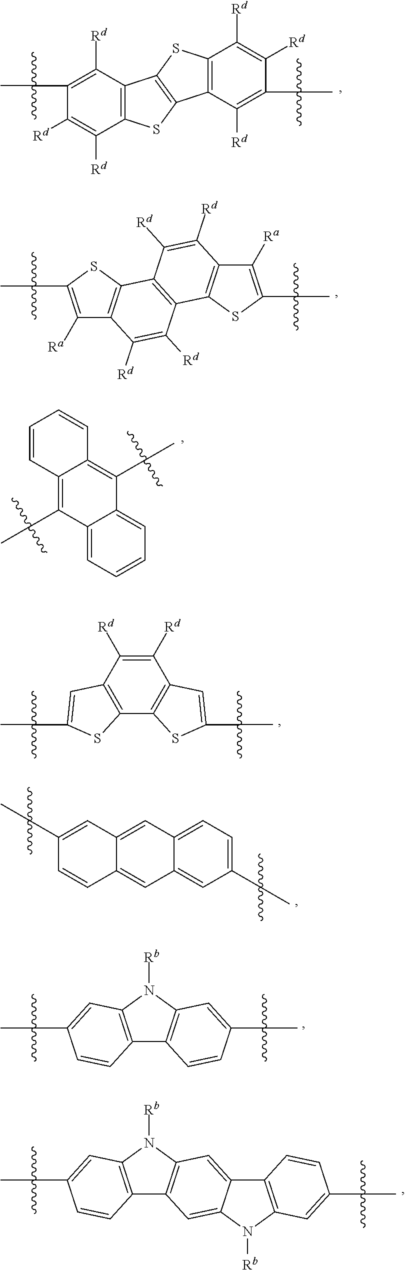

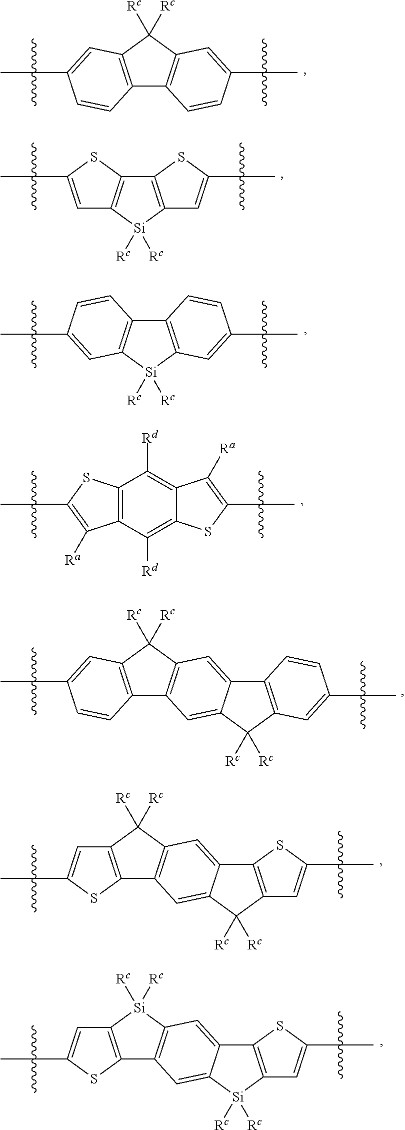

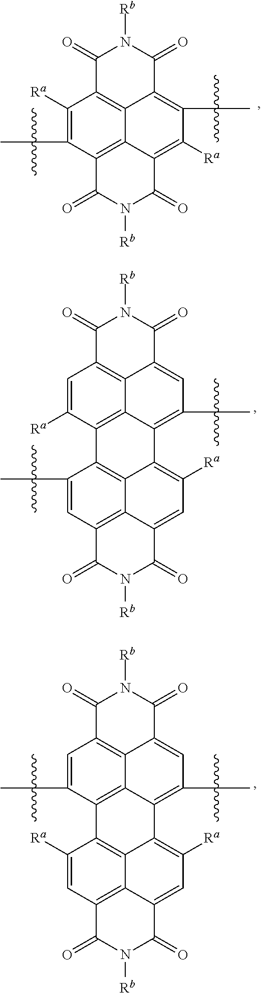

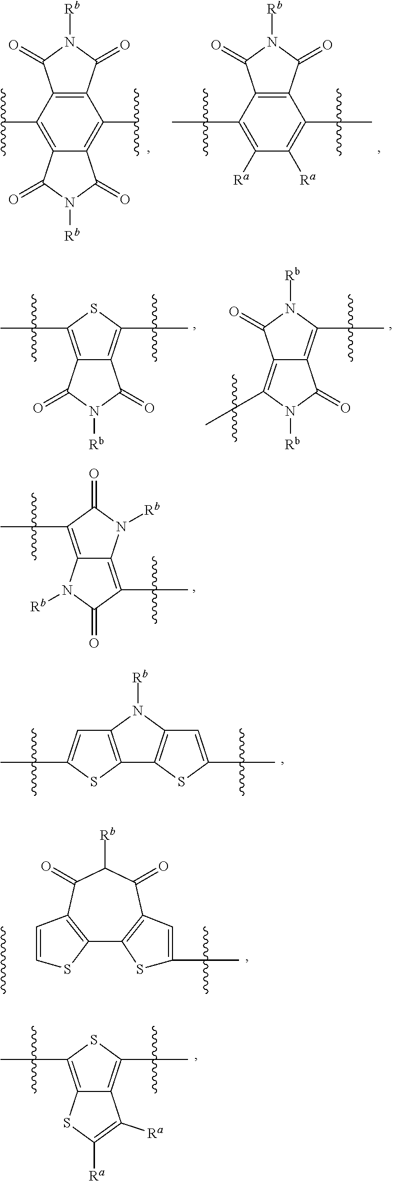

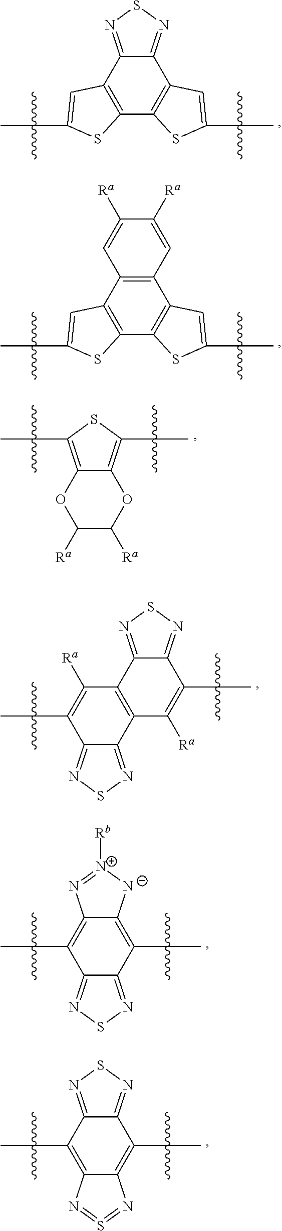

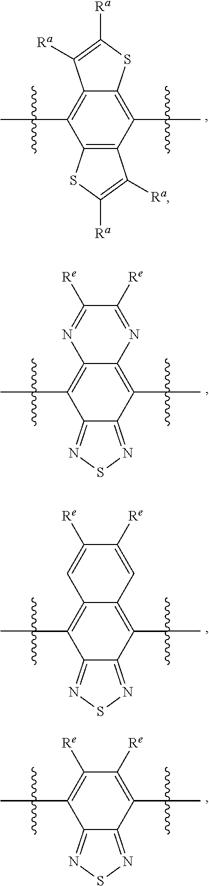

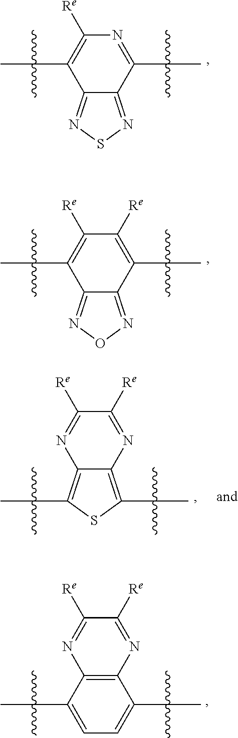

wherein:
R^{a} is selected from the group consisting of H, F, Cl, —CN, R, —OR, —SR, —C(O)R, —OC(O)R, and —C(O)OR;
R^{b} is selected from the group consisting of H, R, and -L′-R^{f};

### R^{c} is H or R;

R^{d} is selected from the group consisting of H, F, Cl, —CN, R, —OR, —SR, —C(O)R, —OC(O)R, —C(O)OR, and -L′-R^{f};
R^{e} is selected from the group consisting of H, F, Cl, —CN, R, —OR, —SR, —C(O)R, —OC(O)R, —C(O)OR, and R^{f};
R^{f} is a C₆₋₂₀ aryl group or a 5-20-membered heteroaryl group, each optionally substituted with 1-8 groups independently selected from the group consisting of F, Cl, —CN, R, —OR, and —SR;
L′ is selected from the group consisting of —O—, —S—, —C(O)—, —OC(O)—, —C(O)O—, and a covalent bond; and
R is selected from the group consisting of a C₁₋₄₀ alkyl group, a C₁₋₄₀ haloalkyl group, a C₂₋₄₀ alkenyl group, and a C₂₋₄₀ alkynyl group.

In yet other embodiments, M₂ can have the formula:

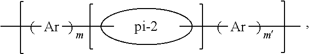

wherein Ar, pi-2, m and m′ are as defined herein. Preferably, (Ar)ₘ and (Ar)_{m′} are selected from:

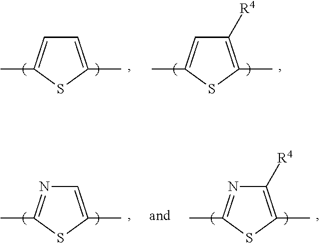

where R⁴ is as defined herein, and pi-2 is selected from:

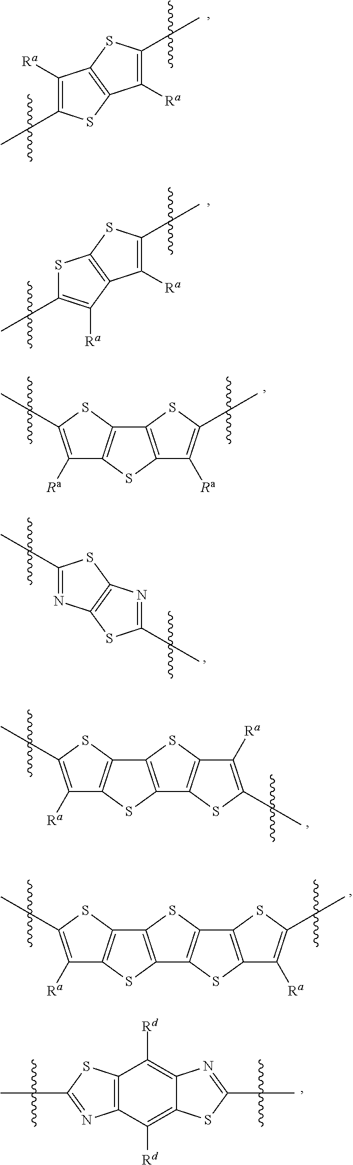

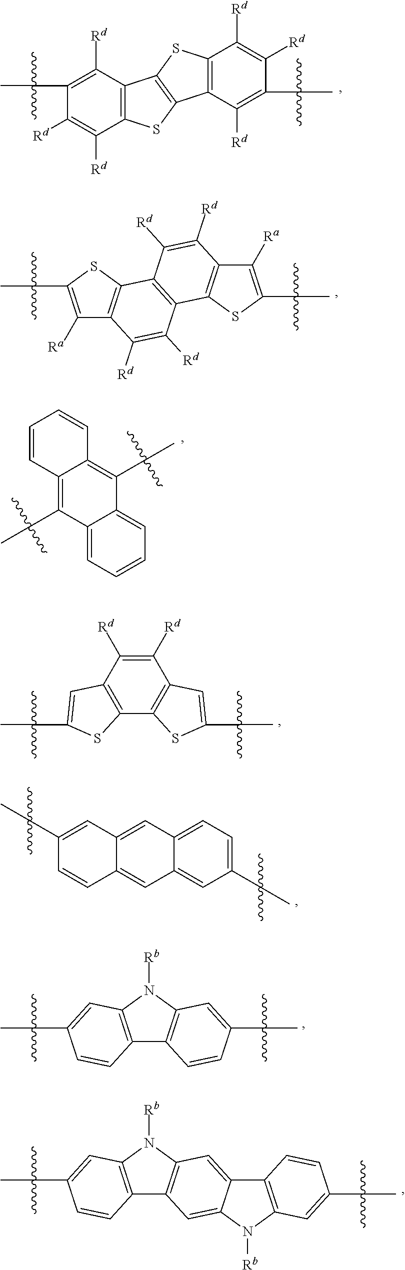

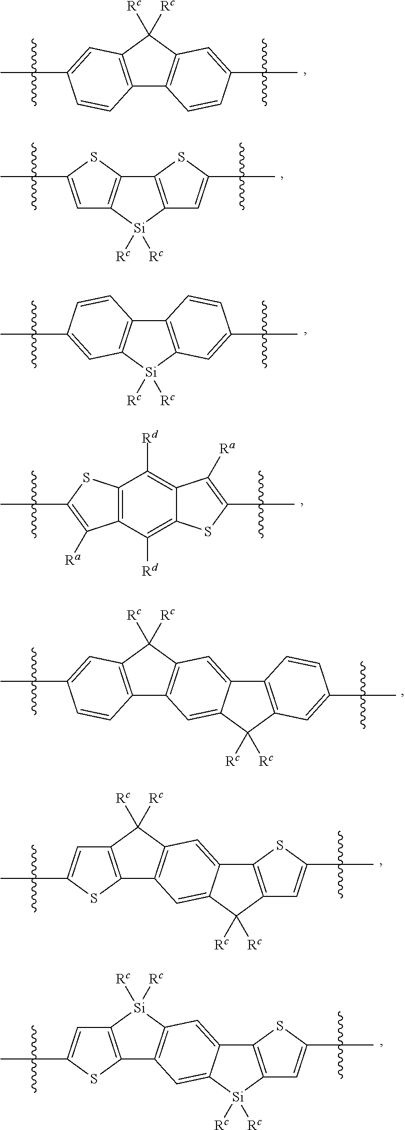

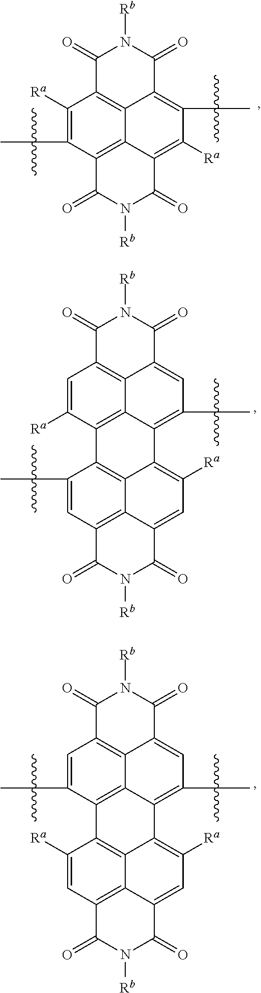

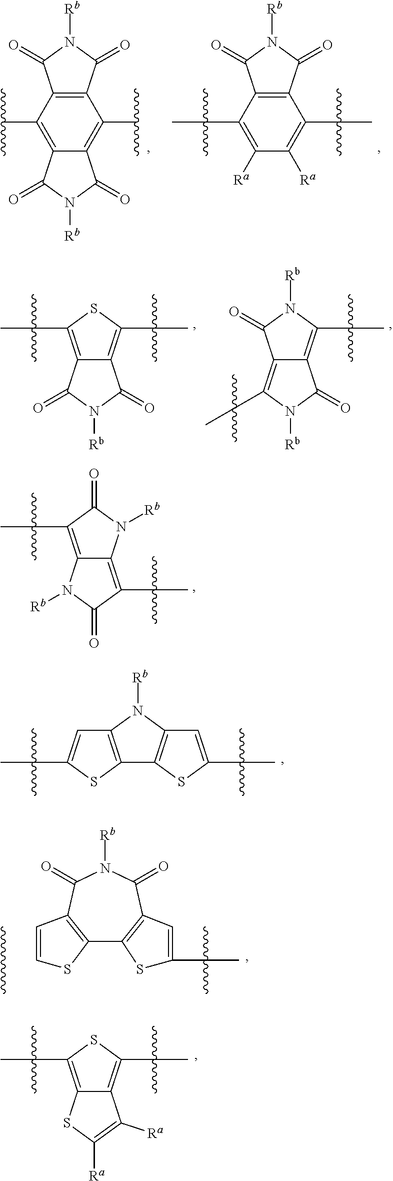

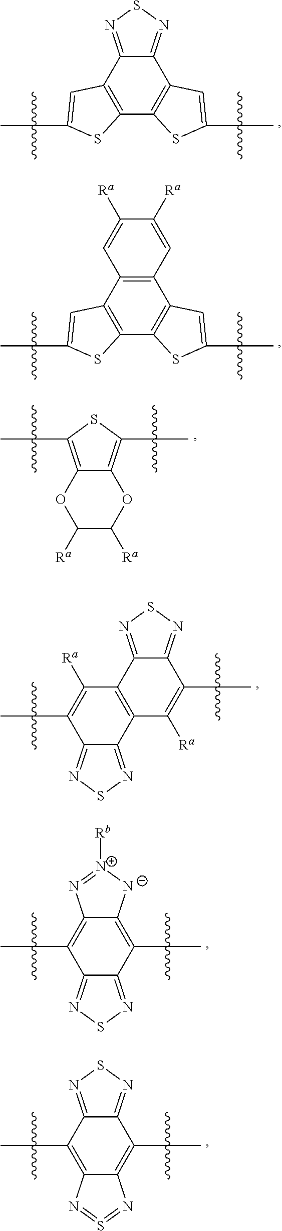

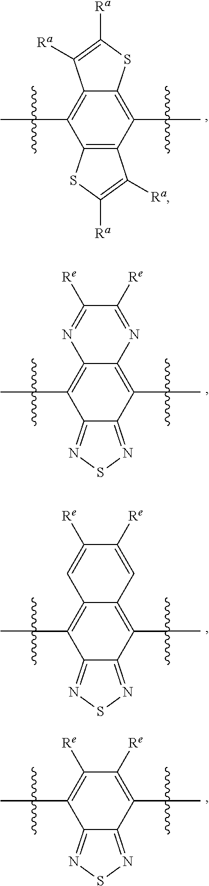

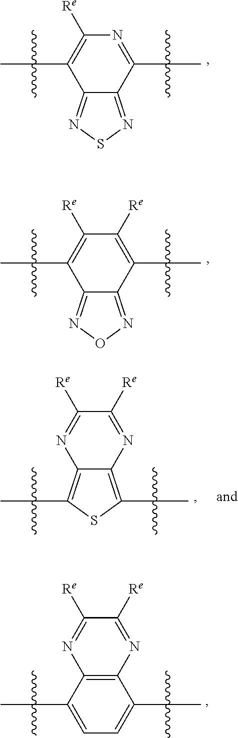

wherein:
R^{a} is selected from the group consisting of H, F, Cl, —CN, R, —OR, —SR, —C(O)R, —OC(O)R, and —C(O)OR;
R^{b} is selected from the group consisting of H, R, and -L′-R^{f};

### R^{c} is H or R;

R^{d} is selected from the group consisting of H, F, Cl, —CN, R, —OR, —SR, —C(O)R, —OC(O)R, —C(O)OR, and -L′-R^{f};
R^{e} is selected from the group consisting of H, F, Cl, —CN, R, —OR, —SR, —C(O)R, —OC(O)R, —C(O)OR, and R^{f};
R^{f} is a C₆₋₂₀ aryl group or a 5-20-membered heteroaryl group, each optionally substituted with 1-8 groups independently selected from the group consisting of F, Cl, —CN, R, —OR, and —SR;
L′ is selected from the group consisting of —O—, —S—, —C(O)—, —OC(O)—, —C(O)O—, and a covalent bond; and
R is selected from the group consisting of a C₁₋₄₀ alkyl group, a C₁₋₄₀ haloalkyl group, a C₂₋₄₀ alkenyl group, and a C₂₋₄₀ alkynyl group.

In other embodiments, M₂ can have a formula selected from:

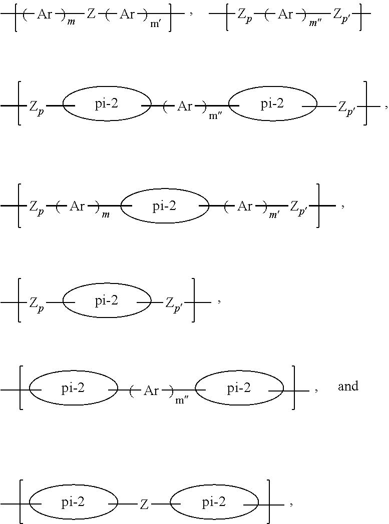

wherein m, m′ and m″ independently are 1, 2, 3 or 4; and Ar, pi-2 and Z are as defined herein. In such embodiments, M₂ can be selected from the group consisting of:

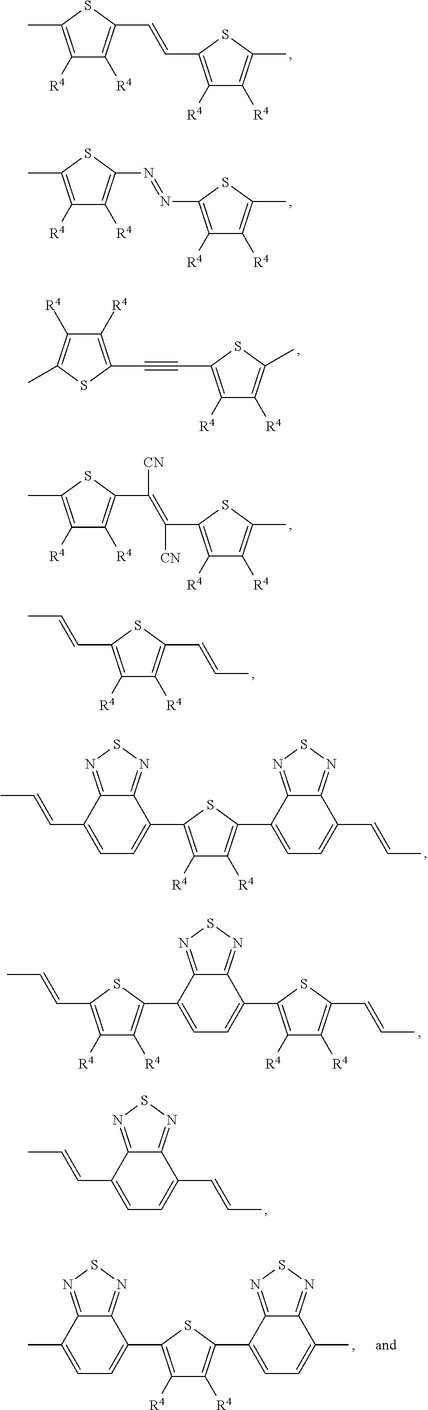

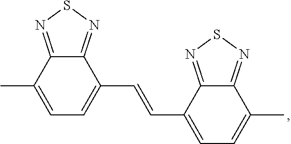

wherein R⁴ is as defined herein.

In preferred embodiments, the present polymers are copolymers of M₁ and at least one M₂, where M₂ is selected from:

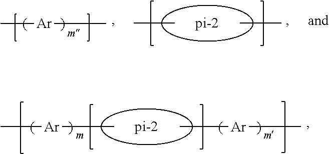

where pi-2, Ar, m, m′, and m′″ are as defined herein.

Certain embodiments of the present copolymers can be represented by a formula selected from the group consisting of:

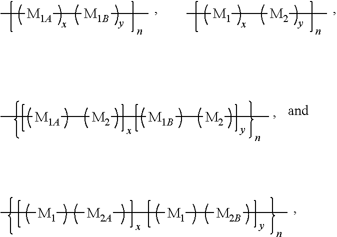

where M_{1A} and M_{1B} represent different repeating units M₁, and M_{2A} and M_{2B} represent different repeating units M₂, x and y are real numbers representing molar ratios, and n is the degree of polymerization. To illustrate, M_{1A} and M_{1B} can be:

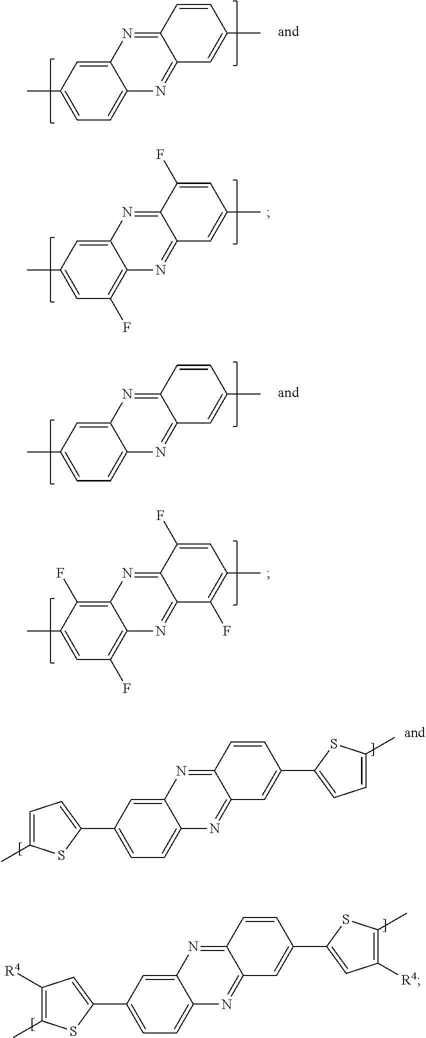

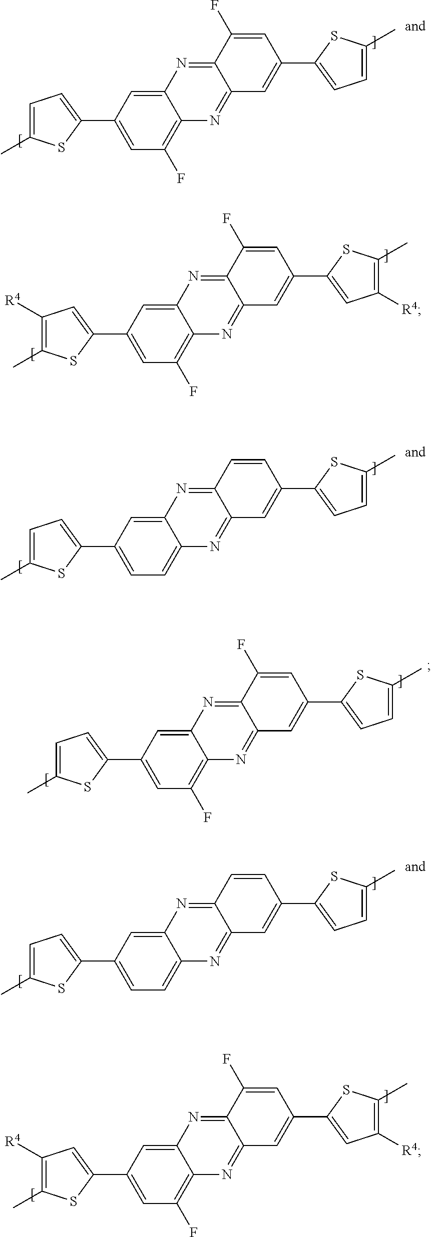

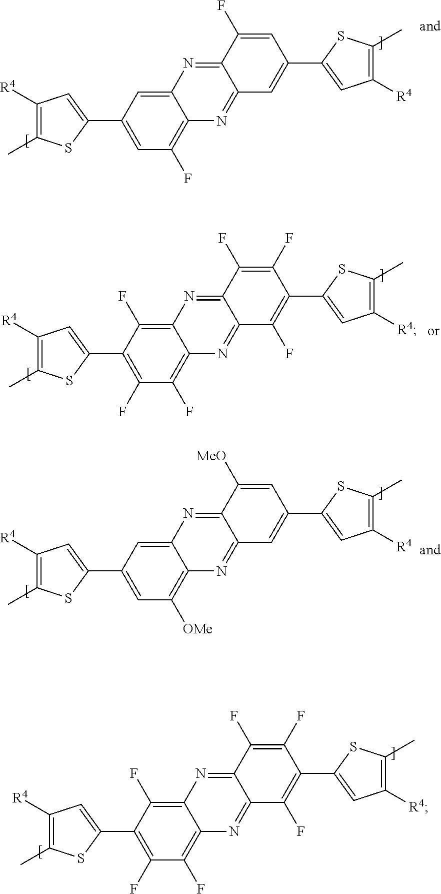

where R⁴ can be selected from R², OR², and SR², where R² is a linear or branched C₁₋₄₀ alkyl or haloalkyl group. To illustrate further, M_{2A} and M_{2B} can be:

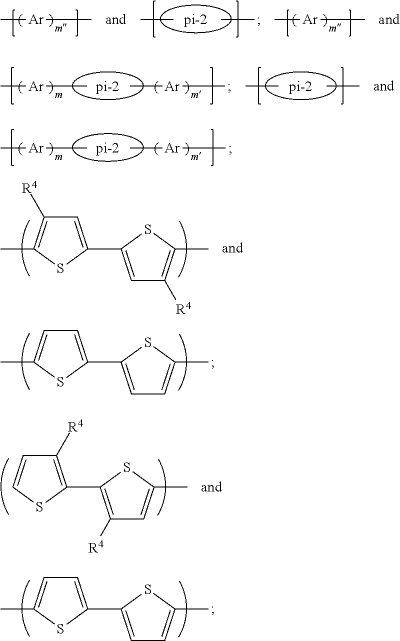

two repeating units represented by:

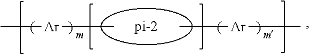

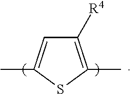

where in M_{2A}, Ar is

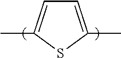

### and in M_{2B}, Ar is

For the various polymers described above, the degree of polymerization (n) can be an integer between 3 and 1,000. In some embodiments, n can be 4-1,000, 5-1,000, 6-1,000, 7-1,000, 8-1,000, 9-1,000, or 10-1,000. For example, n can be 8-500, 8-400, 8-300, or 8-200. In certain embodiments, n can be 8-100. In particular embodiments, the molecular weight of the polymer can be at least 5,000 g/mol, preferably at least 10,000 g/mol.

Embodiments of the present compounds including two or more different repeating units can have such repeating units repeating in a random or alternating manner, and the mole fraction of the two units can be between about 0.05 and about 0.95. For example, the respective mole fractions (x and y) of the two units can be between about 0.1 and about 0.9, between about 0.2 and about 0.8, between about 0.3 and about 0.7, between about 0.4 and about 0.6, or between about 0.45 and about 0.55. In certain embodiments, the present polymers can include the same mole fraction of the first unit as the second unit (i.e., x=y=0.5).

In some embodiments, the present compound can be a molecular compound including at least one phenazine moiety and a plurality of linear and/or cyclic conjugated moieties, such that the compound as a whole provides a pi-extended conjugated system.

To illustrate, exemplary small-molecule semiconducting compounds including at least one phenazine moiety and monomers for preparing the polymers described herein can be represented by the following formulae:

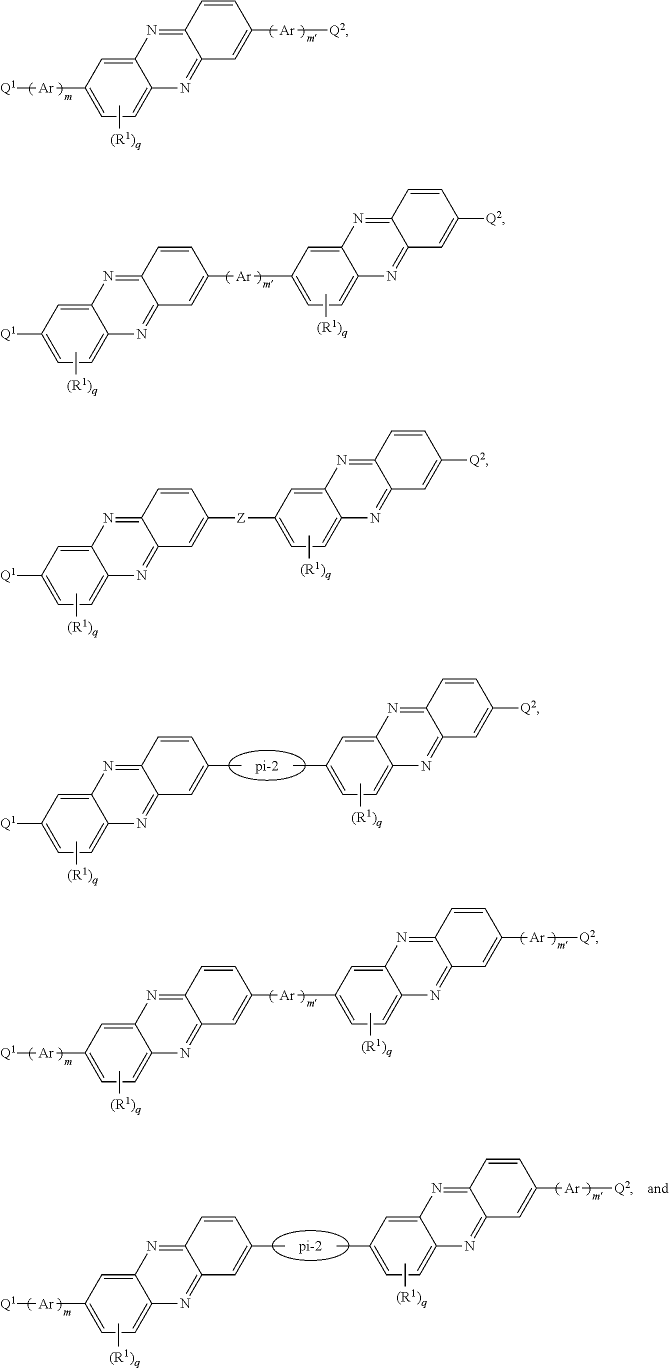

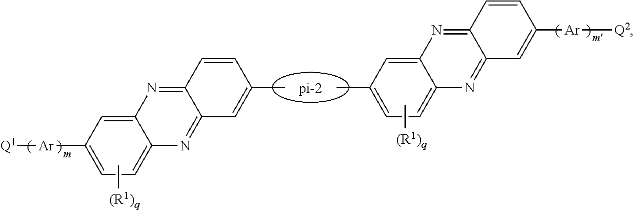

where Q¹ can be X¹ or T¹, Q² can be X² or T², where X¹ and X² can be identical or different reactive groups such as a halide, an organotin group, a boronate, or a polymerizable group, T¹ and T² can be identical or different terminal groups selected from H, R², and C(O)R², where R² is a C₁₋₄₀ alkyl or haloalkyl group, and pi-2, Ar, Z, m, m′, m″, p, and p′ are as defined herein.

Certain embodiments of molecular semiconducting compounds according to the present teachings can be represented by a formula selected from:

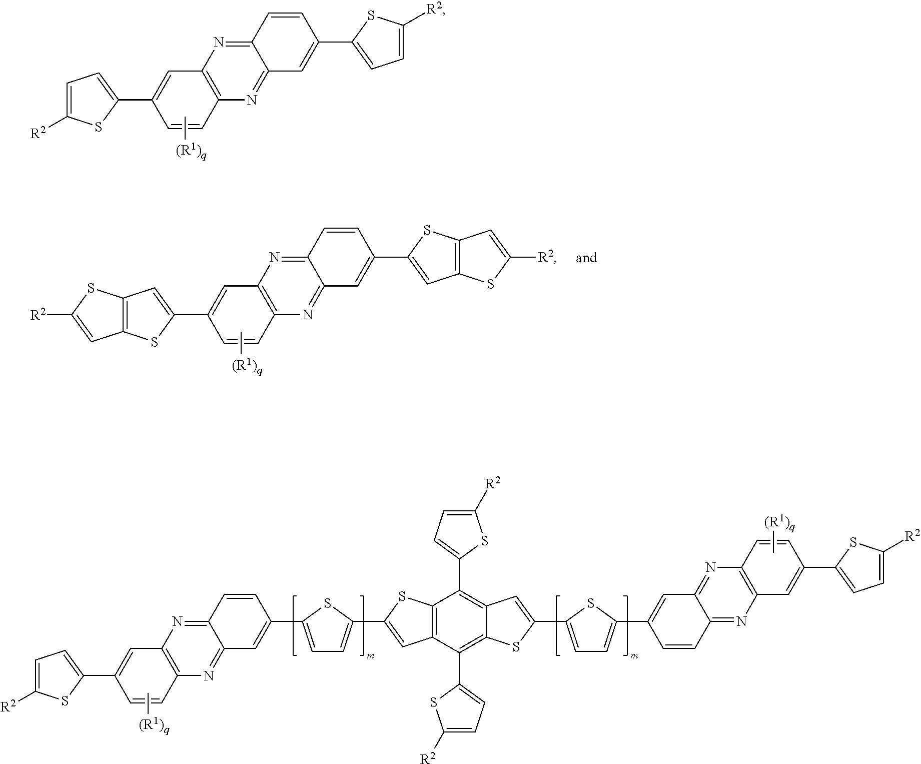

where R¹, R², m and q are as defined herein.

In the above small-molecule semiconducting compounds, each divalent phenazine moiety

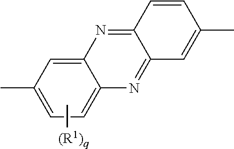

can be more specifically

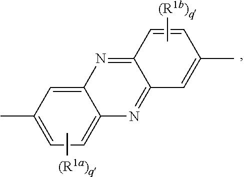

wherein R^{1a} and R^{1b} can be identical or different; and q′, at each occurrence, independently, can be 0 or an integer selected from 1, 2, and 3. In preferred embodiments, at least one of q′ is not 0. To illustrate further, the divalent phenazine moiety in the various embodiments described above can be selected from:

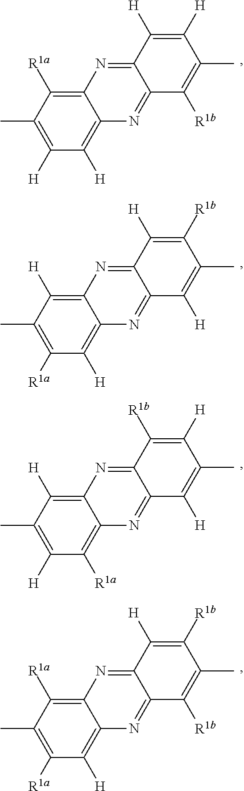

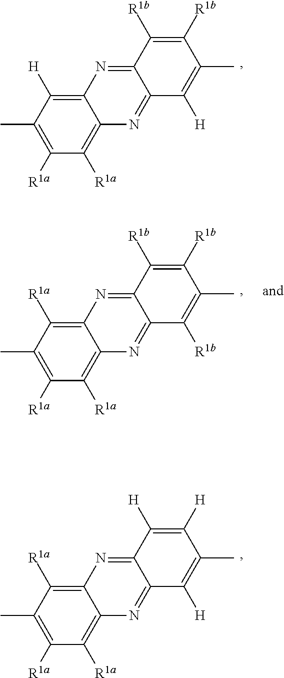

wherein:
R^{1a} and R^{1b} independently can be selected from halogen, —CN, NO₂, R², -L-R³, OH, OR², OR³, NH₂, NHR², N(R²)₂, NHR³, NR²R³, N(R³)₂, SH, SR², SR³, S(O)₂OH, —S(O)₂OR², —S(O)₂OR³, C(O)H, C(O)R², C(O)R³, C(O)OH, C(O)OR², C(O)OR³, C(O)NH₂, C(O)NHR², C(O)N(R²)₂, C(O)NHR³, C(O)NR²R³, C(O)N(R³)₂, SiH₃, SiH(R²)₂, SiH₂(R²), and Si(R²)₃, wherein L is selected from a divalent C₁₋₄₀ alkyl group, a divalent C₂₋₄₀ alkenyl group, a divalent C₁₋₄₀ haloalkyl group, and a covalent bond; R² is selected from a C₁₋₄₀ alkyl group, a C₂₋₄₀ alkenyl group, a C₂₋₄₀ alkynyl group, and a C₁₋₄₀ haloalkyl group; and R³ is selected from a C₃₋₁₀ cycloalkyl group, a C₆₋₁₄ aryl group, a C₆₋₁₄ haloaryl group, a 3-12 membered cycloheteroalkyl group, and a 5-14 membered heteroaryl group, each of which optionally is substituted with 1-5 substituents selected from halogen, —CN, NO₂, R², OR², and SR². In particular embodiments, the divalent phenazine moiety can be either

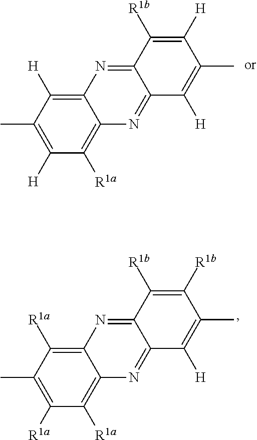

wherein R^{1a} and R^{1b} independently can be selected from F, Cl, Br, I, —CN, —NO₂, R², OR², and SR², where R² can be selected from a linear or branched C₁₋₁₀ alkyl group, a linear or branched C₂₋₁₀ alkenyl group, and a linear or branched C₁₋₁₀ haloalkyl group. In preferred embodiments, R^{1a} and R^{1b} independently can be selected from F, Cl, Br, I, —CN, —NO₂, CH₃, OCH₃, CF₃, and a phenyl group.

Specific exemplary molecular semiconducting compounds according to the present teachings include:

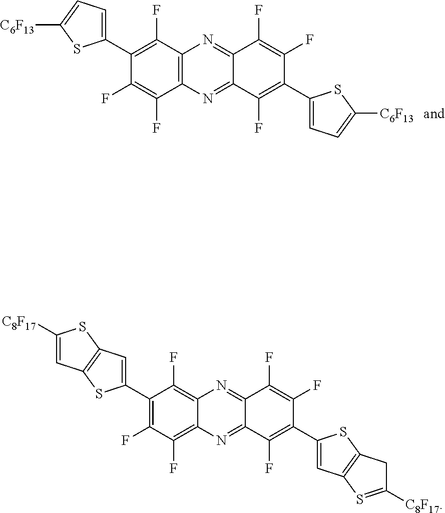

Phenazine and monomers including phenazine according to the present teachings can be prepared using the synthetic routes described hereinbelow. Other monomers according to the present teachings can be commercially available, known in the literature, or can be prepared from readily prepared intermediates by employing standard synthetic methods and procedures known to those skilled in the art. Standard synthetic methods and procedures for the preparation of organic molecules and functional group transformations and manipulations can be readily obtained from the relevant scientific literature or from standard textbooks in the field.

Polymers of the present teachings can be prepared according to procedures analogous to those described in the Examples. In particular, Stille coupling reactions can be used to couple brominated phenazine moieties with stannylated Arₘ, pi-2, and/or Z moieties to prepare polymers according to the present teachings with high molecular weights and in high yields and purity, as confirmed by ¹H NMR spectra, elemental analysis, and/or GPC measurements. Other coupling reactions (such as Suzuki coupling and Negishi coupling) are known in the art and can be used as well.

Alternatively, the present compounds can be prepared from commercially available starting materials, compounds known in the literature, or via other readily prepared intermediates, by employing standard synthetic methods and procedures known to those skilled in the art. Standard synthetic methods and procedures for the preparation of organic molecules and functional group transformations and manipulations can be readily obtained from the relevant scientific literature or from standard textbooks in the field. It will be appreciated that where typical or preferred process conditions (i.e., reaction temperatures, times, mole ratios of reactants, solvents, pressures, etc.) are given, other process conditions can also be used unless otherwise stated. Optimum reaction conditions can vary with the particular reactants or solvent used, but such conditions can be determined by one skilled in the art by routine optimization procedures. Those skilled in the art of organic synthesis will recognize that the nature and order of the synthetic steps presented can be varied for the purpose of optimizing the formation of the compounds described herein.

The processes described herein can be monitored according to any suitable method known in the art. For example, product formation can be monitored by spectroscopic means, such as nuclear magnetic resonance spectroscopy (NMR, e.g., ¹H or ¹³C), infrared spectroscopy (IR), optical absorption/emission spectroscopy (e.g., UV-visible), mass spectrometry (MS), or by chromatography such as high pressure liquid chromatography (HPLC), gas chromatography (GC), gel-permeation chromatography (GPC), or thin layer chromatography (TLC).

The reactions or the processes described herein can be carried out in suitable solvents which can be readily selected by one skilled in the art of organic synthesis. Suitable solvents typically are substantially nonreactive with the reactants, intermediates, and/or products at the temperatures at which the reactions are carried out, i.e., temperatures that can range from the solvent's freezing temperature to the solvent's boiling temperature. A given reaction can be carried out in one solvent or a mixture of more than one solvent. Depending on the particular reaction step, suitable solvents for a particular reaction step can be selected.

Compounds, particularly polymers, disclosed herein can be soluble in various common organic solvents. As used herein, a compound can be considered soluble in a solvent when at least 0.1 mg of the compound can be dissolved in 1 mL of the solvent. Examples of common organic solvents include petroleum ethers; acetonitrile; aromatic hydrocarbons such as benzene, toluene, xylene, and mesitylene; ketones such as acetone, and methyl ethyl ketone; ethers such as tetrahydrofuran, dioxane, bis(2-methoxyethyl) ether, diethyl ether, di-isopropyl ether, and t-butyl methyl ether; alcohols such as methanol, ethanol, butanol, and isopropyl alcohol; aliphatic hydrocarbons such as hexanes; esters such as methyl acetate, ethyl acetate, methyl formate, ethyl formate, isopropyl acetate, and butyl acetate; amides such as dimethylformamide and dimethylacetamide; sulfoxides such as dimethylsulfoxide; halogenated aliphatic and aromatic hydrocarbons such as dichloromethane, chloroform, ethylene chloride, chlorobenzene, dichlorobenzene, and trichlorobenzene; and cyclic solvents such as cyclopentanone, cyclohexanone, and 2-methypyrrolidone.

The compounds described herein can be dissolved, dispersed or suspended in a single solvent or mixture of solvents to provide a composition suitable for solution processing techniques. In preferred embodiments, the solvent can be selected from the group consisting of chlorobenzene, dichlorobenzene (o-dichlorobenzene, m-dichlorobenzene, p-orobenzene, or mixtures thereof), trichlorobenzene, benzene, toluene, chloroform, dichloromethane, dichloroethane, xylenes, α,α,α-trichlorotoluene, methyl naphthalene (e.g., 1-methylnaphthalene, 2-methylnaphthalene, or mixtures thereof), chloronaphthalene (e.g., 1-chloronaphthalene, 2-chloronaphthalene, or mixtures thereof), and mixtures thereof. Various solution-phase processing techniques have been used with organic electronics. Common solution-phase processing techniques include, for example, spin coating, slot coating, doctor blading, drop-casting, zone casting, dip coating, blade coating, or spraying. Another example of solution-phase processing technique is printing. As used herein, “printing” includes a noncontact process such as inkjet printing, microdispensing and the like, and a contact process such as screen-printing, gravure printing, offset printing, flexographic printing, lithographic printing, pad printing, microcontact printing and the like. Molecular semiconductors may be processed via vapor-phase deposition techniques.

Compounds of the present teachings can exhibit semiconductor behavior (including photoactive behavior) such as optimized light absorption/charge separation in a photovoltaic device; charge transport/recombination/light emission in a light-emitting device; and/or high carrier mobility and/or good current modulation characteristics in a field-effect device. In addition, the present compounds can possess certain processing advantages such as solution-processability and/or good stability (e.g., air stability) in ambient conditions. The compounds of the present teachings can be used alone or in combination with other compounds to prepare either p-type (donor or hole-transporting), n-type (acceptor or electron-transporting), or ambipolar semiconductor materials, which in turn can be used to fabricate various organic or hybrid optoelectronic articles, structures and devices, including organic photovoltaic devices, organic light-emitting transistors, and organic field-effect transistors.

The present teachings, therefore, further provide methods of preparing a semiconductor material and composites (e.g., devices) including the semiconductor material. The methods can include preparing a composition (e.g., a solution or dispersion) that includes one or more polymeric compounds disclosed herein dissolved or dispersed in a liquid medium such as a solvent or a mixture of solvents, and depositing the composition on a substrate to provide a semiconductor material. The deposited semiconductor material can be processed further (e.g., subject to an annealing step) prior to formation of additional components thereon to complete a particular device structure.

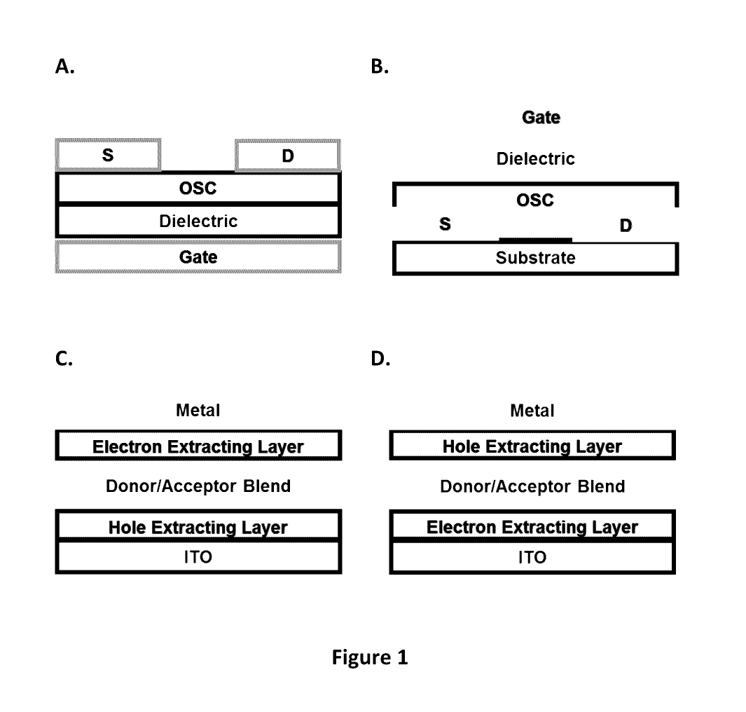

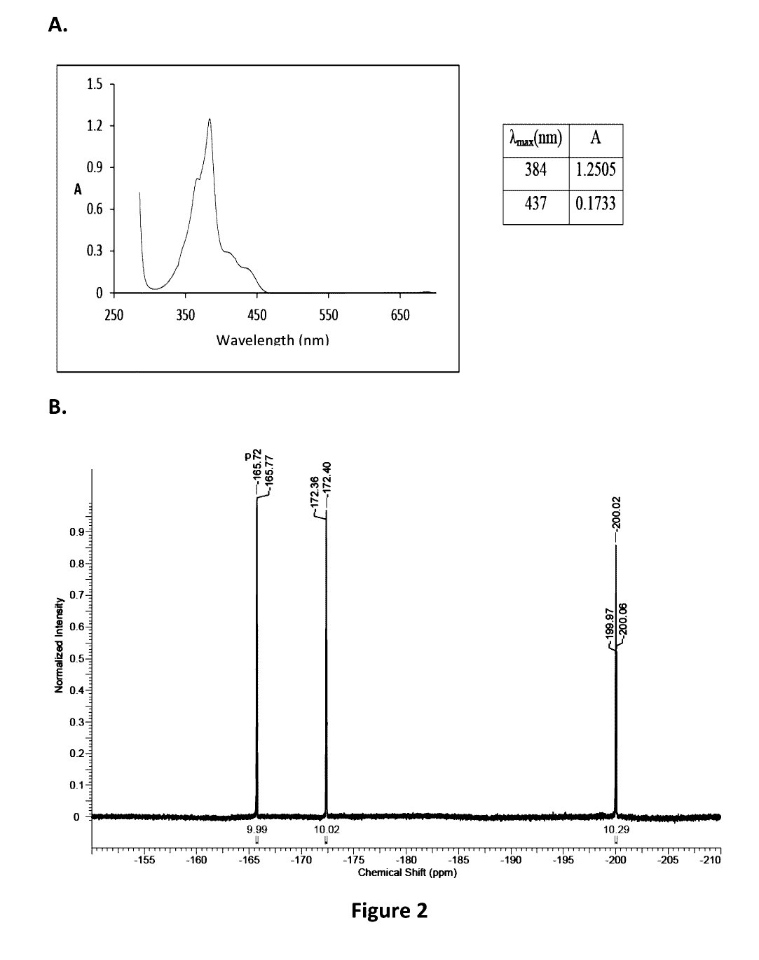

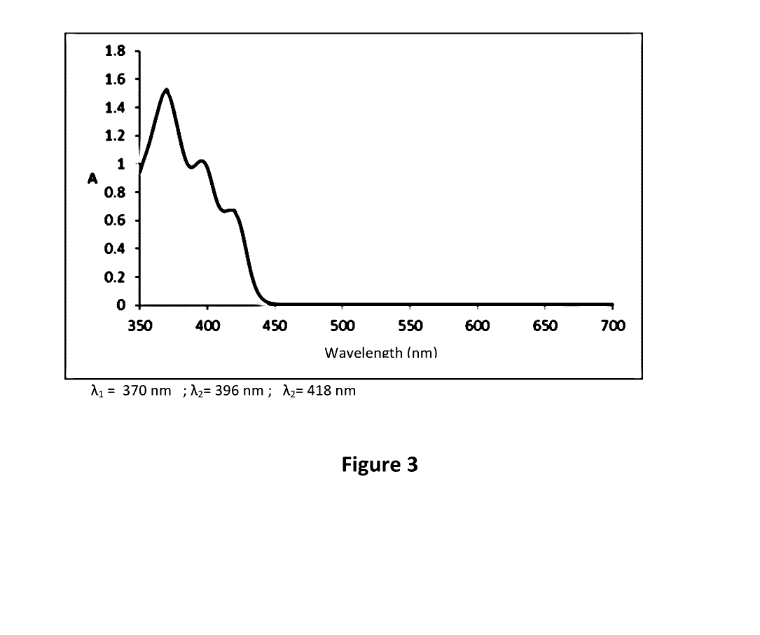

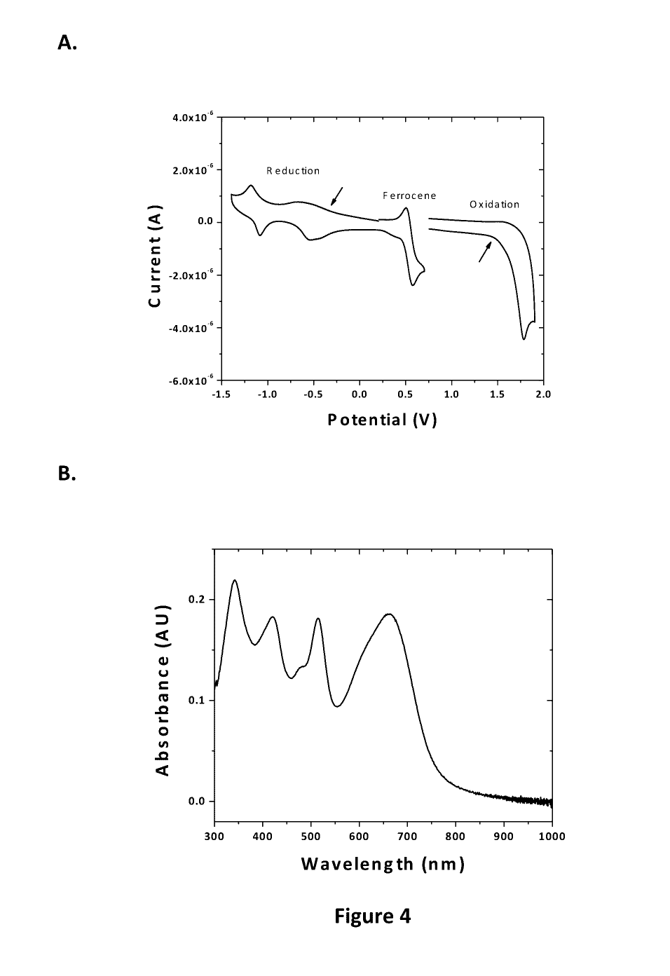

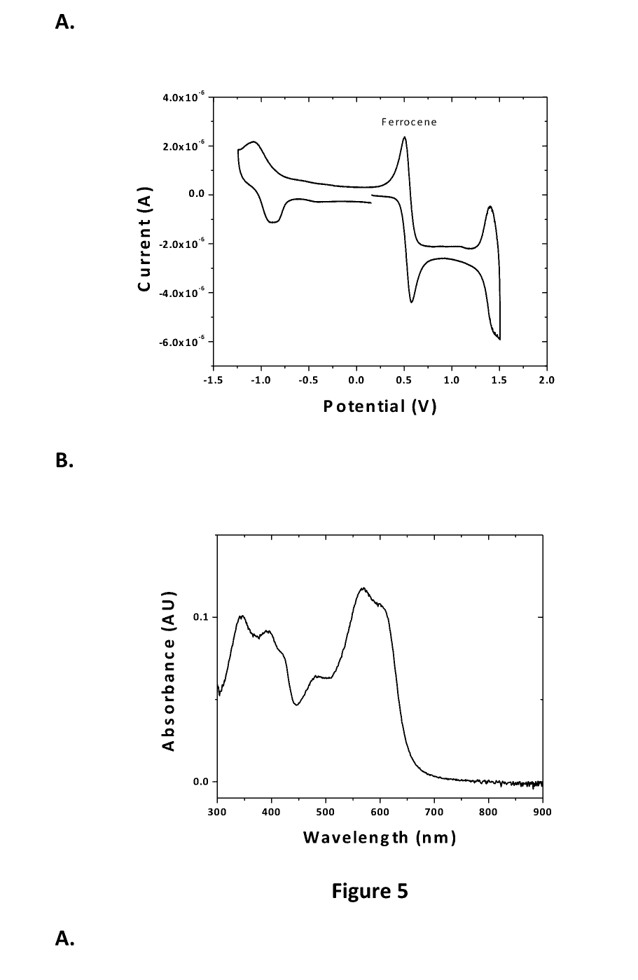

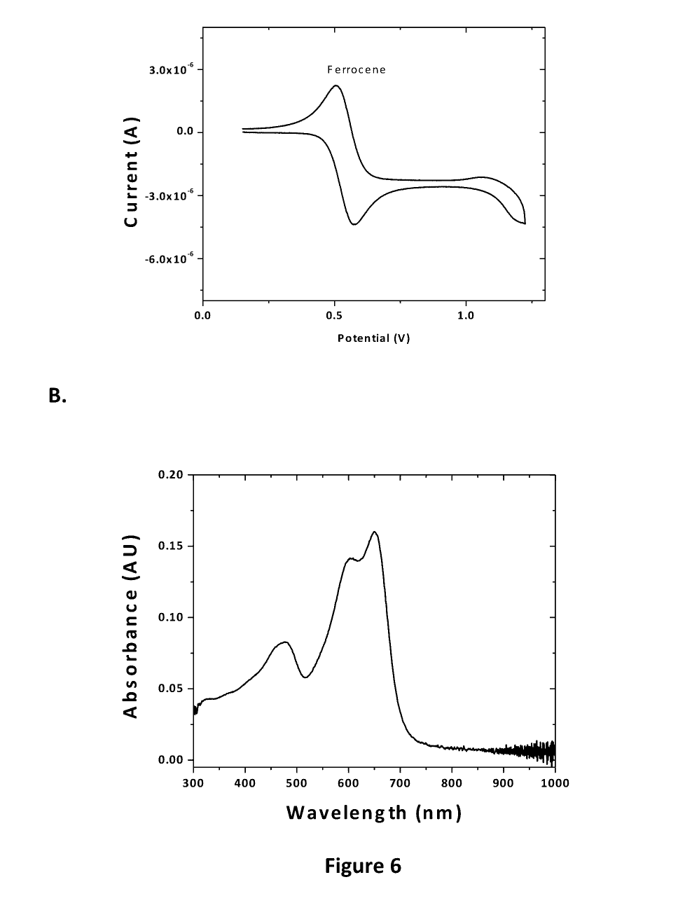

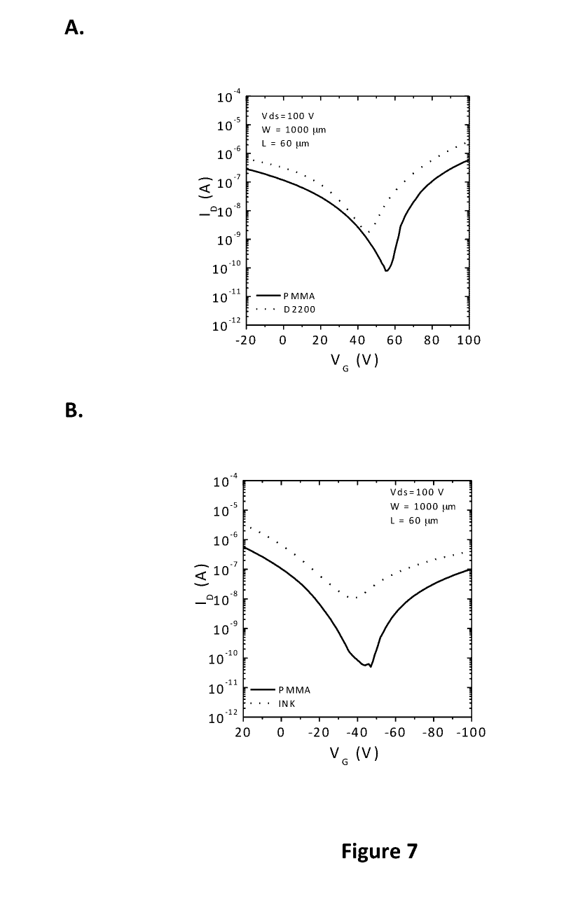

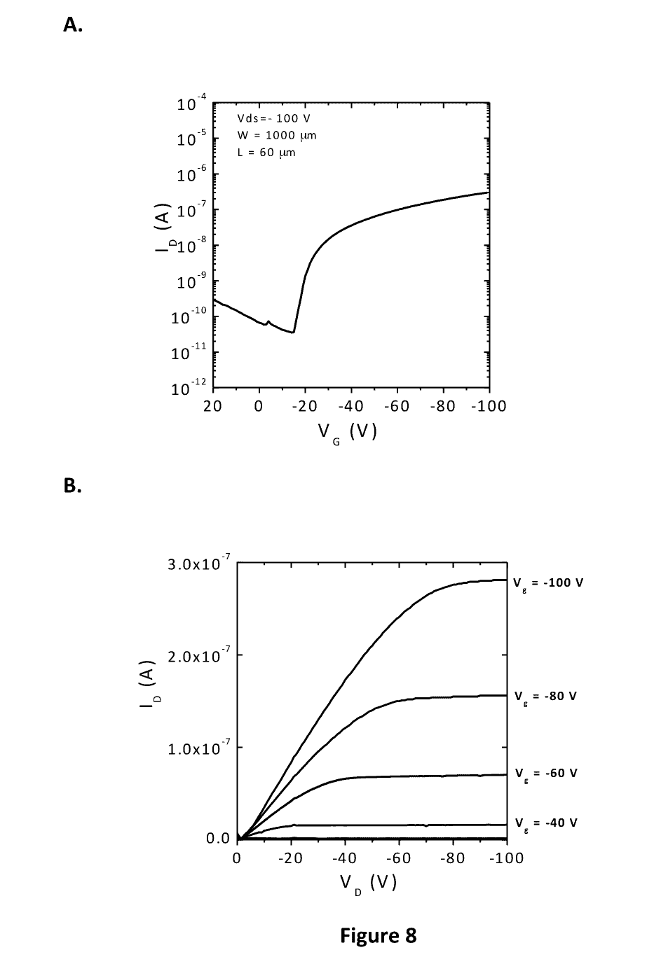

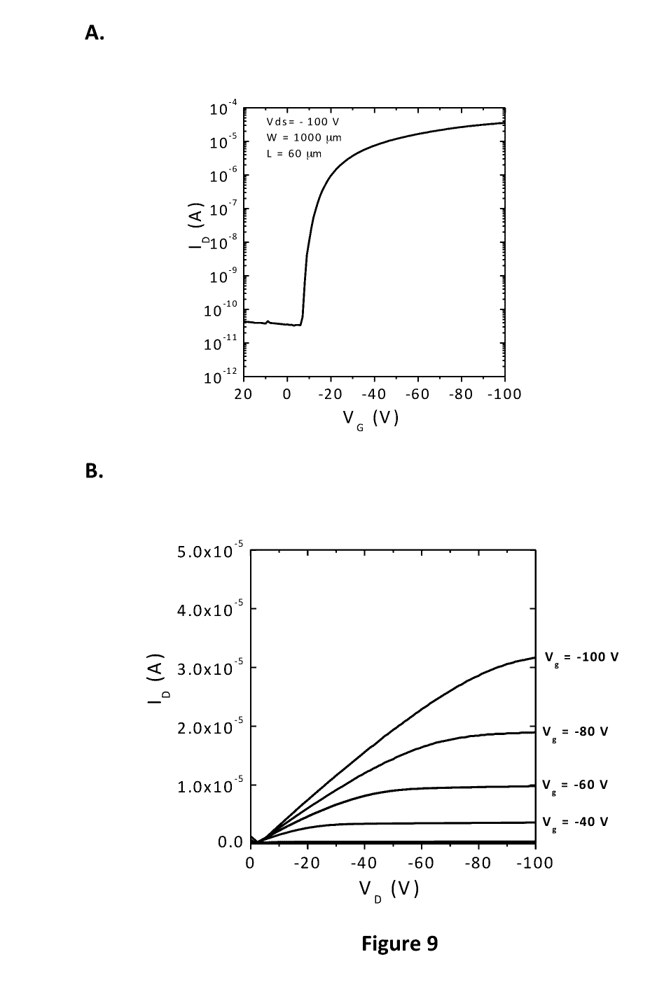

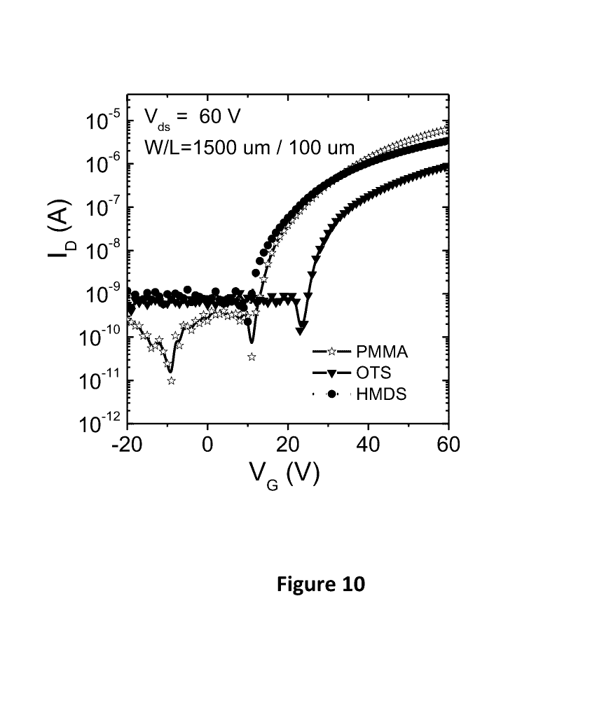

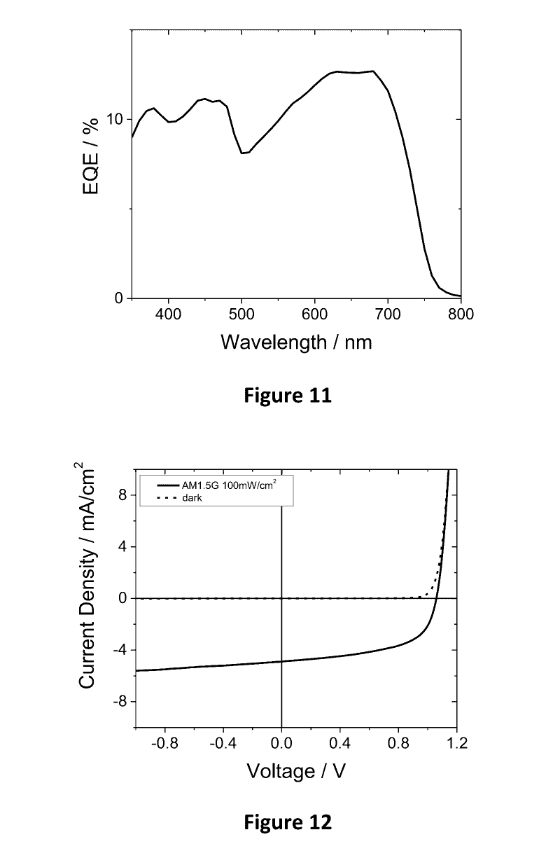

FIG. 1 illustrates, in part, the device structure of (a) a bottom-gate top contact thin-film transistor and (b) a top-gate bottom-contact thin-film transistor. As shown, typical thin-film transistors generally include a semiconductor (OSC) layer which includes a channel layer defined by a pair of source (S) and drain (D) electrodes, a gate electrode (which can be deposited on a substrate in a bottom-gate structure, not shown), and a dielectric layer to insulate the semiconductor layer from the gate electrode. One or more compounds according to the present teachings can be incorporated into the semiconductor layer.

In certain embodiments, OTFT devices can be fabricated with one or more compounds disclosed herein on doped silicon substrates, using SiO₂ as the dielectric. In other embodiments, OTFT devices can be fabricated with one or more compounds disclosed herein on plastic foils, using polymers as the dielectric. In particular embodiments, the active semiconducting layer which incorporates one or more compounds disclosed herein can be deposited at room temperature or at an elevated temperature. In other embodiments, the active semiconducting layer which incorporates one or more compounds disclosed herein can be applied by spin-coating or vapor deposition as described herein. Gate and source/drain contacts can be made of Au, other metals, or conducting polymers and deposited by vapor-deposition and/or printing.

FIG. 1 also illustrates, in part, (c) a conventional organic solar cell, and (d) an inverted solar cell which can incorporate one or more compounds of the present teachings as either the donor material or the acceptor material. In particular, the solar cell can be a bulk heterojunction solar cell. As shown, a representative solar cell generally includes a first electrode and a second electrode (which, respectively, can be composed of a metal and a transparent conducting oxide such as ITO), and between them a photoactive layer which can be composed of a donor/acceptor blend. In some embodiments, one or more electron-extracting layers and/or hole-extracting layers can be present.

The organic solar cell can be fabricated on a substrate which can be a solid, rigid or flexible layer designed to provide robustness to the device. In preferred embodiments, the substrate can be transparent or semi-transparent in the spectral region of interest. As used herein, a material is considered “transparent” when it has transmittance over 50%, and a material is considered “semi-transparent” when it has transmittance between about 50% and about 5%. The substrate can comprise any suitable material known in the art such as glass or a flexible plastic (polymer) film.

The first and second electrodes should have different work functions, with the electrode having the higher work function at or above about 4.5 eV (the “high work function electrode”) serving as the hole-injecting electrode or anode, and the electrode having the lower work function at or below about 4.3 eV (the “low work function electrode”) serving as the electron-injecting electrode. In a traditional OPV device structure, the high work function electrode or anode typically is composed of a transparent conducting metal oxide or metal sulfide such as indium tin oxide (ITO), gallium indium tin oxide (GITO), and zinc indium tin oxide (ZITO), or a thin, transparent layer of gold or silver. The low work function electrode or cathode typically is composed of a low work function metal such as aluminum, indium, calcium, barium, and magnesium. The electrodes can be deposited by thermal vapor deposition, electron beam evaporation, RF or magnetron sputtering, chemical vapor deposition or the like.

In various embodiments, the solar cell can include one or more optional interface layers (“interlayers”) between the anode and the photoactive layer and/or between the cathode and the photoactive layer. For example, in some embodiments, an optional smoothing layer (e.g., a film of 3,4-polyethylenedioxythiophene (PEDOT), or 3,4-polyethylenedioxythiophene:polystyrene-sulfonate (PEDOT:PSS)) can be present between the anode and the photoactive layer. The optional interlayer(s) can perform other functions such as reducing the energy barrier between the photoactive layer and the electrode, forming selective contacts for a single type of carrier (e.g., a hole-blocking layer), modifying the work function of the adjacent electrode, and/or protecting the underlying photoactive layer. In some embodiments, a transition metal oxide layer such as V₂O₅, MoO₃, WO₃ and NiO can be deposited on top of the ITO anode, instead of using PEDOT or PEDOT:PSS as the p-type buffer. To improve device stability via modification of the cathode, an n-type buffer composed of LiF, CsF or similar fluorides can be provided between the cathode and the photoactive layer. Other n-type buffer materials include TiOₓ, ZnOₓ and Cs-doped TiOₓ. Depending on the composition, the interlayers can be solution-processed (e.g., sol-gel deposition, self-assembled monolayers) or deposited by vacuum processes such as thermal evaporation or sputtering.

In certain embodiments, a solar cell according to the present teachings can include a transparent glass substrate onto which an electrode layer (anode) made of indium tin oxide (ITO) is applied. This electrode layer can have a relatively rough surface, and a smoothing layer made of a polymer, typically PEDOT:PSS made electrically conductive through doping, can be applied on top of the electrode layer to enhance its surface morphology. Other similar interlayers can be optionally present between the anode and the photoactive layer for improving mechanical, chemical, and/or electronic properties of the device. The photoactive layer can be composed of a donor/acceptor blend, and can have a layer thickness of, e.g., about 80 nm to a few Before a counter electrode (cathode) is applied, an electrically insulating transition layer can be applied onto the photoactive layer. This transition layer can be made of an alkali halide, e.g., LiF, and can be vapor-deposited in vacuum. Again, similar to the anode, other similar interlayers can be optionally present between the photoactive layer and the cathode for improving mechanical, chemical, and/or electronic properties of the device.

In certain embodiments, a solar cell according to the present teachings can have an inverted device structure, where a modified ITO film is used as the cathode. For example, the ITO can be modified by n-type metal oxides or metal carbonates such as TiOₓ, ZnOₓ, Cs-doped TiOₓ, and caesium carbonate. In particular embodiments, the inverted OPV can include a solution-processed ZnOₓ n-type interface layer as described in Lloyd et al., “Influence of the hole-transport layer on the initial behavior and lifetime of inverted organic photovoltaics,” Solar Energy Materials and Solar Cells, 95(5): 1382-1388 (2011). Compared with the traditional device structure, inverted-type devices can demonstrate better long-term ambient stability by avoiding the need for the corrosive and hygroscopic hole-transporting PEDOT:PSS and low work function metal cathode. The anode of an inverted OPV cell can be composed of Ag, Au, and the like, with an optional p-type interface layer composed of transition metal oxides such as V₂O₅, MoO₃, WO₃ and NiO.

Certain polymers according to the present teachings can be used as the donor material in the donor/acceptor blend which is the photoactive layer in the organic solar cell. For example, polymers according to the present teachings that include unsubstituted phenazines, alkoxylated phenazines, or dihalogenated phenazines may be used as the donor material. The acceptor material can be a fullerene-based compound or an electron-transporting (n-type) polymer. Fullerenes useful in the present teachings can have a broad range of sizes (number of carbon atoms per molecule). The term fullerene as used herein includes various cage-like molecules of pure carbon, including Buckministerfullerene (C₆₀) “bucky ball” and the related “spherical” fullerenes as well as carbon nanotubes. Fullerenes can be selected from those known in the art ranging from, for example, C₂₀-C₁₀₀₀. In certain embodiments, the fullerene can be selected from the range of C₆₀ to C₉₆. In particular embodiments, the fullerene can be a C₆₀ fullerene derivative or a C₇₀ fullerene derivative, such as [6,6]-phenyl-C₆₁-butyric acid methyl ester (PC₆₁BM or simply PCBM) or [6,6]-phenyl-C₇₁-butyric acid methyl ester (PC₇₁BM). In some embodiments, chemically modified fullerenes can be used, provided that the modified fullerene retains acceptor-type and electron mobility characteristics. Some common fullerene derivatives include bisadduct of PC₆₁BM (Bis-PCBM), indene-C₆₀ monoadduct (ICMA), and indene-C₆₀ bisadduct (ICBA). Further, other acceptor materials can be used in place of fullerenes, provided that they have the required acceptor-type and electron mobility characteristics. For example, the acceptor material can be various organic small molecules, polymers, carbon nanotubes, or inorganic particles (quantum dots, quantum rods, quantum tripods, TiO₂, ZnO etc.). In certain embodiments, the acceptor material can be an electron-transporting (n-type) polymer that comprises a bis(imide)arene unit. Exemplary polymers are described in U.S. Patent Publication Nos. 2010/0326527, 2010/0326527, and 2010/0283047.

Certain polymers according to the present teachings can be used as the acceptor material in the donor/acceptor blend which is the photoactive layer in the organic solar cell. For example, polymers according to the present teachings that include hexahalogenated phenazines may be used as the acceptor material. The donor material can be selected from various hole-transporting (p-type) polymers. Exemplary polymers are described in U.S. Patent Publication Nos. 2013/0247992, 2013/0247991, 2013/0247990, 2013/0248831, 2013/0200354, 2013/0200355, 2013/098448, 2012/0186652, 2012/0187385, 2012/0227812, 2011/0226338, and 2010/0307594.

Another aspect of the present teachings relates to methods of fabricating an organic light-emitting transistor or an organic light-emitting diode (OLED) that incorporates one or more semiconductor materials of the present teachings. For example, in an OLED, one or more compounds of the present teachings can be used as electron-transporting and/or emissive and/or hole-transporting materials. An OLED generally includes a substrate, a transparent anode (e.g., ITO), a cathode (e.g., metal), and one or more organic layers which can incorporate one or more compounds of the present teachings as hole-transporting (p-channel) and/or emissive and/or electron-transporting (n-channel) materials. In embodiments where the present compounds only have one or two of the properties of hole transport, electron transport, and emission, the present compounds can be blended with one or more further organic compounds having the remaining required property or properties.

The following examples are provided to illustrate further and to facilitate the understanding of the present teachings and are not in any way intended to limit the invention.

All reagents were purchased from commercial sources and used without further purification unless otherwise noted. Anhydrous THF was distilled from Na/benzophenone. Conventional Schlenk techniques were used on reactions that were carried out under N₂ unless otherwise noted. NMR spectra were recorded on a Varian Unity Plus 500 spectrometer (¹H, 500 MHz). Elemental analysis was done at Midwest Microlab, LLC. Molecular weight of polymers was determined by a Waters GPC system (Waters Pump 510), using polystyrene as standards.

### Example 1

### Preparation of Polymer P1

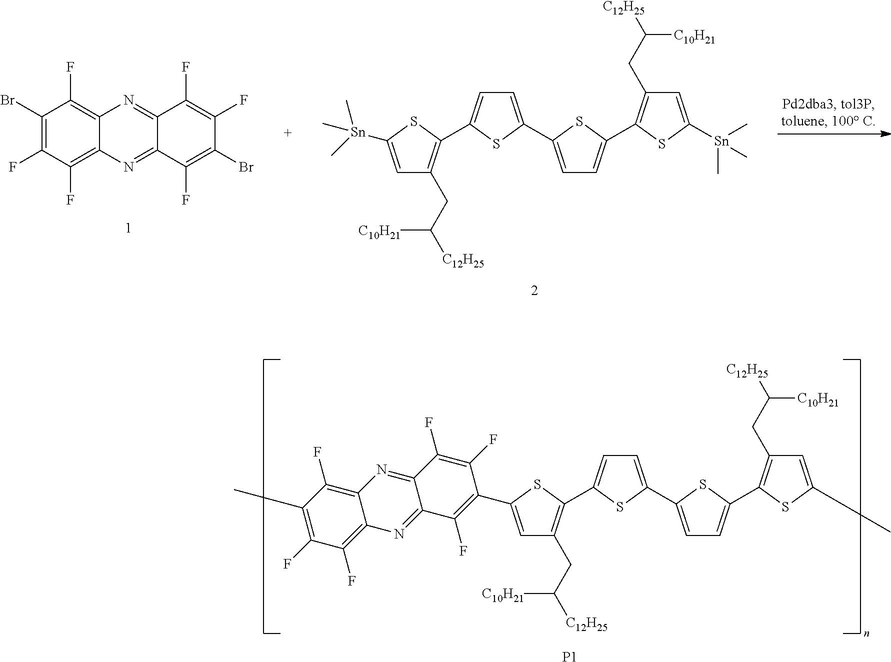

### Synthesis of 2,7-dibromo-1,3,4,6,8,9-hexafluorophenazine (1)

To a solution of 1.5 g of 4-bromo-tetrafluoroaniline in 15 ml of dichloromethane, 4.7 g of Pb(AcO)₄ was slowly added then the mixture was heated to reflux for 2 h. During this time the color of the mixture changed from yellow to red. The reaction mixture was diluted with 50 ml of dichloromethane and filtered over a Celite® pad. The organic phase washed with 50 ml of water, twice with a saturated solution of NaHCO₃ (2×20 ml, to remove all acetic acid) and with water again until a neutral pH was obtained. The organic phase was dried over Na₂SO₄ and the solvent removed under reduced pressure. The crude reaction mixture was purified by column chromatography eluting first with hexane/CH₂Cl₂ (3:1) to collect the azobenzene derivative, then with hexane/CH₂Cl₂ (1:1) to collect the phenazine. The phenazine was further washed with pentane in order to remove colored contaminants (29% yield). ¹F NMR (CDCl₃): −200.02 (dd, 2F), −172.38 (d, 2F), −165.75 (d, 2F).

### Synthesis of P1

Under Ar, a mixture of compound 1 (55.7 mg, 0.12 mmol), quaterthiophene tin reagent 2 (166.2 mg, 0.13 mmol), Pd₂dba₃ (2.3 mg, 0.0025 mmol), and tol₃P (6.1 mg, 0.020 mmol) in anhydrous toluene (12 mL) was stirred at 100° C. for 1.5 h, before bromobenzene (2 mL) was added. This mixture was maintained at 100° C. for an additional 1 h, and it was poured into methanol (100 mL) after it was cooled to rt. The resulting mixture was stirred at rt for 20 min, and the precipitate was collected by filtration, washed with methanol, and then subject to Soxhlet extraction with methanol (21 h), ethyl acetate (19 h), and hexane (23 h), respectively. Finally, the product was extracted with chlorobenzene, and the extract was precipitated in methanol. The precipitate was collected by filtration, washed with methanol, and dried in vacuum, leading to a dark solid as the product (P1) (10.3 mg). Additional P1 was obtained by collecting and drying the solid in thimble to provide a combined yield of 112.1 mg (total yield: 76.1%).

### Example 2

### Preparation of Polymer P2

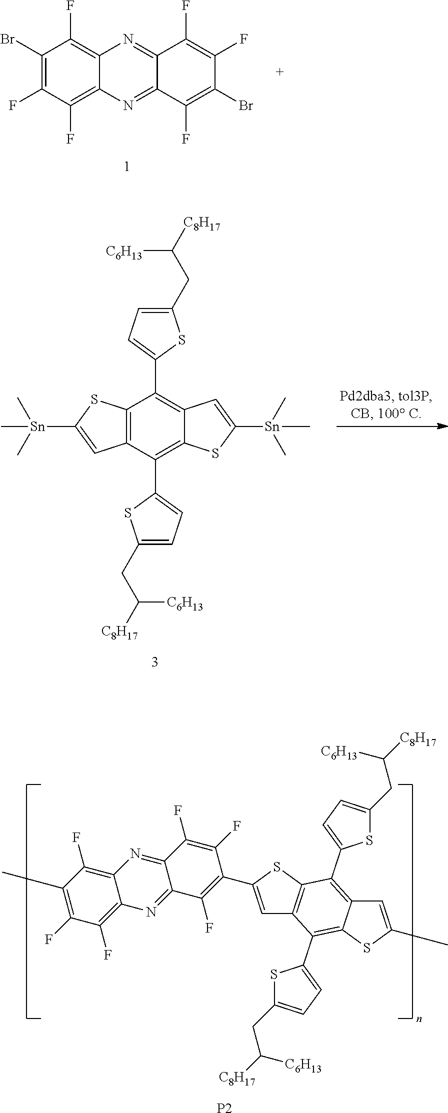

Under Ar, a mixture of compound 1 (47.6 mg, 0.11 mmol), benzodithiophene tin reagent 3 (122.1 mg, 0.11 mmol), Pd₂dba₃ (2.0 mg, 0.0021 mmol), and tol₃P (5.2 mg, 0.017 mmol) in anhydrous chlorobenzene (12 mL) was stirred at 100° C. for 19 h, before bromobenzene (0.2 mL) was added. This mixture was maintained at 100° C. for additional 6 h, and it was poured into methanol (100 mL) after it was cooled to rt. The resulting mixture was stirred at rt for 15 min, and the precipitate was collected by filtration, and washed with methanol. This crude product was then subject to Soxhlet extraction with methanol (16 h), ethyl acetate (19 h), and hexane (20 h), respectively. Finally, the product was extracted with chlorobenzene (100 mL) for 45 min, and the extract was precipitated in methanol (200 mL). The precipitate was collected by filtration, washed with methanol, and dried in vacuum, leading to a dark solid as the product (P2, 108.7 mg, 92.6% yield). GPC (150° C., trichlorobenzene): Mn=13.5 K, PDI=2.8.

### Example 3

### Preparation of Polymer P3

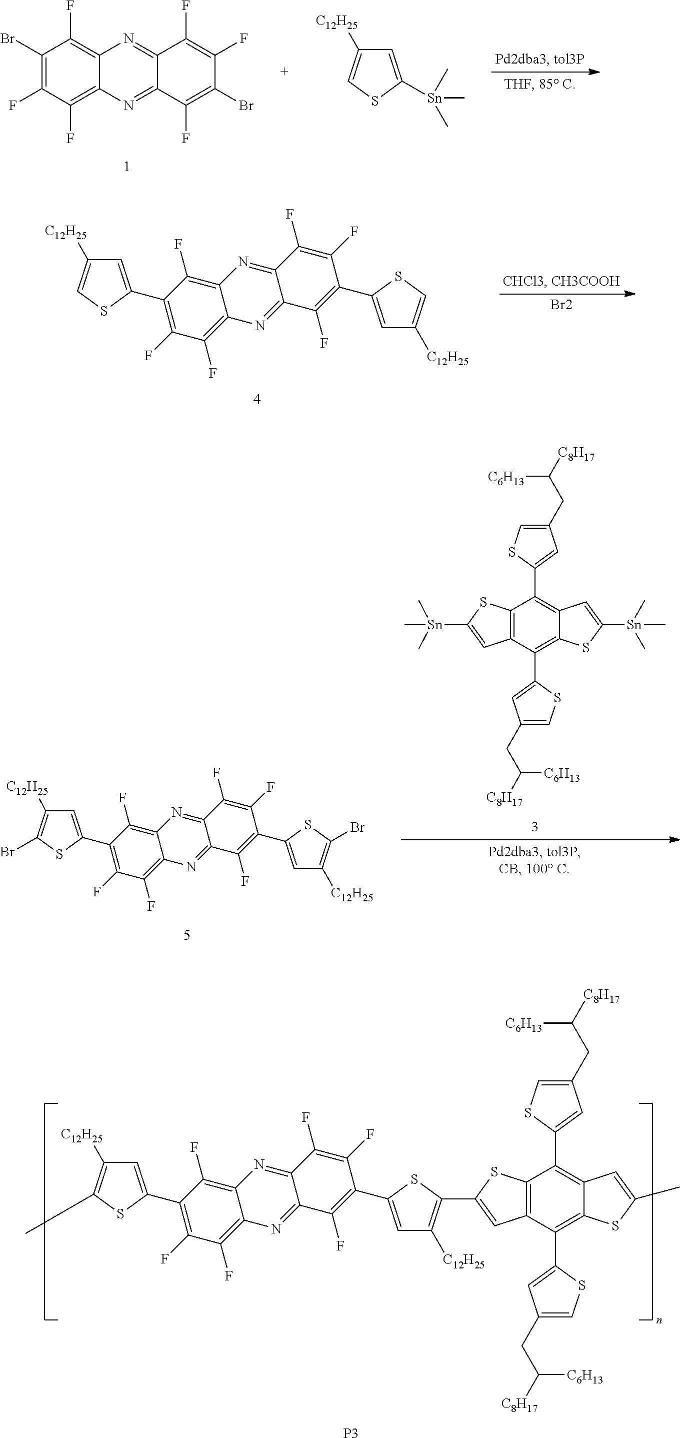

### Synthesis of Compound 4

Under nitrogen, a mixture of compound 1 (200.0 mg, 0.45 mmol), 4-dodecyl-2-trimethylstannylthiophene (411.7 mg, 0.99 mmol), Pd₂dba₃ (16.5 mg, 0.018 mmol), and tol₃P (22.0 mg, 0.072 mmol) in anhydrous THF (20 mL) was heated to 85° C., and the reaction was maintained at this temperature for 18 h. Upon cooling to rt, the reaction mixture was concentrated, and the residue was subject to column chromatography on silica gel with a mixture of hexane:chloroform=3:1 (v/v) as eluent, leading to an orange solid as the product (215 mg, 61% yield). ¹H NMR (400 MHz, CDCl₃): 7.77 (s, 2H), 7.31 (d, J=0.8 Hz, 2H), 2.73 (t, J=7.6 Hz, 4H), 1.71 (m, J=2.4 Hz, 4H), 1.38-1.23 (m, br, 40H) 0.88 (t, J=6.0 Hz, 6H).

### Synthesis of Compound 5

Compound 4 (208 mg, 0.26 mmol) was added to a flask and dissolved in chloroform (20 mL) and AcOH (2 mL). Br₂ (93 mg, 0.58 mmol) was added and the reaction mixture was stirred at rt overnight. The reaction mixture was poured into MeOH:H₂O (1:1, 100 mL). The resulting orange precipitate was isolated by filtration and subject to column chromatography on silica gel with a mixture of hexane:chloroform=1:1 (v/v) as eluent, yielding an orange solid (5, 213 mg, 87% yield). ¹H NMR (CDCl3, 400 MHz): 7.64 (s, 2H), 2.68 (t, J=8.0 Hz, 4H), 1.67 (m, J=2.4 Hz, 4H), 1.38-1.25 (m, br, 40H) 0.89 (t, J=6.0 Hz, 6H).

### Synthesis of Polymer P3

Compounds 5 (100.0 mg, 0.106 mmol) and benzodithiophene tin reagent 3 (119.2 mg, 0.106 mmol) were added to a Schlenk flask with Pd₂dba₃ (3.9 mg, 0.004 mmol) and tol₃P (5.2 mg, 0.016 mmol). The flask was subject to vacuum and then backfilled with Ar, and this cycle was repeated four times. Under Ar, anhydrous chlorobenzene (10 mL) was added, and the resulting mixture was heated to 100° C. and maintained at this temperature for about 16 h. Upon cooling to rt, the reaction mixture was precipitated in methanol (about 30 mL), and the precipitate was collected by filtration and washed with methanol. This crude product was then subject to Soxhlet extraction with methanol (6 h), ethyl acetate (18 h), hexanes (18 h) and finally extracted with chlorobenzene (8 h). Upon cooling to rt, the chlorobenzene extract was precipitated in methanol (about 100 mL). The precipitate was collected by filtration, washed with methanol, and dried in vacuum, leading to a dark green solid as the polymer product P3 (140 mg, 80.3% yield). GPC (150° C., trichlorobenzene): Mn=10.9 K, PDI=2.2.

### Example 4

### Preparation of Polymer P4

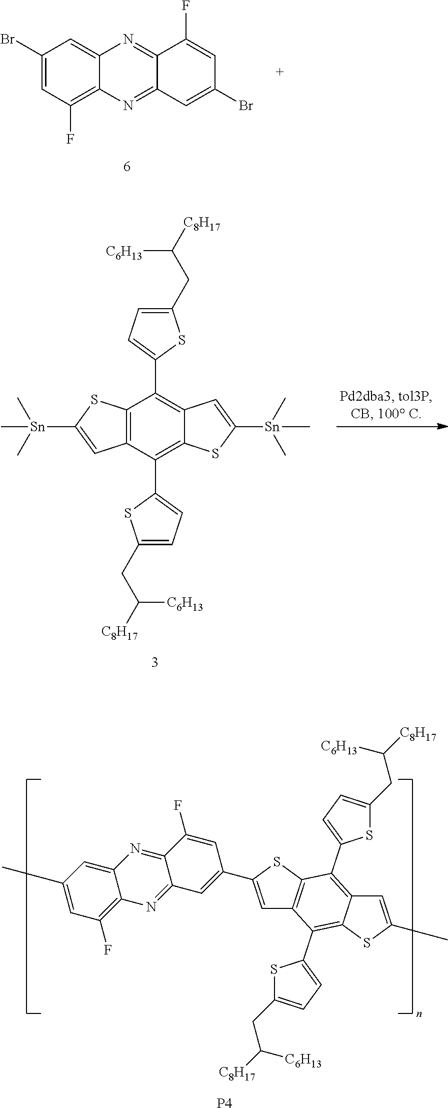

### Synthesis of 3,8-dibromo-1,6-difluorophenazine (6)

To a solution of 4-bromo-2,6-difluoroaniline (1.2 g, 5.8 mmol) in dichloromethane (20 mL), lead acetate (IV) (4.3 g, 9.7 mmol) was added and the resulting solution stirred at 40° C. for 2 h (the complete reaction of the starting aniline was checked by thin layer chromatography, eluent: hexane). After cooling at room temperature, the mixture was filtered through a Celite® pad of 2-3 cm and then washed with dichloromethane (20 mL×4). The organic phase was washed in sequence with: 20 ml water/acetic acid 1:1 solution, 30 ml of saturated NaHCO₃ (twice) and, finally, water (until the pH became neutral). The organic phase was dried over Na₂SO₄ and its volume reduced to ⅓ under reduced pressure. The light brown precipitate was collected by filtration and washed with hexane affording 0.2 g (18% yield) of pure crystalline phenazine (6) as small yellow needles.

### Synthesis of Polymer P4

Under Ar, a mixture of 3,8-dibromo-1,6-difluorophenazine (6) (77.6 mg, 0.21 mmol), benzodithiophene tin reagent 3 (233.7 mg, 0.21 mmol), Pd₂dba₃ (3.8 mg, 0.0042 mmol), and tol₃P (10.1 mg, 0.033 mmol) in anhydrous chlorobenzene (22 mL) was stirred at 100° C. for 18 h, before bromobenzene (0.5 mL) was added. This mixture was maintained at 100° C. for additional 5 h, and it was poured into methanol (150 mL) after it was cooled to rt. The resulting mixture was stirred at rt for 15 min, and the precipitate was collected by filtration, and washed with methanol. This crude product was then subject to Soxhlet extraction with methanol (19 h), ethyl acetate (20 h), and hexane (22 h), respectively. Finally, the product was extracted with chlorobenzene (120 mL) for 2 h, and the extract was precipitated in methanol (200 mL). The precipitate was collected by filtration, washed with methanol, and dried in vacuum, leading to a dark solid as the product (P4, 71.8 mg, 34.2% yield).

### Example 5

### Preparation of Polymer P5

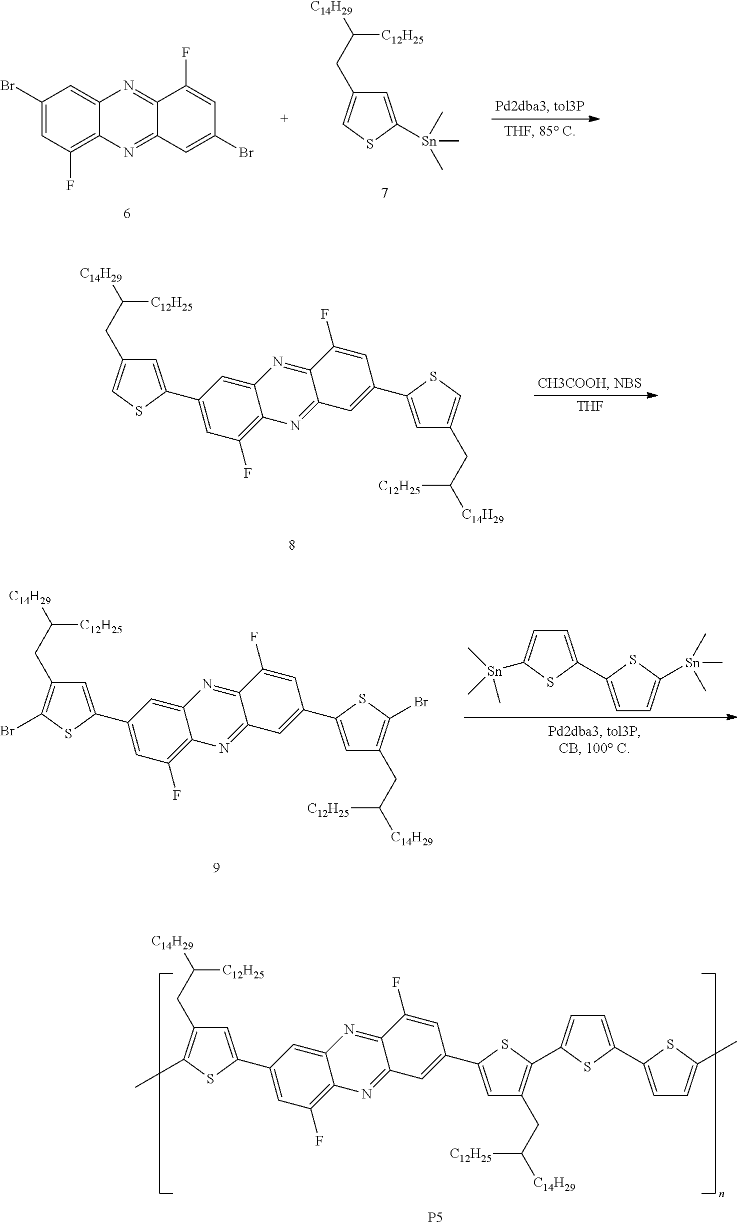

### Synthesis of Compound 8

Under nitrogen, a mixture of compound 6 (179.7 mg, 0.48 mmol), 4-(2-dodecylhexadecyl)-2-trimethylstannylthiophene (7) (805.1 mg, 1.26 mmol), Pd₂dba₃ (22.1 mg, 0.024 mmol), and tol₃P (58.6 mg, 0.19 mmol) in anhydrous THF (45 mL) was heated to 85° C., and the reaction was maintained at this temperature for 18 h. Upon cooling to rt, the reaction mixture was diluted with dichloromethane (150 mL). The resulting mixture was washed with water (100 mL×2), dried over anhydrous Na₂SO₄, and concentrated in vacuo. The residue was subject to column chromatography on silica gel with a mixture of hexane:chloroform=4:1 (up to 2:1, v/v) as eluent, leading to an orange solid as the product (8, 0.50 g, 89.3% yield). ¹H NMR (400 MHz, CDCl₃): 8.32 (d, J=3.2 Hz, 2H), 7.83 (dd, J=10.8 Hz, J=3.2 Hz, 2H), 7.39 (d, J=1.2 Hz, 2H), 7.04 (d, J=1.2 Hz, 2H), 2.60 (d, J=6.8 Hz, 4H), 1.19-192 (m, br, 98H) 0.88-0.91 (m, br, 12H).

### Synthesis of Compound 9

Compound 8 (500 mg, 0.43 mmol) was added to a flask and dissolved in THF (40 mL) and AcOH (4 mL). NB S (168 mg, 094 mmol) was added and the reaction mixture was stirred at 60° C. overnight. The reaction mixture was cooled to rt and poured into MeOH:H₂O (1:1, 100 mL). The resulting red precipitate was isolated by filtration, subject to column chromatography on silica gel with a mixture of hexane:chloroform=3:1 (v/v) as eluent, and then recrystallized from EtOAc (30 mL) in the fridge. Filtration yielded a red solid as the product (9, 354 mg, 62%). ¹H NMR (CDCl3, 400 MHz): 7.64 (s, 2H), 7.75 (dd, J=10.4 Hz, J=1.2 Hz, 2H), 7.24 (s, 2H), 2.55 (d, J=7.2 Hz, 4H), 1.23-1.26 (m, br, 98H) 0.85-0.88 (m, br, 12H).

### Synthesis of Polymer P5

Compound 9 (100.0 mg, 0.075 mmol) and 5,5′-bis(trimethylstannyl)-2,2′-bithiophene (41.9 mg, 0.085 mmol) were added to a Schlenk flask with Pd₂dba₃ (2.8 mg, 0.003 mmol) and tol₃P (3.7 mg, 0.012 mmol). The flask was subject to vacuum and then backfilled with Ar, and this cycle was repeated four times. Under Ar, anhydrous chlorobenzene (10 mL) was added, and the resulting mixture was heated to 100° C. and maintained at this temperature for about 16 h. Upon cooling to rt, the reaction mixture was precipitated in methanol (about 50 mL), and the precipitate was collected by filtration and washed with methanol. This crude product was then subject to Soxhlet extraction with methanol (18 h), ethyl acetate (18 h), hexanes (18 h) and finally extracted with chlorobenzene (4 h). Upon cooling to rt, the chlorobenzene extract was precipitated in methanol (about 100 mL). The precipitate was collected by filtration, washed with methanol, and dried in vacuum, leading to a dark green solid as the polymer product (P5, 87 mg, 87.3% yield).

### Example 6

### Preparation of Polymer P6

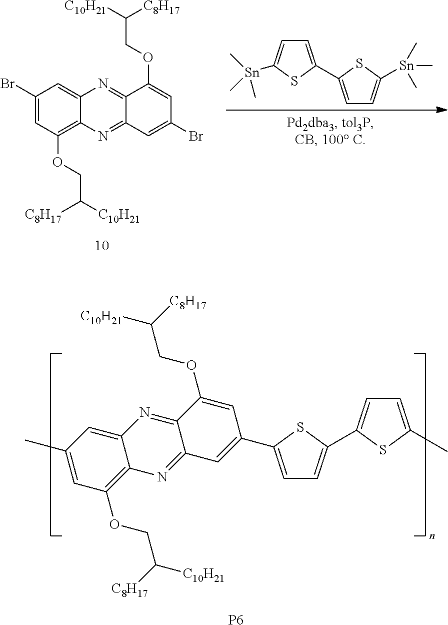

### Synthesis of 3,8-dibromo-1,6-di(2-octyldodecyloxy)phenazine (10)

Under argon, to a solution of sodium hydride (60% in mineral oil) (10.6 mg, 0.267 mmol) in anhydrous THF (45 mL) was added 2-octyl-1-dodecanol (120 mg, 0.401 mmol). The mixture was stirred at rt for 30 minutes before 3,8-dibromo-1,6-difluorophenazine (6) was added in a single portion. The mixture was stirred at rt overnight. The reaction was concentrated, and the residue was subject to column chromatography on silica gel with a mixture of hexane:chloroform=1:1 (v/v) as eluent, leading to a yellow-orange solid as the product (10, 30.9 mg, 25% yield). ¹H NMR (400 MHz, CDCl3): 8.07 (d, J=2.0 Hz, 2H), 7.12 (d, J=2.0 Hz, 2H), 4.12 (d, J=6.4 Hz, 4H), 1.73-1.70 (m, 2H), 1.28-1.24 (m, br, 64H), 0.90-0.86 (t, 12H).

### Synthesis of Polymer P6

Compound 10 (30.9 mg, 0.033 mmol) and 5,5′-bis(trimethylstannyl)-2,2′-bithiophene (16.3 mg, 0.033 mmol) were added to a Schlenk flask with Pd₂dba₃ (1.2 mg, 0.001 mmol) and tol₃P (1.6 mg, 0.005 mmol). The flask was subject to vacuum and then backfilled with Ar, and this cycle was repeated four times. Under Ar, anhydrous chlorobenzene (3 mL) was added, and the resulting mixture was heated to 100° C. and maintained at this temperature for about 16 h. Upon cooling to rt, the reaction mixture was precipitated in methanol (about 20 mL), and the yellow precipitate was collected by filtration, washed with additional methanol, and dried in vacuum.

### Example 7

### Preparation of Small Molecule SM1

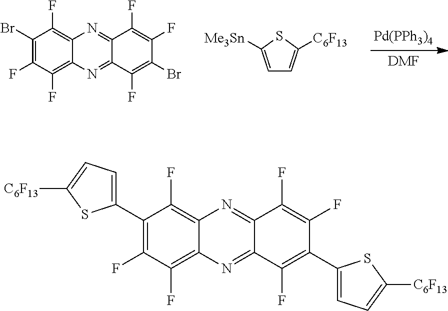

A Schlenk tube was charged with 2,7-dibromo-1,3,4,6,8,9-hexafluorophenazine (100 mg, 224 μmol, 1.00 equiv.) and Pd(PPh₃)₄ (13 mg, 11 μmol, 5.0 mol %). DMF (2.5 mL) and 2-trimethylstannyl-5-tridecafluorohexylthiophene (253 mg, 448 μmol, 2.00 equiv.) were then added and the mixture was heated in a 90° C. heat bath for 17 hours. The reaction mixture was then cooled to room temperature and diluted with methanol (5 mL) and filtered to collect a yellow crude solid, which was subject to gradient sublimation (crucible temperature=210° C., pressure=6×10⁻⁵ torr) to give the title compound as a yellow solid (17 mg, 7% yield). m.p. 229° C. ¹H NMR (500 MHz, C₂D₂Cl₄ δ ppm 7.37-7.17 (m, 2H), 7.12-6.92 (m, 2H); 19F NMR (470 MHz, C₂D₂Cl₄ δ ppm −80.94 (s, 6F), −100.81 (s, 4F), −119.95-121.71 (m, 10F), −122.26 (s, 4F), −125.51 (s, 3F), −129.73 (d, J=14.27 Hz, 2F), −151.33 (t, J=16.51 Hz, 2F).

### Example 8

### Preparation of Small Molecule SM2

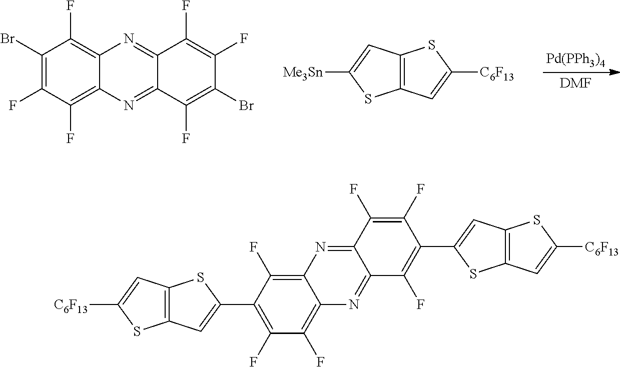

To a 50 mL Schleck flask was added 2,7-dibromo-1,3,4,6,8,9-hexafluorophenazine (125 mg, 280 μmol, 1.00 equiv.), and Pd(PPh₃)₄ (32 mg, 28 μmol, 10 mol %). DMF (10 mL) and 2-trimethylstannyl-5-tridecafluorohexylthieno[3,2-b]thiophene (522 mg, 841 μmol, 3.00 equiv.) were then added and the mixture was heated in an 90° C. heat bath for 16 hours. The mixture was cooled to room temperature and the precipitate was collected by filtration and washed with methanol (30 mL) and hexanes (30 mL). The crude product was subject to gradient sublimation (crucible temperature=280° C., pressure=5×10⁻⁵ torr) to give the title compound as an orange solid (47 mg, 14% yield). Anal. calcd. for (C₃₆H₄F₃₂N₂S₄): C, 36.01; H, 0.34; N, 2.33. Found: C, 35.77; H, 0.25; N, 0.22. m.p. 309-310° C.

### Example 9

### Synthetic Route for Asymmetric-Substituted Phenazines

Asymmetric-substituted phenazines can be prepared by thermal decomposition of aryl-azide in the presence of aniline or polyfluorinated aniline (see Scriven et al., “Thermolysis of aryl azides in anilines,” Tetrahedron Letters (1973), pp. 103-106).

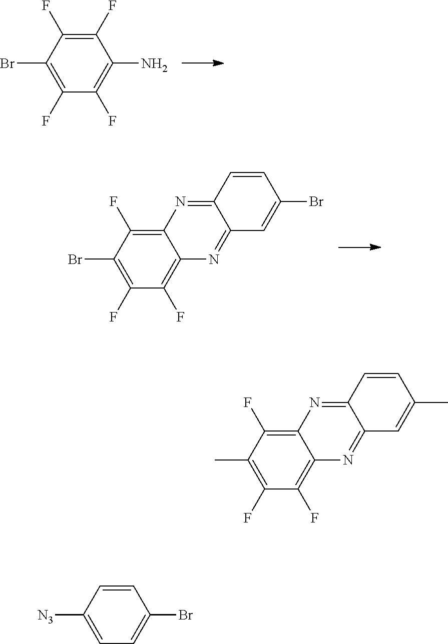

The above synthetic route can be used to provide 1,3,4 trifluoro-2,6-dibromo-phenazine, which in turn can be used as an intermediate for the synthesis of molecular semiconductors and polymers according to the present teachings using, for example, procedures analogous to those described in Examples 1-8.

### Example 10

### Characterization of Polymers and Small Molecules

### Experimental Conditions

UV-Vis spectra were recorded on a Cary 50 UV-vis spectrophotometer. Cyclic voltammetry measurement was carried out under nitrogen using a BAS-CV-50W voltammetric analyzer. For redox property measurements of polymer samples, the polymer films were prepared by drop-casting a 2 mg/mL polymer solution in chloroform onto a platinum disk working electrode followed by slow drying. A platinum wire served as the auxiliary electrode, and an Ag wire anodized with AgCl served as a pseudo-reference electrode. The experiments were performed on deoxygenated 0.1 M solutions of tetra-n-butylammonium hexafluorophosphate in anhydrous acetonitrile at a scan rate of 50 mV/s. Potentials were referenced to the ferrocenium/ferrocene)(FeCp2^{+/0})couple by using ferrocene as an external standard. For redox property measurements of small molecule samples, the experiments were performed on deoxygenated 0.1 M solutions of tetra-n-butylammonium hexafluorophosphate in anhydrous dichloromethane with a certain concentration of the respective materials at a scan rate of 50 mV/s. Potentials were referenced to the ferrocenium/ferrocene)(FeCp2^{+/0}) couple by using ferrocene as an internal standard.

TABLE 1
Summary of physico-chemical data
for the indicated phenazine-based semiconductors.

| | | | | | Band | Band |
|---|---|---|---|---|---|---|
| | | | | | Gap | Gap |
| Com- | | | | | (from | (from |
| pound | Eₒₓ | E_{red} | LUMO | HOMO | CV) | UV-Vis) |
| P2 | +1.52 V | −0.27 V | −4.17 eV | −5.96 eV | 1.79 eV | 1.63 eV |
| P3 | +1.35 V | −0.48 V | −3.96 eV | −5.79 eV | 1.83 eV | 1.63 eV |
| P4 | +1.32 V | −0.74 V | −3.70 eV | −5.76 eV | 2.06 eV | 1.88 eV |
| P5 | | −0.95 V | −3.64 eV | −5.39 eV | — | 1.75 eV |
| SM2 | | | | | | 2.35 eV |

### Example 11

### Organic Transistor Device Fabrication and Measurements

Top-gate bottom-contact (TGBC) thin film transistors were prepared as follows: Step 1. Glass substrates (eagle 2000) were optionally covered with a thin film of Polyera ActivInk™ B2000, which was spin-coated from a PGMEA solution at 1200 rpm, followed by UV irradiation for 10 min. Step 2. Gold (30-50 nm) were thermally evaporated as S/D electrodes. Step 3. S/D electrodes were optionally treated with a thiolate molecule to promote charge injection. Step 4. The semiconductor was dissolved in an organic solvent, at a concentration of ˜4-10 mg/mL and then it was spin-coated at 1000-2000 rpm, and then dried at 120-150° C. to give a film of ˜50 nm. Step 5. The dielectric was deposited by spin coating. Examples of dielectric include Polyera Activink™ D2200, PMMA, or CYTOP. Gold (30 nm) was thermally evaporated as gate electrode. TFTs were tested under dark in a probe station (Signatone) in ambient environment using Keithley 4200 two source electrometer.

Bottom-gate top-contact (BGTC) thin film transistors were prepared as follows: Step 1. Highly n-type doped silicon wafers (<0.004 Ωcm) with 300 nm SiO₂ were used as gate/dielectric substrates. The dielectric surface was optionally functionalized with hexamethyldisilazane (HMDS), octadecyltrichlorosilane (OTS), or a thin polymethylmethacrylate (PMMA) layer (˜30 nm). Step 2. Semiconductor thin films (40-50 nm) were next vapor-deposited onto the Si/SiO₂-treated substrates held at room temperature or 70° C., with a deposition rate of 0.2 Å/s at ˜3×10-7 Torr, employing a high-vacuum deposition chamber (Denton Vacuum, Inc., USA). Step 3, Source/drain electrodes were defined by thermal evaporation of 50 nm thick gold film through shadow masks at ˜2×10-6 Torr. The channel lengths and widths are 100 μm and 1000 μm, respectively. TFT were tested under dark in a vacuum probe station (˜1×10-5 Torr) using Keithley 4200 two source electrometer.

TABLE 2
Summary of the TGBC OTFT device performance for the
indicated phenazine-based polymers (Au S/D contacts).

| | | Electron Mobility | Hole mobility |
|---|---|---|---|
| Polymer | Dielectric | (cm²/Vs) | (cm²/Vs) |
| P2 | PMMA | 1.8 × 10⁻² | 1.8 × 10⁻³ |
| P2 | D2200 | 6.8 × 10⁻² | 3.1 × 10⁻³ |
| P3 | D2200 | — | 3.9 × 10⁻³ |
| P5 | D2200 | — | 0.3 |

TABLE 3
Summary of the BGTC OTFT electron mobility (cm²/Vs) for the
indicated phenazine-based small molecules (Au S/D contacts).

| | |
|---|---|
| Small | Si/SiO2 Coating |

| Molecule | Condition | PMMA | OTS | HMDS |
|---|---|---|---|---|
| SM1 | RT | 7.1 × 10⁻² | 1.2 × 10⁻² | 3.2 × 10⁻³ |
| | 70° C. | 6.5 × 10⁻² | 1.1 × 10⁻² | 2.3 × 10⁻² |
| SM2 | RT | — | 1.5 × 10⁻² | — |
| | 70° C. | 8.3 × 10⁻⁴ | 4.0 × 10⁻² | 6.0 × 10⁻⁴ |

### Example 12

### Solar Cell Device Fabrication and Measurements

Phenazine-Based Polymers as Donor Semiconductors.

Conventional OPV devices were fabricated by evaporating 8 nm of MoO₃ onto pre-cleaned ITO substrates. A blend solution for forming the active layer was prepared by dissolving a phenazine polymer (functioning as the donor) and C₇₀PCBM (functioning as the acceptor) in a weight ratio of 5:10 mg/ml in an organic solvent (e.g., a 9:1 by volume solvent mixture of CHCl₃:DCB). Active layers were spin-cast in a N₂ glove box. Finally, 0.6 nm of LiF and 100 nm of Al were evaporated as the top electrode under a vacuum of about 10⁻⁶ mbar. Devices were encapsulated using a blanket of EPOTEK OG116-31 UV-curable epoxy (Epoxy Technologies) and a glass cover slip. The photovoltaic characteristics of encapsulated devices were tested in air. The current-voltage (I-V) curves were obtained by a Keithley 2400 source-measure unit. The photocurrent was measured under simulated AM1.5 G irradiation (100 mW cm⁻²) using a xenon-lamp-based solar simulator (Newport 91160A 300 W Class-A Solar Simulator, 2 inch by 2 inch uniform beam). The light intensity was set using a NREL calibrated silicon photodiode with a color filter. External quantum efficiency was measured using Newport's QE setup. Incident light from a xenon lamp (300 W) passing through a monochromator (Newport, Cornerstone 260) was focused on the active area of the cell. The output current was measured using a current pre-amplifier (Newport, 70710QE) and a lock-in amplifier (Newport, 70105 Dual channel Merlin). A calibrated silicon diode (Newport 70356) was used as the reference.

TABLE 4
JV characteristics of the indicated phenazine-
based polymer donor: C₇₀PCBM blend device measured
under simulated AM1.5 (100 mW/cm²).

| Polymer | V_{oc} [V] | J_{sc} [mA/cm²] | FF [%] | PCE [%] |
|---|---|---|---|---|
| P4 | 1.06 | 5.0 | 56.3 | 3.0 |
| P5 | 0.90 | 6.1 | 58.1 | 3.2 |

Phenazine-Based Polymers as Acceptor Semiconductors.

Inverted OPVs were fabricated on pre-cleaned ITO-covered glass. First, ZnO films were prepared by spin-coating a mixture of diethylzinc solution in toluene (15 wt %) and tetrahydrofuran (1:6 by volume) in air onto ITO followed by annealing at 120° C. in N₂ for 20 minutes. A blend solution for forming the active layer was prepared by dissolving a phenazine polymer (functioning as the acceptor) and a donor polymer (PV2000 from Polyera Corp.) in an organic solvent (e.g., CHCl₃) in a weight ratio of 6:6 mg/ml. Active layers were spin-cast in a N₂ glove box. To complete the device fabrication, 8 nm of vanadium oxide (V₂O₅) and 100 nm of Al were evaporated as the top electrode under a vacuum of about 10⁻⁶ mbar. Devices were encapsulated using a blanket of EPOTEK OG116-31 UV-curable epoxy (Epoxy Technologies) and a glass cover slip.

TABLE 5
JV characteristics for the indicated PV2000:
phenazine-based polymer acceptor blend device measured
under simulated AM1.5 (100 mW/cm²)

| Polymer | V_{oc} [V] | J_{sc} [mA/cm²] | FF [%] | PCE [%] |
|---|---|---|---|---|
| P2 | 1.00 | 1.0 | 27.0 | 0.2 |
| P3 | 1.08 | 2.5 | 31.1 | 0.8 |

All publications, including but not limited to patents and patent applications, cited in this specification are herein incorporated by reference as if each individual publication were specifically and individually indicated to be incorporated by reference herein as though fully set forth.

The present teachings encompass embodiments in other specific forms without departing from the spirit or essential characteristics thereof. The foregoing embodiments are therefore to be considered in all respects illustrative rather than limiting on the present teachings described herein. Scope of the present invention is thus indicated by the appended claims rather than by the foregoing description, and all changes that come within the meaning and range of equivalency of the claims are intended to be embraced therein.

1. A semiconducting compound comprising one or more phenazine moieties represented by formula (I): 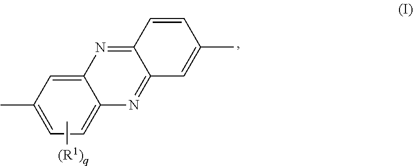
wherein:
R¹, at each occurrence, independently is selected from the group consisting of a halogen, —CN, NO₂, R², -L-R³, OH, OR², OR³, NH₂, NHR², N(R²)₂, NR²R³, N(R³)₂, SH, SR², SR³, S(O)₂OH, —S(O)₂OR², —S(O)₂OR³, C(O)H, C(O)R², C(O)R³, C(O)OH, C(O)OR², C(O)OR³, C(O)NH₂, C(O)NHR², C(O)N(R²)₂, C(O)NR²R³, C(O)N(R³)₂, SiH₃, SiH(R²)₂, SiH₂(R²), and Si(R²)₃, wherein L is selected from the group consisting of a divalent C₁₋₄₀ alkyl group, a divalent C₂₋₄₀ alkenyl group, a divalent C₁₋₄₀ haloalkyl group, and a covalent bond; R² is selected from the group consisting of a C₁₋₄₀ alkyl group, a C₂₋₄₀ alkenyl group, a C₂₋₄₀ alkynyl group, and a C₁₋₄₀ haloalkyl group; and R³ is selected from the group consisting of a C₃₋₁₀ cycloalkyl group, a C₆₋₁₄ aryl group, a C₆₋₁₄ haloaryl group, a 3-12 membered cycloheteroalkyl group, and a 5-14 membered heteroaryl group, each of which optionally is substituted with 1-5 substituents selected from the group consisting of a halogen, —CN, NO₂, R², OR², and SR², and
q is 0 or an integer selected from the group consisting of 1, 2, 3, 4, 5, and 6; and
one or more linear and/or cyclic conjugated moieties other than the phenazine moieties represented by formula (I).

2. The compound of claim 1, wherein q is an integer selected from the group consisting of 1, 2, 3, 4, 5, and 6.

3. The compound of claim 2, wherein R¹, at each occurrence, independently is selected from the group consisting of F, Cl, —CN, —NO₂, a phenyl group, R², OR², and SR², wherein R² is selected from the group consisting of a linear or branched C₁₋₄₀ alkyl group, a linear or branched C₂₋₄₀ alkenyl group, and a linear or branched C₁₋₄₀ haloalkyl group.

4. The compound of claim 3, wherein each R¹ is F.

5. The compound of claim 1, wherein the compound is a polymer having a first repeating unit M₁ comprising one or more divalent units represented by formula (I) and wherein said polymer has a degree of polymerization (n) ranging from 3 to 1,000.

6. The compound of claim 5, wherein M₁ is selected from the group consisting of: 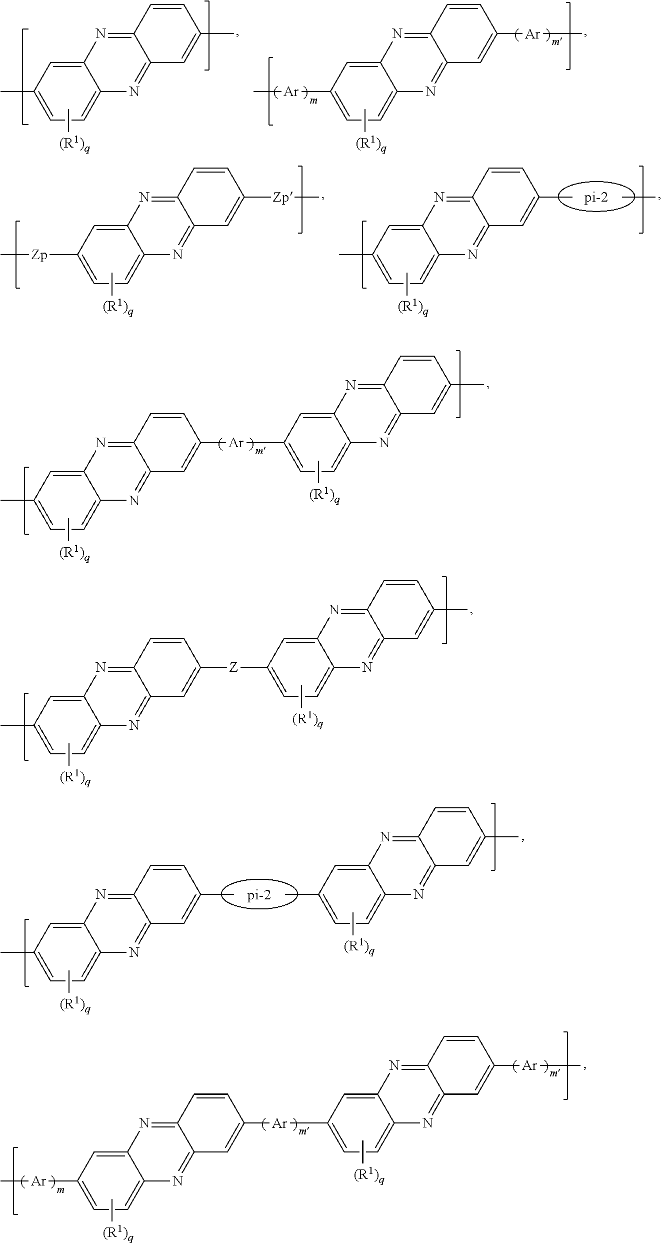 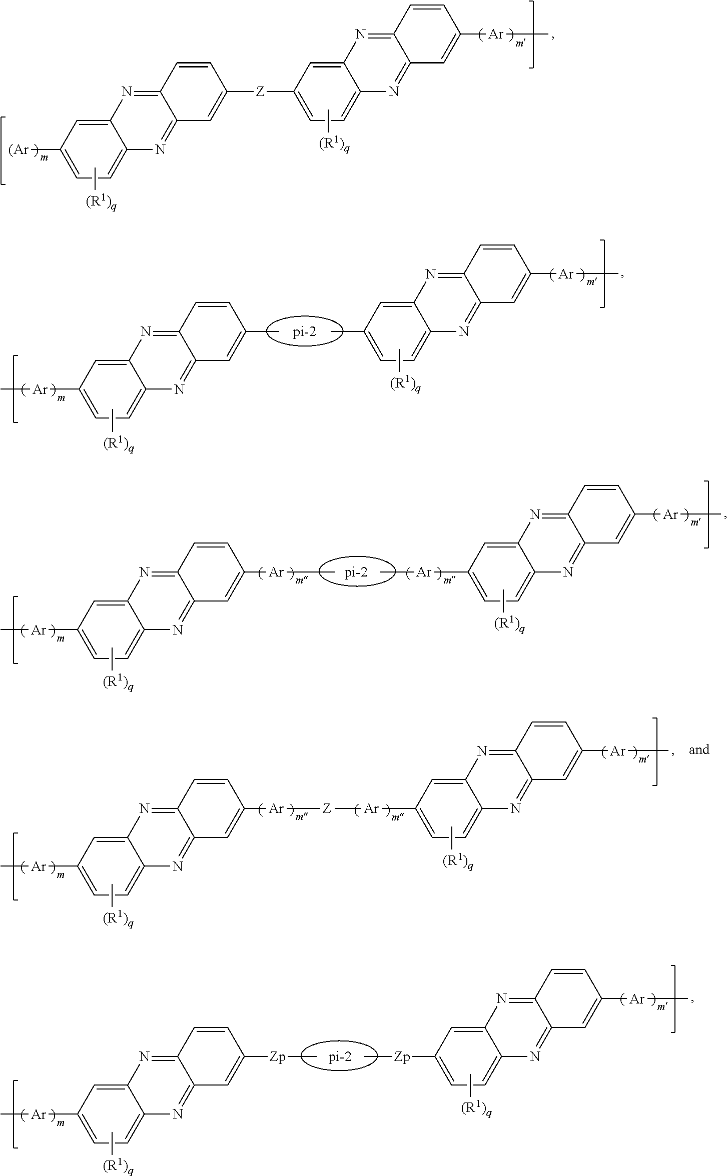
wherein:
pi-2 is an optionally substituted conjugated polycyclic moiety selected from the group consisting of an optionally substituted C₈₋₂₆ aryl group and an optionally substituted 8-26 membered heteroaryl group;
Ar, at each occurrence, independently is an optionally substituted monocyclic moiety selected from the group consisting of an optionally substituted 5-membered aryl group, an optionally substituted 6-membered aryl group, an optionally substituted 5-membered heteroaryl group, and an optionally substituted 6-membered heteroaryl group;
Z is a conjugated noncyclic linker;
m and m′ independently are 0, 1, 2, 3, 4, 5 or 6, provided that at least one of m and m′ is not 0;
m″ is 1, 2, 3, 4, 5 or 6; and
p and p′ independently are 0 and 1, provided that at least one of p and p′ is 1.

7. The compound of claim 6, wherein pi-2 is selected from the group consisting of: 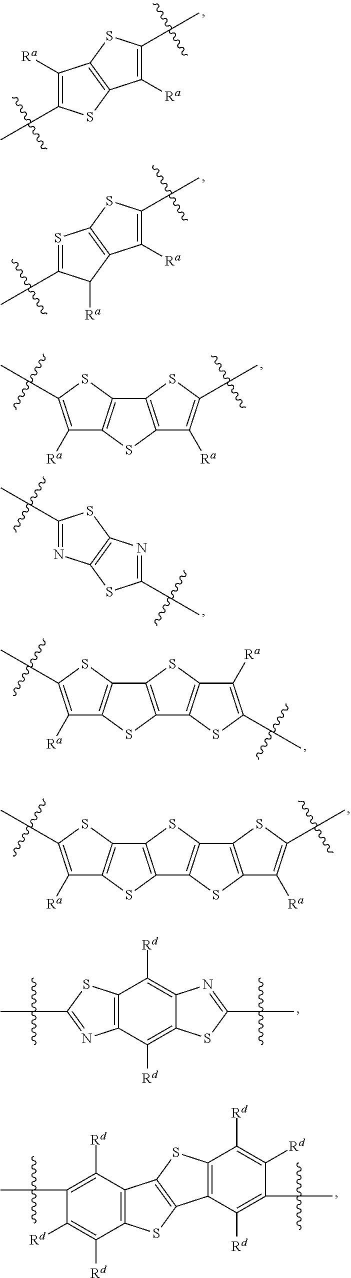 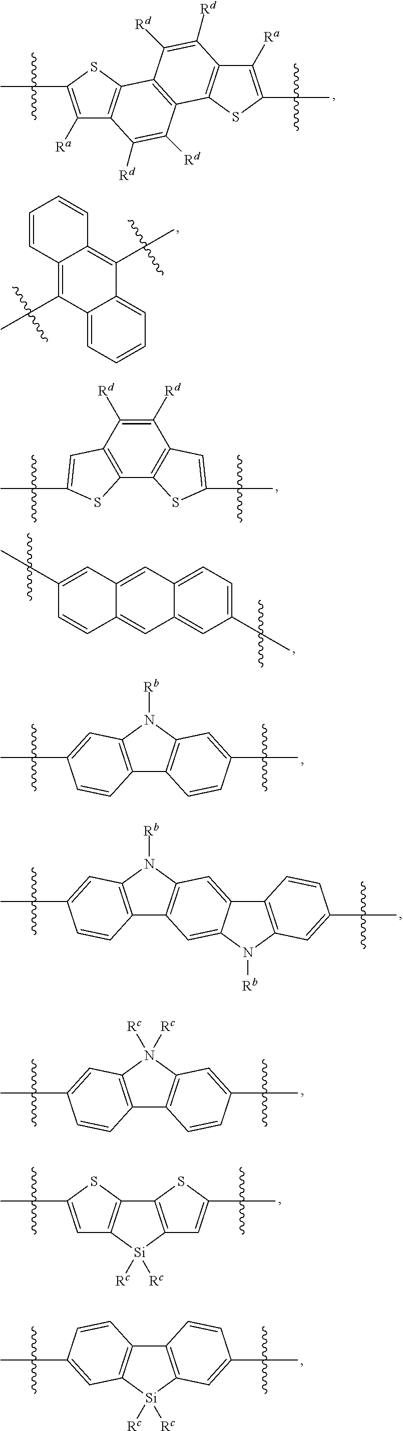 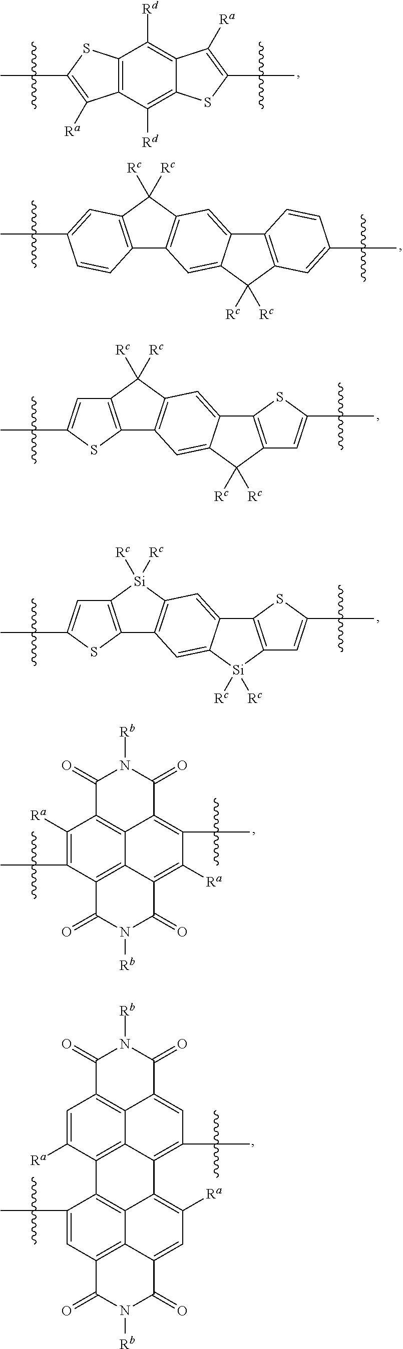 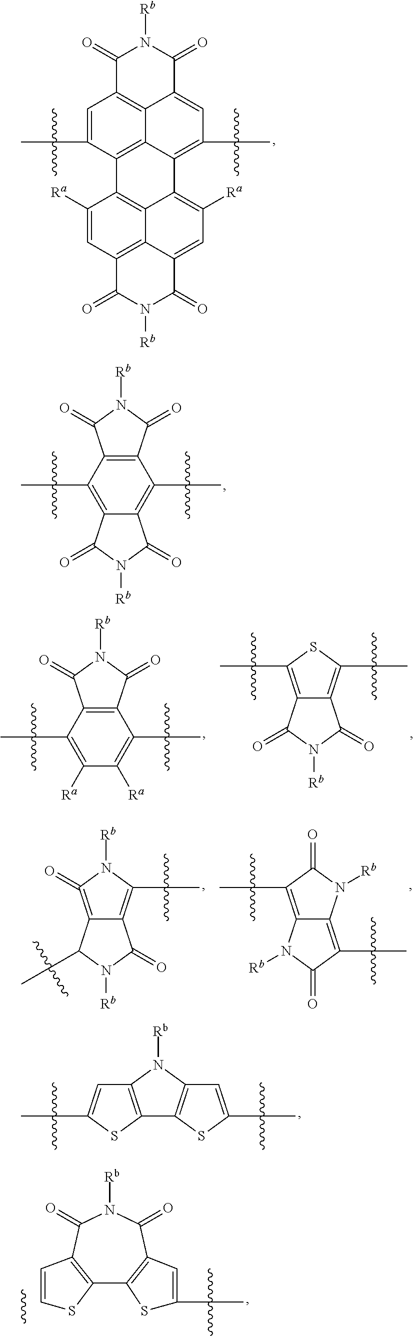 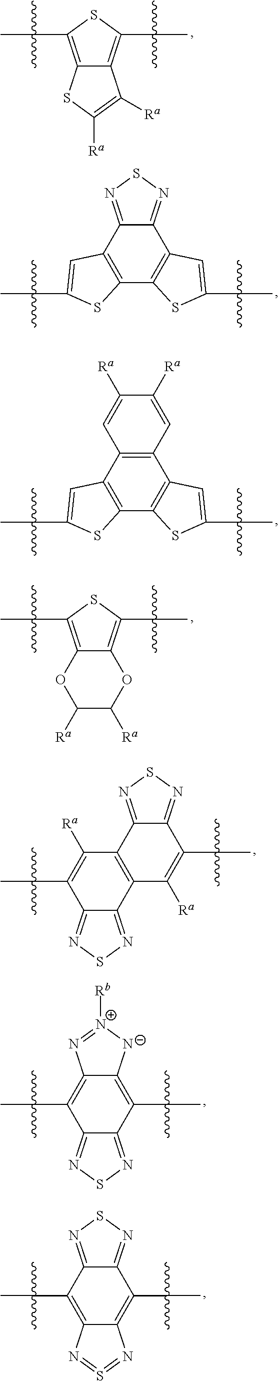 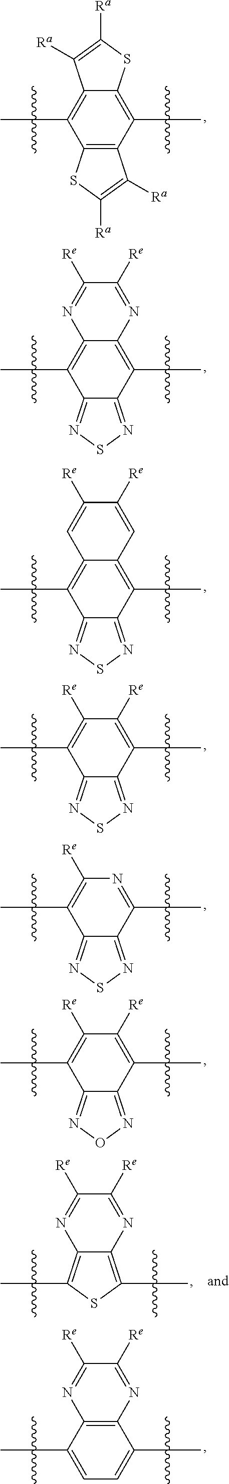
wherein:
R^{a} is selected from the group consisting of H, F, Cl, —CN, R, —OR, —SR, —C(O)R, —OC(O)R, and —C(O)OR;
R^{b} is selected from the group consisting of H, R, and -L′-R^{f};
R^{c} is H or R;
R^{d} is selected from the group consisting of H, F, Cl, —CN, R, —OR, —SR, —C(O)R, —OC(O)R, —C(O)OR, and -L′-R^{f};
R^{e} is selected from the group consisting of H, F, Cl, —CN, R, —OR, —SR, —C(O)R, —OC(O)R, —C(O)OR, and R^{f};
R^{f} is a C₆₋₂₀ aryl group or a 5-20-membered heteroaryl group, each optionally substituted with 1-8 groups independently selected from the group consisting of F, Cl, —CN, R, —OR, and SR;
L′ is selected from the group consisting of —O—, —S—, —C(O)—, —OC(O)—, —C(O)O—, and a covalent bond; and
R is selected from the group consisting of a C₁₋₄₀ alkyl group, a C₁₋₄₀ haloalkyl group, a C₂₋₄₀ alkenyl group, and a C₂₋₄₀ alkynyl group.

8. The compound of claim 6, wherein Ar in (Ar)ₘ, (Ar)_{m′}, and (Ar)_{m″} is represented by: 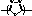
wherein each W independently is selected from the group consisting of N, CH, and CR⁴, wherein R⁴ is selected from the group consisting of F, Cl, —CN, R², OR², SR², C(O)R², OC(O)R², and C(O)OR², and wherein R² is selected from the group consisting of a C₁₋₄₀ alkyl group, a C₂₋₄₀ alkenyl group, a C₂₋₄₀ alkynyl group, and a C₁₋₄₀ haloalkyl group.

9. The compound of claim 8, wherein (Ar)ₘ, (Ar)_{m′}, and (Ar)_{m″} independently are selected from the group consisting of:

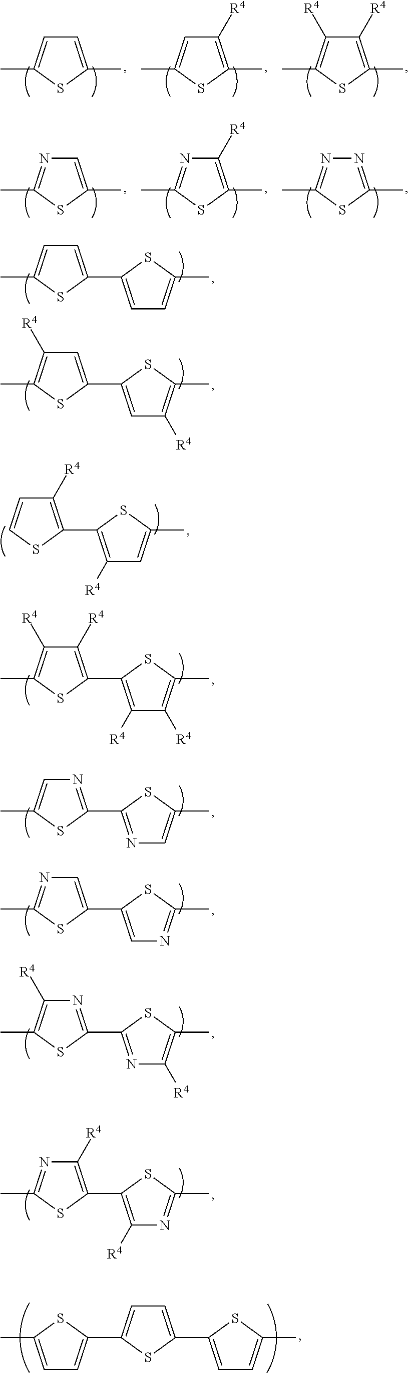

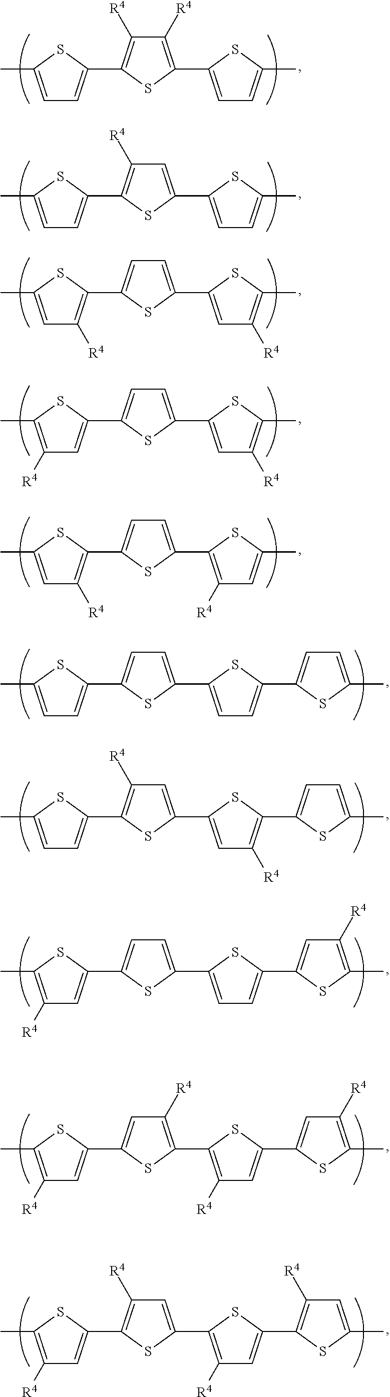

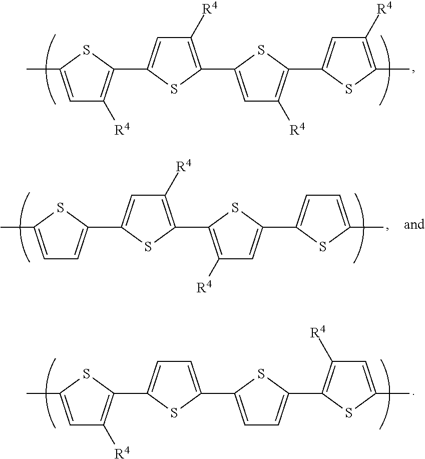

10. The compound of claim 6, wherein Z is selected from the group consisting of: 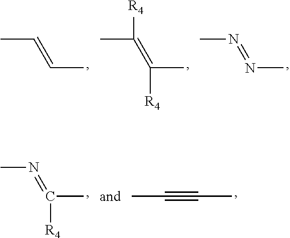
wherein R⁴ is selected from the group consisting of F, Cl, —CN, R², OR², SR², C(O)R², OC(O)R², and C(O)OR², and wherein R² is selected from the group consisting of a C₁₋₄₀ alkyl group, a C₂₋₄₀ alkenyl group, a C₂₋₄₀ alkynyl group, and a C₁₋₄₀ haloalkyl group.

11. The compound of claim 5, further comprising one or more repeating units other than M₁, the one or more other repeating units (M₂) being selected from the group consisting of: 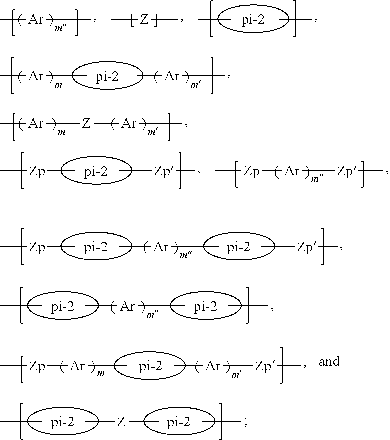
wherein:
pi-2 is an optionally substituted conjugated polycyclic moiety selected from the group consisting of an optionally substituted C₈₋₂₆ aryl group and an optionally substituted 8-26 membered heteroaryl group;
Ar, at each occurrence, independently is an optionally substituted monocyclic moiety selected from the group consisting of an optionally substituted 5-membered aryl group, an optionally substituted 6-membered aryl group, an optionally substituted 5-membered heteroaryl group, and an optionally substituted 6-membered heteroaryl group;
Z is a conjugated noncyclic linker;
m and m′ independently are 0, 1, 2, 3, 4, 5 or 6, provided that at least one of m and m′ is not 0;
m″ is 1, 2, 3, 4, 5 or 6; and
p and p′ independently are 0 and 1, provided that at least one of p and p′ is 1.

12. The compound of claim 11, wherein:
Z is selected from the group consisting of: 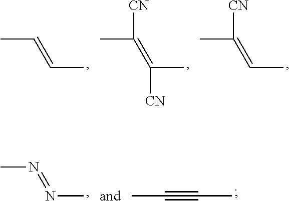
(Ar)ₘ, (Ar)_{m′}, and (Ar)_{m″} independently are selected from the group consisting of: 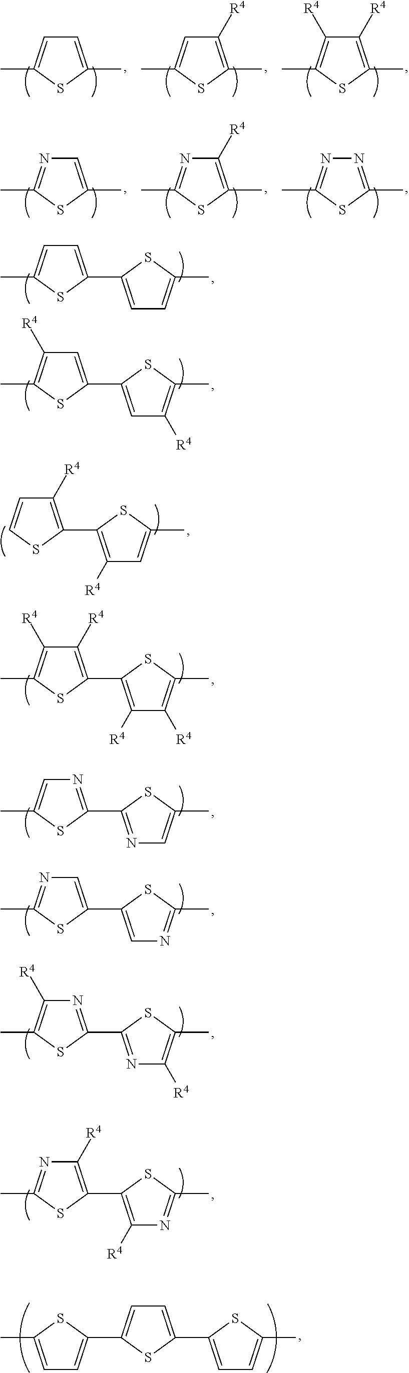 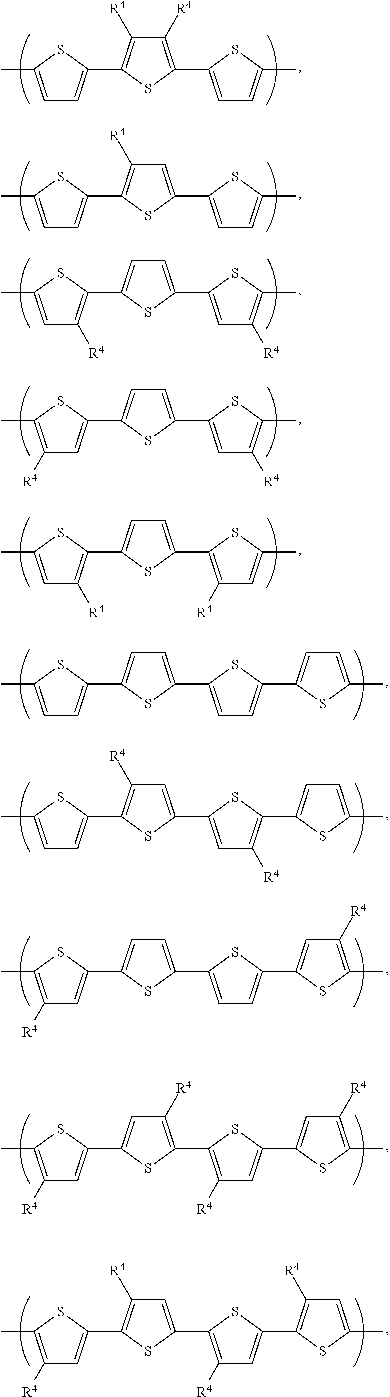 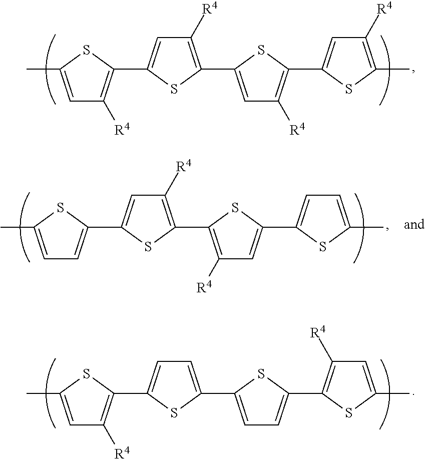
wherein R⁴ is selected from the group consisting of F, Cl, —CN, R², OR², SR², C(O)R², OC(O)R², and C(O)OR², and wherein R² is selected from the group consisting of a C₁₋₄₀ alkyl group, a C₂₋₄₀ alkenyl group, a C₂₋₄₀ alkynyl group, and a C₁₋₄₀ haloalkyl group; and
pi-2 is selected from the group consisting of: 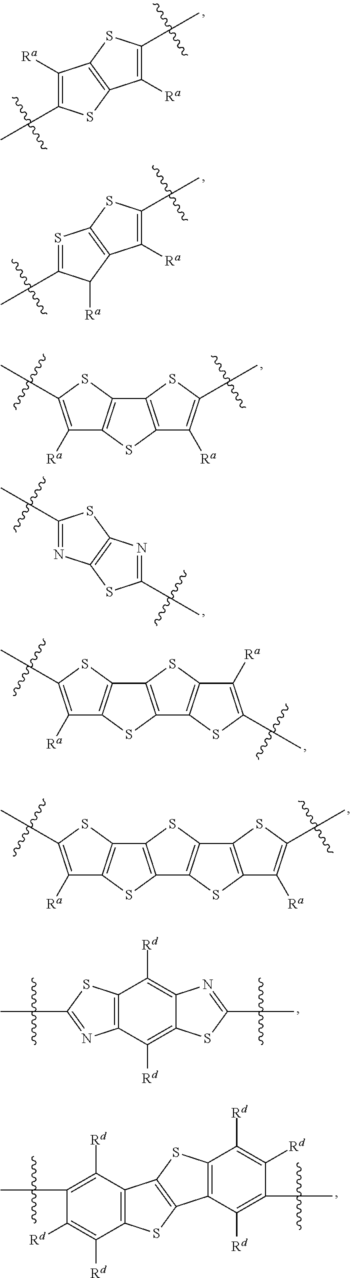 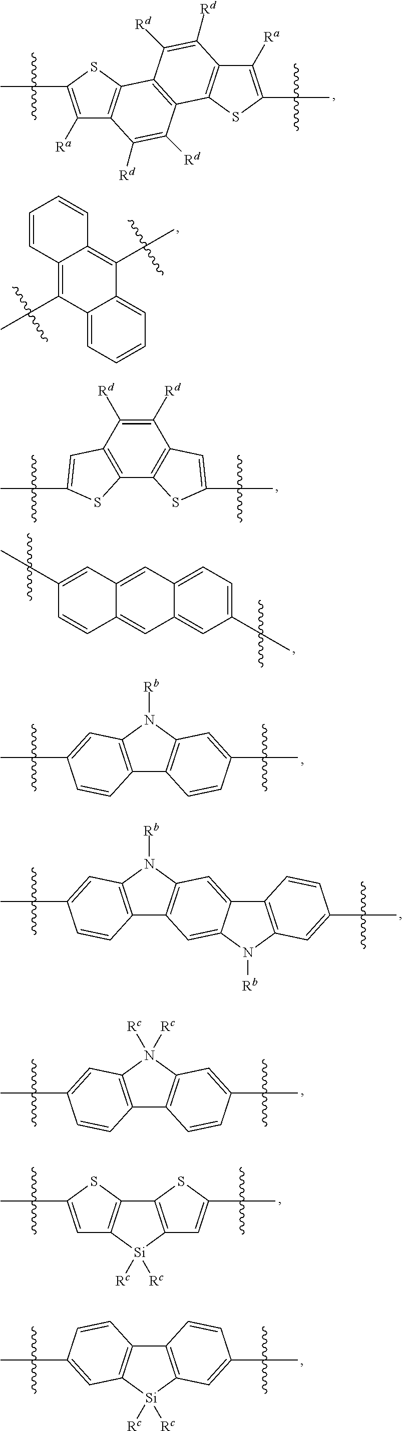 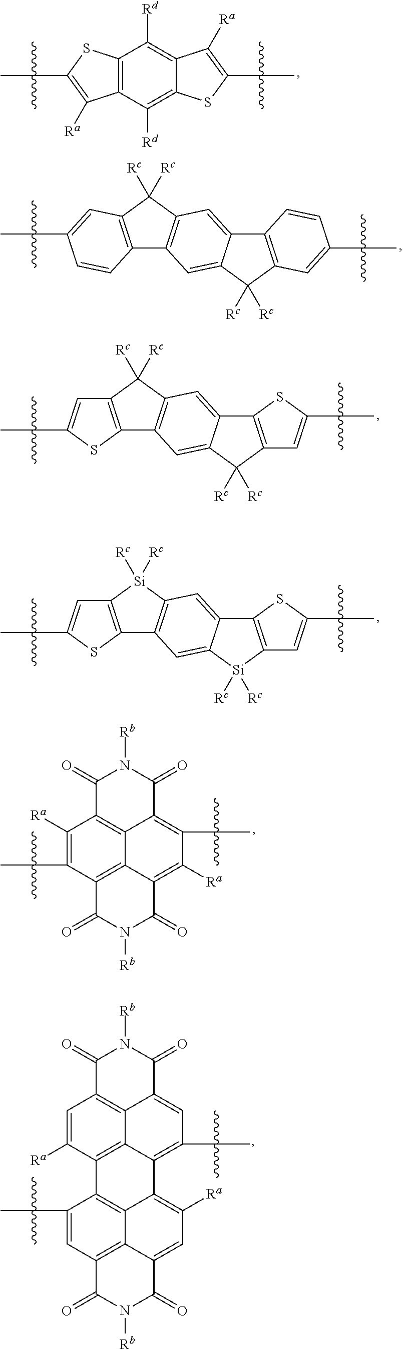 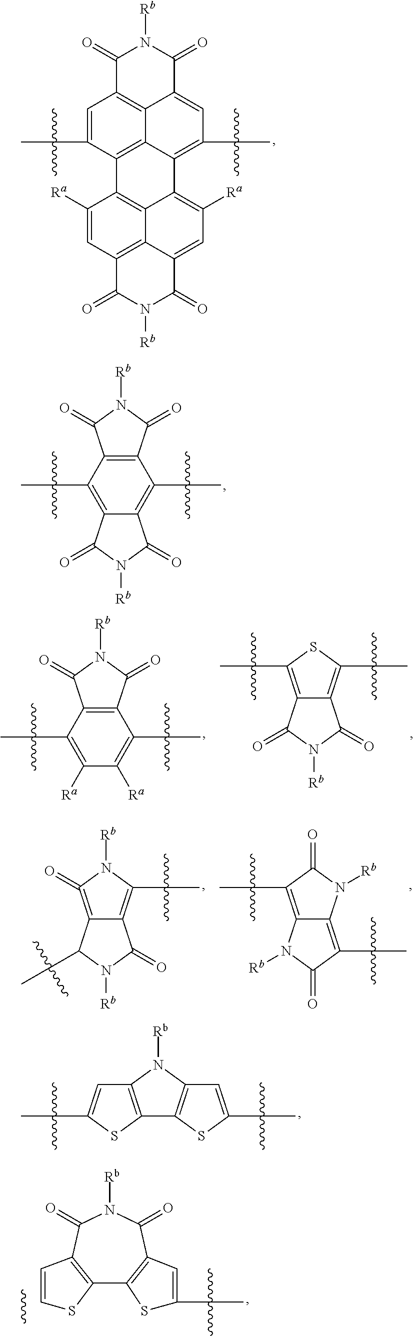 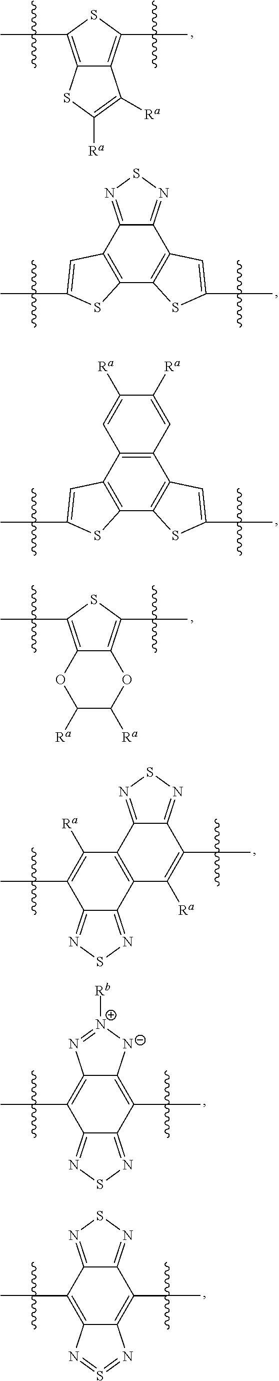 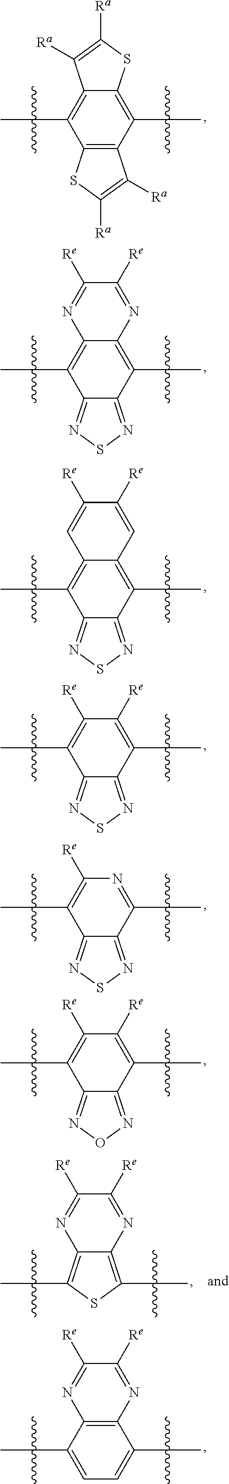
wherein:
R^{a} is selected from the group consisting of H, F, Cl, —CN, R, —OR, —SR, —C(O)R, —OC(O)R, and —C(O)OR;
R^{b} is selected from the group consisting of H, R, and -L′-R^{f};
R^{c} is H or R;
R^{d} is selected from the group consisting of H, F, Cl, —CN, R, —OR, —SR, —C(O)R, —OC(O)R, —C(O)OR, and -L′-R^{f}; and
R^{e} is selected from the group consisting of H, F, Cl, —CN, R, —OR, —SR, —C(O)R, —OC(O)R, —C(O)OR, and R^{f}; wherein
R^{f} is a C₆₋₂₀ aryl group or a 5-20-membered heteroaryl group, each optionally substituted with 1-8 groups independently selected from the group consisting of F, Cl, —CN, R, —OR, and —SR;
L′ is selected from the group consisting of —O—, —S—, —C(O)—, —OC(O)—, —C(O)O—, and a covalent bond; and R is selected from the group consisting of a C₁₋₄₀ alkyl group, a C₁₋₄₀ haloalkyl group, a C₂₋₄₀ alkenyl group, and a C₂₋₄₀ alkynyl group; and
R is selected from the group consisting of a C₁₋₄₀ alkyl group, a C₁₋₄₀ haloalkyl group, a C₂₋₄₀ alkenyl group, and a C₂₋₄₀ alkynyl group.

13. The compound of claim 12, wherein each divalent phenazine moiety 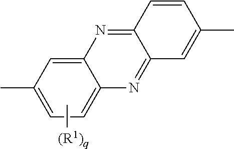
is more specifically 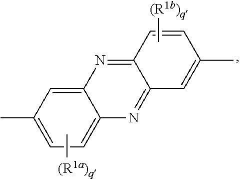
wherein R^{1a} and R^{1b} are identical or different, independently being selected from the group consisting of a halogen, —CN, NO₂, R², -L-R³, OH, OR², OR³, NH₂, NHR², N(R²)₂, NHR³, NR²R³, N(R³)₂, SH, SR², SR³, S(O)₂OH, —S(O)₂OR², —S(O)₂OR³, C(O)H, C(O)R², C(O)R³, C(O)OH, C(O)OR², C(O)OR³, C(O)NH₂, C(O)NHR², C(O)N(R²)₂, C(O)NHR³, C(O)NR²R³, C(O)N(R³)₂, SiH₃, SiH(R²)₂, SiH₂(R²), and Si(R²)₃, wherein L is selected from the group consisting of a divalent C₁₋₄₀ alkyl group, a divalent C₂₋₄₀ alkenyl group, a divalent C₁₋₄₀ haloalkyl group, and a covalent bond; R² is selected from the group consisting of a C₁₋₄₀ alkyl group, a C₂₋₄₀ alkenyl group, a C₂₋₄₀ alkynyl group, and a C₁₋₄₀ haloalkyl group; and R³ is selected from the group consisting of a C₃₋₁₀ cycloalkyl group, a C₆₋₁₄ aryl group, a C₆₋₁₄ haloaryl group, a 3-12 membered cycloheteroalkyl group, and a 5-14 membered heteroaryl group, each of which optionally is substituted with 1-5 substituents selected from the group consisting of a halogen, —CN, NO₂, R², OR², and SR²; and
q′, at each occurrence, independently, is 0 or an integer selected from the group consisting of 1, 2, and 3, provided that at least one of q′ is not 0.

14. The compound of claim 13, wherein 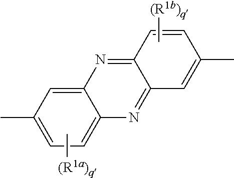
is selected from the group consisting of:

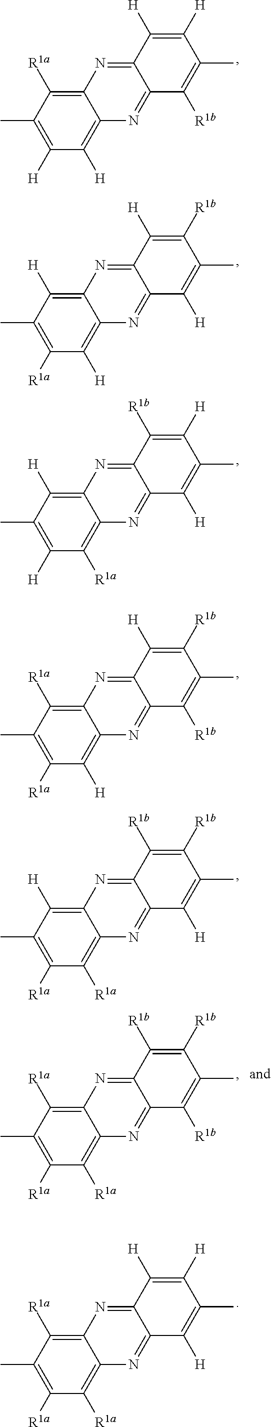

15. The compound of claim 11, wherein M₁ is selected from the group consisting of: 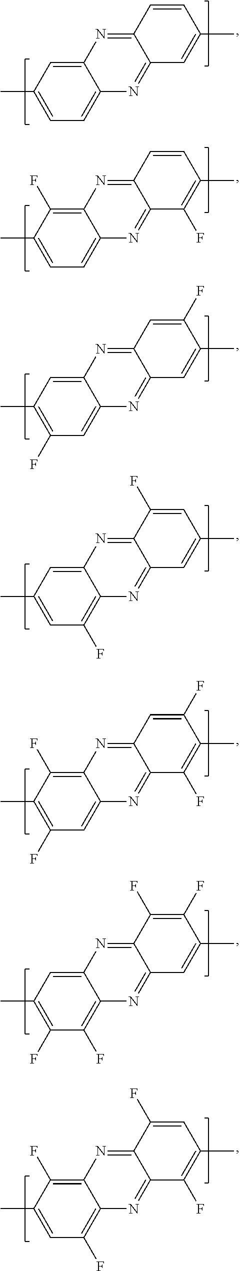 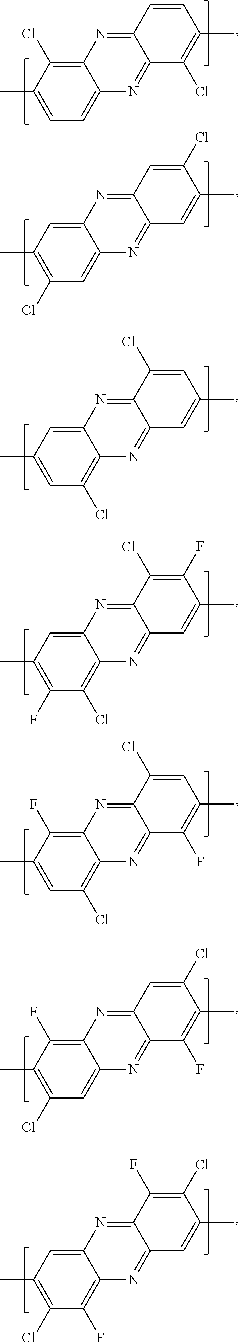 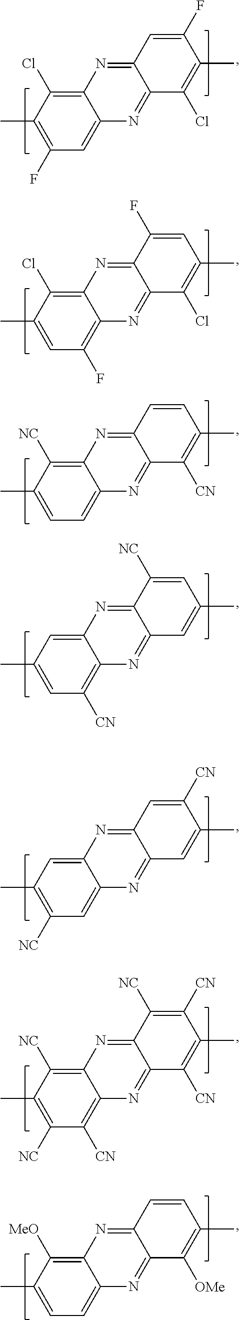 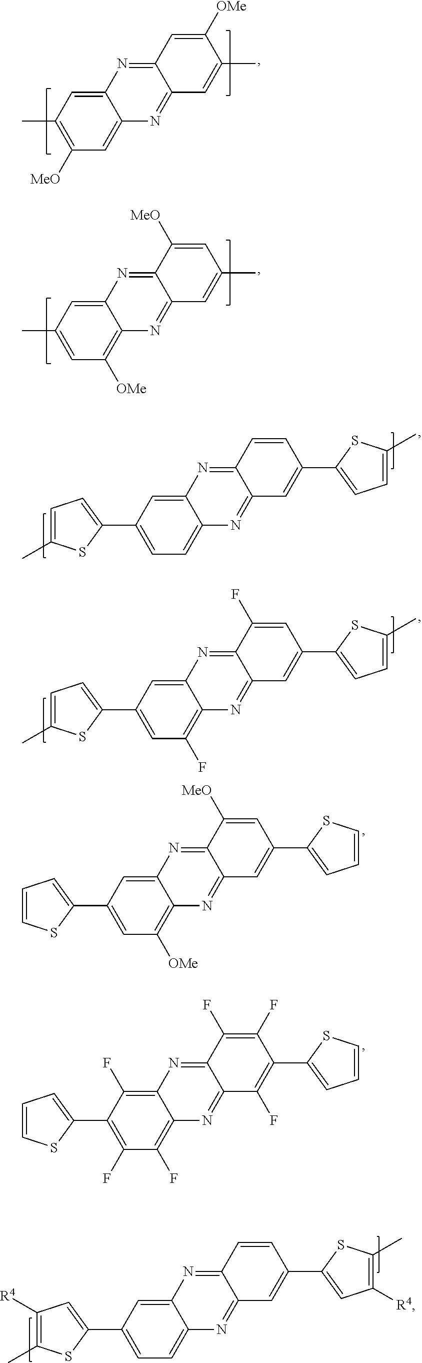 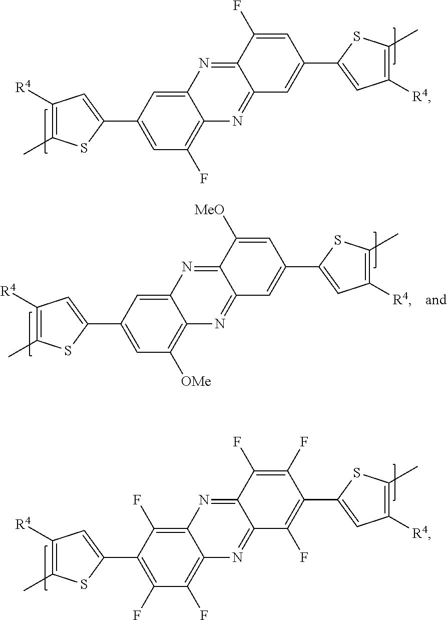
wherein R⁴, at each occurrence, independently is selected from the group consisting of R², OR², and SR², where R² is a linear or branched C₁₋₄₀ alkyl or haloalkyl group; and
M₂ is selected from the group consisting of: 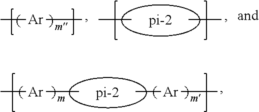
wherein (Ar), and (Ar)_{m′} are selected from the group consisting of:

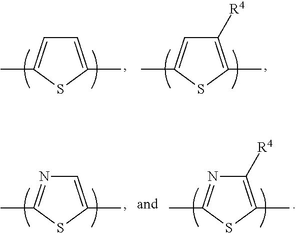

16. The compound of claim 15, wherein the compound is a copolymer having a formula selected from the group consisting of: 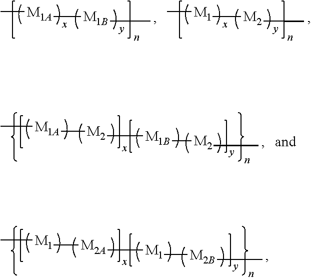
wherein M_{1A} and M_{1B} represent different repeating units M₁, and M_{2A} and M_{2B} represent different repeating units M₂, x and y are real numbers representing molar ratios, and n is the degree of polymerization.

17. The compound of claim 1, wherein the compound is a small molecule represented by a formula selected from the group consisting of: 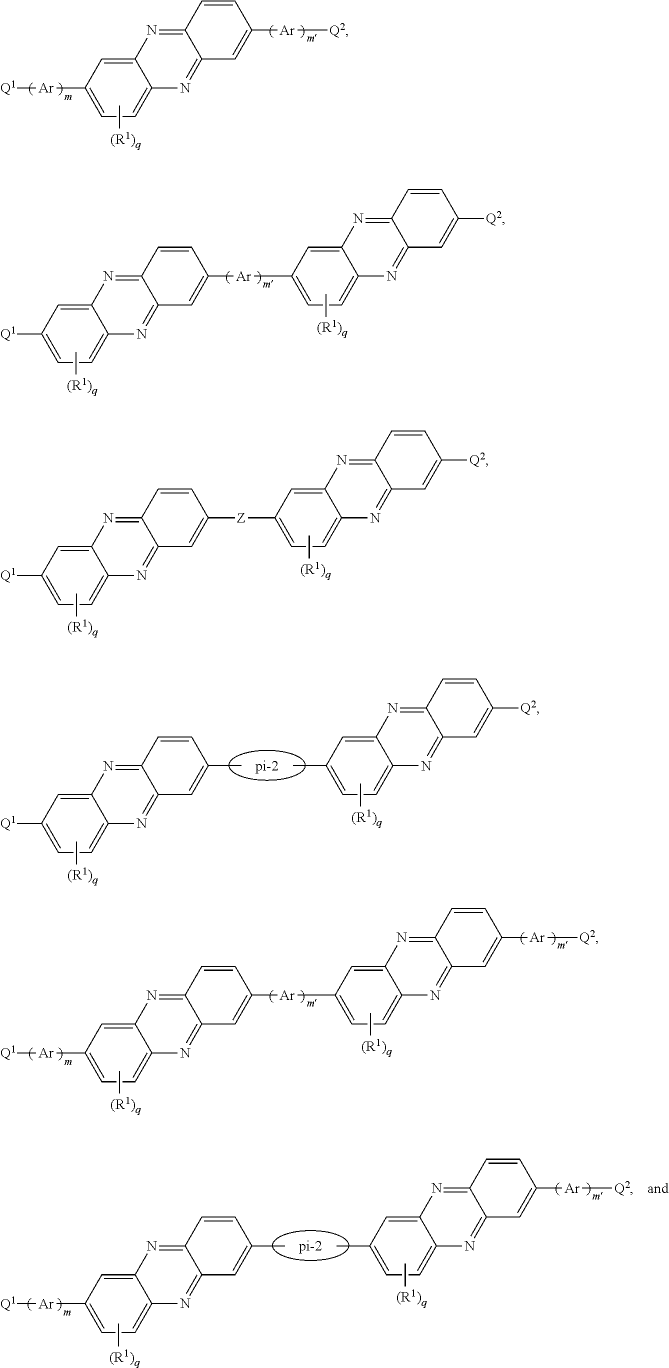 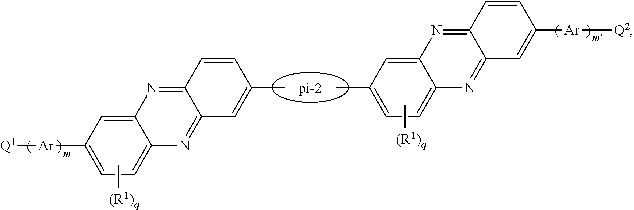
wherein:
Q¹ and Q² independently are selected from the group consisting of H, R², and C(O)R², wherein R² is a C₁₋₄₀ alkyl or haloalkyl group;
pi-2 is an optionally substituted conjugated polycyclic moiety selected from the group consisting of an optionally substituted C₈₋₂₆ aryl group and an optionally substituted 8-26 membered heteroaryl group;
Ar, at each occurrence, independently is an optionally substituted monocyclic moiety selected from the group consisting of an optionally substituted 5-membered aryl group, an optionally substituted 6-membered aryl group, an optionally substituted 5-membered heteroaryl group, and an optionally substituted 6-membered heteroaryl group;
Z is a conjugated noncyclic linker;
m and m′ independently are 0, 1, 2, 3, 4, 5 or 6, provided that at least one of m and m′ is not 0;
m″ is 1, 2, 3, 4, 5 or 6; and
p and p′ independently are 0 and 1, provided that at least one of p and p′ is 1.

18. The compound of claim 17, wherein the compound is represented by a formula selected from the group consisting of:

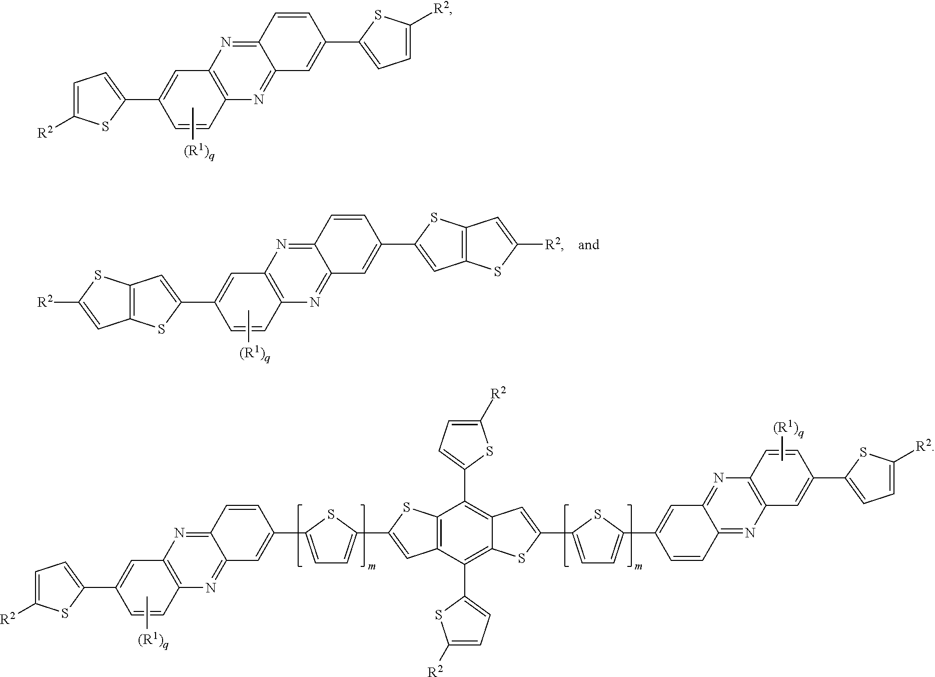

19. The compound of claim 17 selected from the group consisting of:

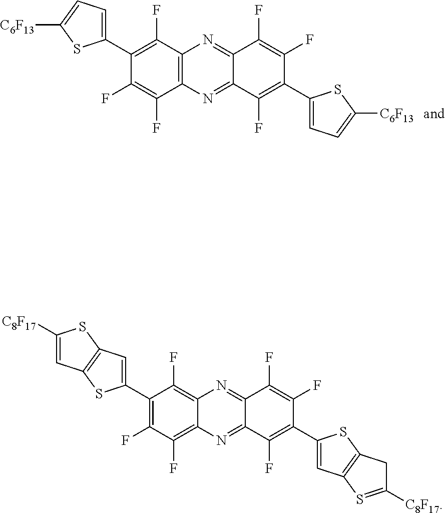

20. An electronic, optical or optoelectronic device comprising a semiconductor component, the semiconductor component comprising a compound of claim 1, wherein the electronic, optical or optoelectronic device optionally is selected from (a) an organic photovoltaic device comprising an anode, a cathode, optionally one or more anode interlayers, optionally one or more cathode interlayers, and in between the anode and the cathode a semiconductor component comprising a blend material, the blend material comprising an electron-acceptor compound and an electron-donor compound, wherein either the electron-acceptor compound or the electron-donor compound is a compound of claim 1; and (b) an organic thin film transistor comprising a substrate, a thin film semiconductor, a dielectric layer, a gate electrode, and source and drain electrodes, wherein the thin film semiconductor comprises a compound of claim 1.
